(19) United States
(12) Patent Application Publication
(10) Pub. No.: US 2020/0280771 A1
(43) Pub. Date: Sep. 3, 2020

(54) SMART ENERGY METERING SYSTEM AND METHOD

(71) Applicant: Pacific Gas and Electric Company, San Francisco, CA (US)

(72) Inventors: Quoc Hoang, Walnut Creek, CA (US); Alan Jones, Berkeley, CA (US); Earle Davis, Walnut Creek, CA (US); Young D. Nguyen, Alameda, CA (US); Alex Yan, Berkeley, CA (US); Shelley Williams, Antioch, CA (US)

(21) Appl. No.: 16/878,239

(22) Filed: May 19, 2020

Related U.S. Application Data
(63) Continuation-in-part of application No. 15/586,093, filed on May 3, 2017, now Pat. No. 10,658,798.
(60) Provisional application No. 62/408,260, filed on Oct. 14, 2016.

(51) Int. Cl. H04Q 9/00; H01R 13/703; H04L 29/08; G01R 22/06

(52) U.S. Cl. CPC H04Q 9/00; H01R 13/7031; H04L 67/12; H04Q 2209/60; H04Q 2209/75; H04Q 2209/20; G01R 22/063

(57) ABSTRACT

Some embodiments include an electric meter assembly including a socket housing with a socket interface extending from a top side of the socket housing, and a removable or portable meter coupled to the socket interface. Further, the electric meter assembly includes a strap coupled at one end to at least one side of the socket housing. The socket housing includes a socket interface extending from a top side of the socket housing, and a secondary housing enclosed within the socket housing. The secondary housing includes a CT shunt and a switch assembly including an actuator extending through the top side. In some embodiments, the system includes a Customer and Distribution Automation Open Architecture. In some embodiments, an IoT router facilitates communication between one or more remote electronics including the electric meter assembly.

### CROSS-REFERENCE TO RELATED APPLICATIONS

This application is a continuation-in-part of U.S. application Ser. No. 15/586,093, filed May 2, 2017, entitled “Smart Energy Metering System and Method”, which claims the benefit of and priority to U.S. Provisional Application No. 62/408,260, filed Oct. 14, 2016, entitled “Smart Energy Metering System and Method”, the entire contents of which are incorporated herein by reference.

### BACKGROUND

Many of today's energy metering systems such as residential and commercial electric and gas meters are bulky and not conveniently mounted or integrated with new or existing infrastructure. Mounting pedestals for self-contained meters are also bulky and costly, and are generally difficult to integrate with adjoining systems.

With the accelerating growth of distributed energy systems and mobile transportation and infrastructure, it would be desirable to provide energy metering systems that can be easily and unobtrusively integrated with existing infrastructure to provide convenient energy delivery, and real time consumption monitoring and transactions.

### SUMMARY

Table 1 is a list of acronyms used throughout this disclosure in descriptions of some embodiments.

TABLE 1
List of Acronyms

| | |
|---|---|
| AMI | Advanced Metering Infrastructure |
| API | Application Programming Interface |
| Byte | A unit of digital information consisting of 8 bits |
| DER | Distributed Energy Resource |
| DG | Distributed Generation |
| DNP3 | A communications protocol used in SCADA and telemetry |
| | system |
| DNS | Domain Name System |
| DNS-SD | DNS Service Discovery |
| DRLC | Demand Response and Load Control |
| EPIC | Electric Program Investment Charge |
| ESI | Energy Services Interface |
| EXI | Efficient XML Interface |
| GUI | Graphical User Interface |
| IEEE 2030.5 | A protocol standard designed for management of Smart |
| | Energy devices |
| IoT | Internet of Things |
| IP | Internet Protocol |
| IPv4 | Internet Protocol version 4 |
| IPv6 | Internet Protocol version 6 |
| Kbps | Kilobits per second - A unit of measure for network |
| | speed |
| kWh | Kilowatt hours - A measure of energy usage over time |
| LFDI | IEEE 2030.5 - Long Form Device Identifier |
| LLRP | Low-Level Reader Protocol. A standard protocol for |
| | communicating with RFID readers. |
| OTA | Over the Air |
| SCADA | Supervisory Control and Data Acquisition |
| SEP 2.0 | Another name synonymous with IEEE 2030.5 |
| SFDI | IEEE 2030.5 - Short Form Device ID |
| SSN | Silver Springs Networks Company (now Itron as of |
| | February 2018) |
| UDPTICNet | User Datagram Protocol |
| VPNUDP | Virtual Private NetworkUser Datagram Protocol |
| xmDNSVPN | Extensible Multicast DNSVirtual Private Network |
| xmDNS | Extensible Multicast DNS |

In some embodiments, terms and acronyms as used herein have the following meanings: TLS (new name for SSL as in HTTPS). XSD/WADL—XML Schema Definition and Web Application Description Language (define XML format and Web Service interface). DER: Distributed Energy Resource—Any device that can put energy onto grid (Smart Inverters, Batteries, etc.). DRLC: Demand Response Load Control—A means for communicating to devices to control energy consumption. SIWG—Smart Inverter Working Group—Joint CPUC/CEC group looking at issues around increase in proliferation of DER and CA Rule 21 revisions. SunSpec Alliance—Group creating/promoting system interoperability in DER domain. CSEP—Consortium for SEP2 Interoperability—Produced certification plan for IEEE 2030.5. POST—Power-On Self-Test, a diagnostic testing sequence that a is run by a computer system's starting program to determine if one or more hardware and/or software components are testing properly. GET—a data retrieval process where the Client downloads data from the Server.

In some embodiments, the following are IEEE 2030.5 Terms: Discovery—The process by which Clients identify Resources on the network. Resources—A URI-addressable object that a client can GET from or POST to the Server. Function Sets—A logical grouping of resources that cooperate to implement IEEE 2030.5 features (e.g. Metering, DER). Function Set Assignment—A “label” applied to End Devices for the purposes of issuing commands to groups of devices. EXI—Efficient XML Interchange (compressed XML payload). xmDNS—Extended Multicast DNS (For service discovery like Apple's® “bonjour”). SFDI/LFDI—Short Form/Long Form Device Identifiers—Both are derived from hashing the device certificate.

In some embodiments, the system includes one or more of the following technology stacks:

Server: Operating System—Linux® (ubuntu); Languages—Java®, Groovy®, Javascript®; Frameworks—Grails®; Persistence—MySQL®.

Client: Operating System—Linux® (ubuntu core); Languages—Java®, Groovy®; Frameworks—SpringBoot®; Persistence—Filesystem® (or SQLite®); Servlet Container—Apache Tomcat®.

In some embodiments, the system includes one or more of the following open source libraries for the Server and/or Client: jlibmodbus—open source software for reading and writing to hardware registers using the MODBUS protocol; opendnp3—open source software for decoding and forming DNP3 requests; openssl—open source software for performing SSL functions; bouncycastle—open source software that contains the elliptic curve secp256r1 cipher suite required by IEEE 2030.5 for hashing the TLS certificate; openEXI—open source library for converting XML to/from the EXI (compressed) format; llrp-toolkit—open source library for Low-Level Reader Protocol (LLRP) used with RFID Readers.

Some embodiments of the energy metering system (hereafter, the “system”) include an electric meter assembly comprising a support platform including at least one transformer coupled to the support platform, where the socket housing is coupled to the support platform. The socket housing comprises a socket interface extending from a top side of the socket housing, and a secondary housing at least partially enclosed within the socket housing, wherein the secondary housing includes at least one CT shunt and at least one switch assembly including an actuator extending through the top side of the socket housing.

Some embodiments further comprise a removable or portable meter coupled to the socket interface. In some embodiments, the actuator includes at least one actuator shaft extending through the top side of the socket housing. In some embodiments, the at least one actuator shaft is configured and arranged to be coupled to at least one shunt via at least one roller contact. In some embodiments, the at least one actuator shaft is supported within a spring in a plunger housing, and the spring is positioned in a cavity of the plunger housing and extends coupled to a contact of the at least one actuator shaft.

In some embodiments, the shunts include a plurality of electrical contacts. In some embodiments of the system, the at least one at least one actuator shaft is configured and arranged to electrically couple and decouple from the plurality of electric contacts based on the movement of the at least one actuator shaft.

Some embodiments include an electric meter assembly comprising a socket housing including a socket interface extending from a top side of the socket housing, and a removable or portable meter coupled to the socket interface. Further, the electric meter assembly comprises at least one strap coupled at one end to at least one side of the socket housing. The at least one strap is configured and arranged to extend over at least a portion of the meter from one side of the socket to an opposite side of the socket.

In some embodiments, the at least one strap is pre-bent. In some embodiments, the socket housing includes at least one strap latch configured to couple to a second end of the at least one strap. Some embodiments include a tamper-resistant seal coupled to a side of the socket housing. In some embodiments, the tamper-resistant seal is configured and arranged to be threaded through an aperture in the at least one strap. In some embodiments, the at least one strap comprises metal or metal alloy. In other embodiments, the at least one strap comprises polymer.

Some embodiments include at least one bracket coupled to at least one side of the socket housing. Some embodiments include at least one power receptacle extending through one side of the socket housing. In some embodiments, the socket housing is coupled to a support platform including a coupled transformer.

In some embodiments, the system includes a Customer and Distribution Automation Open Architecture. In some embodiments, an IoT router facilitates communication between one or more remote electronics (e.g., electric meter assembly described herein). As used herein, references made to remote “electrical devices”, “end devices,” and/or “electronics” include structure that at least includes one or more circuits to allow a directed flow of electricity. In some embodiments, the system leverages one or more conventional advanced metering infrastructure (AMI) networks to control the one or more remote electronics. In some embodiments, one or more remote electronics comprise consumer electronics, RFID electronics, distribution-grid electronics, and solar aggregator-managed/individual-managed electronics.

In some embodiments, the system software is divided between a server (Server) and client (Client). In some embodiments, the Server software is designed for and deployed on a virtual machine. In some embodiments, the virtual machine includes an operating system. In some embodiments, the operating system is a conventional operating system (e.g., a Linux-based operating system). In some embodiments, the Client software is configured to be deployed on the IoT router. In some embodiments, the IoT router has limited RAM (e.g., 1 GB), disk space (e.g., 4 GB), CPU power, and/or some root-level capabilities due to the Ubuntu core operating system. In some embodiments, communication between the Client and Server is over a bandwidth-constrained or other AMI network. In some embodiments, design considerations limit the amount of communication between client and server as well as the bandwidth used by each communication occurrence.

In some embodiments, the Server and Client applications are deployed on a conventional Apache Tomcat application container. In some embodiments, the Server is deployed directly through an application web archive (WAR) file while the Client software is deployed through an Ubuntu core SNAP container.

In some embodiments, both the Server and Client HTTP communication are secured with conventional Transport Layer Security (e.g., TLS v 1.2). In some embodiments, access to the web interface of the Server is controlled by user login and password credentials. In some embodiments, one or more administrative accounts are configured by default with full read/write access to all server domains. In some embodiments, additional user accounts default to full administrative access but can be configured to have restricted visibility to specific data and read/write capabilities on a per user and per data type basis. In some embodiments, administration of the Client is performed directly through the application account on the IoT router.

In some embodiments, the system uses conventional third-party software. In some embodiments, one or more conventional third-party software the system uses is shown below in Table 2.

TABLE 2
Third-Party Software

| Name | Description |
|---|---|
| jlibmodbus | Open source software for reading and writing to hardware |
| | registers using the MODBUS protocol. |
| opendnp3 | Open source software for forming DNP3 requests |
| openssl | Open source software for performing SSL functions. |
| bouncycastle | Open source software that contains the elliptic curve |
| | secp256r1 cipher suite required by IEEE 2030.5 for |
| | hashing the TLS certificate. |
| openEXI | Open source library for converting XML to/from the EXI |
| | (compressed) format. |
| llrp-toolkit | Open source library for Low-Level Reader Protocol (LLRP) |
| | used with RFID Readers. |

FIG. 13 depicts a system network diagram illustrating the high-level functionality required in both the Server and Client applications according to some embodiments. In some embodiments, 2030.5 Server resides on a virtual machine instance in the SLO02 environment provided by ATS. In some embodiments, 2030.5 Server network interface has both IPv4 and IPv6 addresses. In some embodiments, 2030.5 Clients reside on IoT routers staged in the ATS Smart Grid lab. In some embodiments, IoT routers have IPv6 address on AMI interface and an IPv4 local subnet including a DHCP server for devices. In some embodiments, RT SCADA instance is also an instance on the SLO02 environment. The DNP3 API (Web Service) manages inbound requests from RT SCADA. 2030.5 Server has several GUIs to allow user to create various requests: 2030.5 DER Programs, LLRP/SeedLink requests. In some embodiments, at least two communication paths between Server and Client are supported: IEEE 2030.5 and “DNP3”: IEEE 2030.5 path will use protocol-compliant messaging; DNP3 path will not be true DNP3 outstation/master, but a generic HTTP message relay which can be reused for other protocols. In some embodiments, 2030.5 Client Interface receives 2030.5 messages and converts them to commands using the device-specific protocol and customized for the specific device manufacturer. In some embodiments, 2030.5 Client contains required 2030.5 business logic for registration, managing multiple DER Programs, etc.

In some embodiments, the Server is a web-based, java application utilizing an open source web application framework (e.g., the Grails® framework) and a syntax-compatible object-oriented programming language (e.g., the Java-based Groovy® dynamic language). In some embodiments, the Server application runs in a conventional Tomcat® application container. In some embodiments, data for the application is persisted to an open-source relational database management system (e.g., MySQL®) database that is also hosted on the same virtual server as the application. In some embodiments, example conventional third-party applications compatible with the system are: Java®: 1.8.0_144; Grails®: 3.3.0.M2; Groovy®: 2.4.7; Tomcat®: 8.5.14, and/or MySQL®: 5.7.20-0ubuntu0.17.04.1.

In some embodiments, the Server and/or Client run a diagnostic testing sequence that is run by each system's starting program to determine if one or more hardware and/or software components are testing properly. In some embodiments, one or more Clients is configured to send a diagnostic testing sequence to one or more Servers that are configured to receive a diagnostic testing sequence.

FIG. 14 depicts a Server Class UML diagram for device objects and also shows the data to be stored for the End Devices and Client IoT routers according to some embodiments.

FIG. 15 depicts a Server Class UML diagram for device objects and shows the User object and associated Roles according to some embodiments.

Some embodiments provide GUIs that are designed to facilitate specific types of requests. In some embodiments, the Server contains one or more web Graphical User Interfaces (GUIs). In some embodiments, one or more GUIs initiate test requests with user-configurable parameters. In some embodiments, one or more GUIs are configured to perform CRUD (Create/Read/Update/Delete) operations against Domain elements stored in the Server database.

FIG. 16 shows a DER Program GUI that is used to create a DER Program according to some embodiments. In some embodiments, the system sends notifications to all end devices that share the Function Set Assignment of the DER Program and/or have subscribed to the DER Program Resource.

FIG. 17 shows a DER Curve GUI configured to set the points of a DER Curve. In some embodiments, once the GUI is created, it is associated with a specific DER Program.

FIG. 18 shows a DER Control GUI configured to set the points of a DER Curve. In some embodiments, once the GUI is created, it is associated with a specific DER Program.

In some embodiments, the Server makes available a web service API configured to receive an external DNP3 request from the RT SCADA (Real-Time Supervisory Control and Data Acquisition) system for a remote electrically controlled device being managed by a Client. In some embodiments, the web service receives and interprets the inbound DNP3 message from the RT SCADA to determine which IoT router is hosting the device for which the message is intended. In some embodiments, the message is then forwarded to the Client on the appropriate IoT router either as the original DNP3 message via the DNP3 interface or via an IEEE 2030.5 Subscription Notification message depending on the desired OTA protocol. In some embodiments, the Server logs details for the inbound request and performs any necessary translation required before forwarding the request to the proper Client.

In some embodiments, the system includes at least one IEEE 2030.5 interface. In some embodiments, the Server supports all IEEE 2030.5 specification model elements and processes required to support one or more remote electronics.

In some embodiments, the system includes one or more RESTful Web Services (REST stands for Representational State Transfer, and RESTful Web Services are web services that are REST based). In some embodiments, IEEE 2030.5 specifications are described in the IEEE 2030.5 standard. In some embodiments, the Server implements a REST-based web service model conforming to the WADL and XSD provided with the specification. In some embodiments, Uniform Resource Identifiers (URIs) are used to make HTTP requests to the Server. In some embodiments, URIs also conform to the specification standards including those used for performing queries as defined in Section 6.6.1.

In some embodiments, the system includes one or more security methods and/or technologies. In some embodiments, IEEE 2030.5 requires one or more processes and technologies to provide security at the application layer. In some embodiments, one or more non-limiting processes implemented in the Server include Access Control List, Device Credentials, and/or Transport Layer Security (TLS) over HTTP:

Access Control List (ACL): The ACLs are configured on the server to grant/deny access to specific services by multiple criteria including down to a specific client/device according to some embodiments.

Device Credentials: The server supports electronic device authentication by all of the IEEE 2030.5 standard identifiers (SFDI/LFDI) requiring hashing of the device certificate and the optional PIN code according to some embodiments.

TLS over HTTP: Both Server and Client support TLS over HTTP using the required cipher suite elliptic curve secp256r1 according to some embodiments.

In some embodiments, the system includes Discovery. In some embodiments, the server responds to any IEEE 2030.5 client discovery requests made to the server's Device Capabilities Resource as described in the IEEE 2030.5 specification. In some embodiments, based on the server's ACL configuration and the device making the request, the Device Capabilities response contains the URI's for the Resources for which the device is allowed access.

In some embodiments, the system includes Registration. In some embodiments, In IEEE 2030.5, End Device Registration is facilitated by out-of-band communication of the End Device's SFDI and an optional PIN. In some embodiments, the Server supports persisting of these in advance of an IEEE 2030.5 Client's initial discovery or Resource request.

In some embodiments, the system includes Resources and Functions Sets. In some embodiments, The IEEE 2030.5 specification groups associated data model objects (“Resources”) and functions (“Function Sets”) into three Resource groups called Support, Common, and Smart Energy. In some embodiments, all the supported Resources and Function Sets are persisted to the database and entries for each are viewable and editable through a web-based interface by any user with administrative rights. In some embodiments, the system includes the Resources and Function Sets listed in Table 3:

TABLE 3
Resources and Function Sets

| | | |
|---|---|---|
| Support | Device Capabilities | Used to communicate to a device what |
| | | information it is allowed to access on the |
| | | Server. |
| | Self Device | Used to communicate information about the |
| | | Server itself. |
| | End Device | Used to communicate information about End |
| | | Devices between the Server and Client. |
| | Function Set Assignments | Labels used to group End Devices for the |
| | | purposes of targeting them for execution of |
| | | Function Sets. |
| | Subscription/Notification | Resources for a device to subscribe to be |
| | | notified in the event changes are made to |
| | | specific Resources. |
| | Response | The Function Set used for a Client to |
| | | communicate a response to an event sent |
| | | from the Server. |
| Common | Time Function Set | The Function Set used to synchronize time |
| | | between the Server and Client. |
| | Log Event List | A list of Log Events (time-stamped, |
| | | significant events detected by the End |
| | | Device) tor the device. |
| | File Download Function | Used for download of remote files to the End |
| | Set | Device. Used to support software and |
| | | firmware update Use Cases. |
| Smart Energy | Metering Function Set | Function Set used for an End Device to report |
| | | its metering data to the Server. |
| | Metering Mirror Function | Function Set used for a “sleepy” End Device |
| | Set | to report its metering data to the Server. |
| | Demand Response Load | Function Set containing the DRLC |
| | Control (DRLC) Function | Resources: DemandResponseProgram and |
| | Set | EndDeviceControl. |
| | Distributed Energy | Function Set containing the DER Resources: |
| | Resources (DER) Function | DERProgram, DERControl, DERCurve, and |
| | Set | DERInfo. |
| Proprietary | SCADA Function Set | A proprietary Function Set designed for the |
| Extensions | | transport of SCADA commands and data. |
| | LLRP Function Set | A proprietary Function Set designed for the |
| | | transport of LLRP commands and data. |

In some embodiments, the system includes background processes. In some embodiments, the Server has one or more background processes that executes every five minutes to perform necessary IEEE 2030.5 server functions. In some embodiments, server functions include deleting Client Subscriptions that have not been renewed within a specified time (e.g., the last 36 hours (10.6.3.4)).

In some embodiments, the system includes proprietary extensions. In some embodiments, the IEEE 2030.5 specification allows for proprietary extensions to support additional, manufacturer-specific Device Capabilities and Resources. In some embodiments, Device Capabilities and Resources are used to support any Server-Client communication not defined within the 2013 version of the IEEE 2030.5 specification (SCADA, LLRP, etc.).

In some embodiments, the system includes at least one DPN3 Interface. In some embodiments, the Server DNP3 Interface is responsible for forwarding DNP3 messages from the Server to the Client DNP3 Interface. In some embodiments, the session is secured using user credentials shared between the Server and Client.

In some embodiments, the Client Technology stack includes Client software that is a web-based, Java application utilizing the java-based Groovy® dynamic language. In some embodiments, to reduce the size of the application footprint and save on processor utilization, the Client is configured directly from flat files and application data is persisted directly to the files ystem instead of using a separate database server. In some embodiments, the term “Client” should not be confused with the term “client” when used to represent an IEEE 2030.5 End Device. In some embodiments, the Client software is designed to support multiple End Devices per single instance of the Client software and IoT router hardware. In some embodiments, the Client implements conventional HTTP server design principles found in server-based systems for security and authentication including SSL/TLS and password-secured user accounts. In some embodiments, the system uses conventional third-party applications (e.g., Java: 1.8.0_144; Spring Boot: 1.5.7; Groovy: 2.4.10; Tomcat: 8.5.20).

In some embodiments, the Client includes one or more object models. FIG. 19 illustrates a basic UML diagram for objects in a Client object model according to some embodiments.

In some embodiments, the Client includes device polling. In some embodiments, the Client has a background process that is able to perform scheduled actions against the connected End Devices. In some embodiments, the process is configurable via a configuration (e.g., flat file).

In some embodiments, the Client includes at least one IEEE 2030.5 Server Interface. In some embodiments, the IEEE 2030.5 Server Interface includes Discovery. In some embodiments, to facilitate discovery of the IEEE 2030.5 Server by the Client, the Client uses one or more extensible Domain Name System (DNS) management schemes that uses XML to store data (e.g., xmDNS).

In some embodiments, the IEEE 2030.5 Server Interface includes Registration & Authentication. In some embodiments, for one or more launches of the Client process, the client performs one or more of the following standard IEEE 2030.5 functions: End Device registration process; discover the Server for the end device's allowed Device Capabilities; perform time sync of the Client with the Server; query all available Device Capabilities; and/or Subscribe to all allowed subscribable Resources and Function Sets.

In some embodiments, the IEEE 2030.5 Server Interface includes one or more scheduled processes. In some embodiments, the Client has a background process for performing one or more of the following necessary scheduled IEEE 2030.5 Client actions: issuing commands to the End Devices to perform DER Control; sending Subscription renewals to the Server; and or ending Mirrored Metering data to Server.

In some embodiments, the Client includes at least one DPN3 interface. In some embodiments, the Client DNP3 Interface is responsible for receiving forwarded DNP3 messages from the Server's DNP3 Interface and forwarding them to the appropriate End Device connected to the IoT router. In some embodiments, the Client DNP3 Interface supports physical layer connections both via TCP/IP and Serial over USB.

FIGS. 20-28 represent sequence diagrams describing the flow of interactions between the Server and Client as well as End Devices and other entities both within the IEEE 2030.5 specification framework and outside of it according to some embodiments.

In some embodiments, the sequence diagrams shown in FIGS. 20-26 apply for the processes that are governed by the IEEE 2030.5 specification. In some embodiments, they also assume physical layer connectivity has been established and do not describe other authentication steps inherent in the standard (e.g., TLS setup).

FIG. 20 shows the End Device Registration sequence and processes required for the Client to ask the Server if it has been registered and to POST its End Device information if it is not found in the Server according to some embodiments. In some embodiments, the system begins by populating the registration information in both the Client and Server through an out of band process. In some embodiments, after POST-ing the End Device details for the first time, the Client also GETs the Registration Resource to validate the device's PIN against what is stored in the server.

FIG. 21 shows the Time Sync process for the Client to request current time details from the Server for the Client to synchronize with according to some embodiments. In some embodiments, the End Device supports remote time updates and is configured to do so within the Client and the Client updates the clock of the End Device.

FIG. 22 illustrates a Subscription/Notification sequence diagram that shows the communication between Client and Server for both the process of Subscription and Notification. In some embodiments, the communication follows successful registration of the Client and querying of the available Device Capabilities and whether they are “subscribable” or not. In some embodiments, the Client then posts a list of Subscription details to the Server which the server acknowledges has been completed with an HTTP 201 message. In some embodiments, when a change occurs on the server that affects a subscribed-to Resource, a NotificationList is sent to the Client which the Client acknowledges with an HTTP 201 message.

FIG. 23 shows the Log Event process for the Client to report asynchronous event/alarm notifications to the Server. In some embodiments, the event is triggered during the Client's polling process which contains the business logic required to identify the event/alarm requiring notification. In some embodiments, the details of the alarm/event are populated into a LogEvent message and POST-ed to the Server.

FIG. 24 illustrates the Mirrored Metering process which is used for an electronic device to periodically push its device's metering data to a metering server. In some embodiments, the 2030.5 Server is also used as the Mirrored Metering Server. In some embodiments, the Client's background polling process is configured to collect the raw data from the End Device and save it on the disk storage or other storage media of the IoT router. In some embodiments, on a separate, configurable cycle, the Client forwards the raw collected data to the Server via MirrorMeterReading messages. In some embodiments, FIG. 24 also shows the messaging for creating the MirrorUsagePoint to which the meter readings are POST-ed.

FIG. 25 shows both the DER Program messaging for the Client to GET the details of a DERProgram from the Server as well as the process during the DER Event itself. In some embodiments, the business logic required to manage multiple, independent DERPrograms resides on the Client as well as the scheduler used to manage the End Device settings and notifications at the start, stop, and during a DER Event.

FIG. 26 shows both the Demand Response messaging for the Client to GET the details of a DERProgram from the Server as well as the process during the DER Event itself. In some embodiments, the business logic required to manage multiple, independent DERPrograms resides on the Client as well as the scheduler used to manage the End Device settings and notifications at the start, stop, and during a DER Event.

FIG. 27 describes the process through which SCADA (DNP3) messages flow from the RT SCADA source, through the Server and Client, to the End Device and back according to some embodiments. In some embodiments, in this sequence the DNP3 message is encapsulated in an IEEE 2030.5 message over the AMI network between the Server and Client. In some embodiments, this requires the use of the IEEE 2030.5 Proprietary Extensions which is used to provide a ‘subscribable’ Resource (e.g., SCADA) which the Client subscribes to in order to receive Notifications.

FIGS. 28 and 29 show a sequence diagram that describes the process through which SCADA (DNP3) messages flow from the RT SCADA source, through the Server and Client, to the End Device (e.g., meter assembly) and back that is not dictated by the IEEE 2030.5 specification according to some embodiments. In some embodiments, in this sequence the DNP3 message is interpreted and forwarded through a custom interface that does not use the IEEE 2030.5 protocol. In some embodiments, based on the data within the original message, the Server forwards the message to the appropriate Client which then forwards the message to the appropriate End Device.

### DESCRIPTION OF THE DRAWINGS

FIG. 1A illustrates a traditional self-contained meter.

FIG. 1B illustrates a pedestal for the meter shown in FIG. 1A.

FIG. 2A illustrates a bottom perspective view of a smart self-contained pole meter in accordance with some embodiments of the system.

FIG. 2B illustrates a perspective view of a smart pole meter and socket assembly in accordance with some embodiments of the system.

FIG. 2C illustrates a perspective view of a smart pole meter and socket assembly in accordance with some embodiments of the system.

FIG. 2D illustrates a side view of a smart pole meter and socket assembly in accordance with some embodiments of the system.

FIG. 2E illustrates a side view of a smart pole meter and socket assembly opposite to the side of FIG. 2D in accordance with some embodiments of the system.

FIG. 2F illustrates a rear view of a smart pole meter and socket assembly in accordance with some embodiments of the system.

FIG. 2G illustrates a top view of a smart pole meter and socket assembly in accordance with some embodiments of the system.

FIG. 2H illustrates a bottom view of a smart pole meter and socket assembly in accordance with some embodiments of the system.

FIG. 2I illustrates a top perspective view of a transformer-rated meter socket in accordance with some embodiments of the system.

FIG. 2J illustrates a side view of a transformer-rated meter socket/meter assembly with coupled smart meter in accordance with some embodiments of the system.

FIG. 3A illustrates an exploded assembly view of a small foot print metering solution including a transformer-rated meter socket assembly in accordance with some embodiments of the system.

FIG. 3B illustrates a bottom perspective view of smart pole meter in accordance with some embodiments of the system.

FIG. 3C illustrates a side perspective view of smart pole meter in accordance with some embodiments of the system.

FIG. 3D illustrates a cross-section and internal component view of the smart pole meter of FIGS. 3B-3C in accordance with some embodiments of the system.

FIG. 4 illustrates meter interface design in accordance with some embodiments of the system.

FIG. 5A illustrates a side view of a transformer-rated meter socket assembly in accordance with some embodiments of the system.

FIG. 5B illustrates a top view of a transformer-rated meter socket assembly in accordance with some embodiments of the system.

FIG. 6A illustrates a partially transparent internal side view of a transformer-rated meter socket assembly in accordance with some embodiments of the system.

FIG. 6B illustrates a bottom side perspective partially transparent view of a transformer-rated meter socket assembly in accordance with some embodiments of the system.

FIG. 7 illustrates a perspective view of a plunger switch attached on a socket face in accordance with some embodiments of the system.

FIG. 8 illustrates a perspective view of a plunger switch assembly in accordance with some embodiments of the system.

FIG. 9A illustrates a transformer-rated meter socket assembly in accordance with some embodiments of the system.

FIG. 9B illustrates a partially transparent transformer-rated plunger switch in accordance with some embodiments of the system.

FIG. 10A illustrates a perspective view of a smart pole system including an integrated meter system in accordance with some embodiments of the system.

FIG. 10B illustrates a pole meter system with integrated and coupled meter system options in accordance with some embodiments of the system.

FIG. 10C illustrates pole meter power system in accordance with some embodiments of the system.

FIG. 11 illustrates a system overview of infrastructure integration of smart pole meter with an EV charging station in accordance with some embodiments of the system.

FIG. 12 illustrates a system for operating a charging infrastructure using smart pole meters in accordance with some embodiments of the system.

FIG. 13 depicts a system network diagram illustrating the high-level functionality required in both the Server and Client applications according to some embodiments.

FIG. 14 depicts a Server Class UML diagram for device objects and also shows the data to be stored for the End Devices and Client IoT routers according to some embodiments.

FIG. 15 depicts a Server Class UML diagram for device objects and shows the User object and associated Roles according to some embodiments.

FIG. 16 shows a DER Program GUI that is used to create a DER Program according to some embodiments. In some embodiments, the system sends notifications to all end devices that share the Function Set Assignment of the DER Program and/or have subscribed to the DER Program Resource.

FIG. 17 shows a DER Curve GUI configured to set the points of a DER Curve. In some embodiments, once the GUI is created, it is associated with a specific DER Program.

FIG. 18 shows a DER Control GUI configured to set the points of a DER Curve. In some embodiments, once the GUI is created, it is associated with a specific DER Program.

FIG. 19 illustrates a basic UML diagram for objects in a Client object model according to some embodiments.

FIG. 20 illustrates an overview of a registration process according to some embodiments.

FIG. 21 shows an overview of a synchronization process according to some embodiments.

FIG. 22 illustrates an overview of a subscription/notification process according to some embodiments.

FIG. 23 shows an overview of a log event process according to some embodiments.

FIG. 24 illustrates an overview of a mirrored metering process according to some embodiments.

FIG. 25 shows an overview of a DER control process according to some embodiments.

FIG. 26 illustrates an overview of a DR control process according to some embodiments.

FIG. 27 illustrates an overview of a SCADA process according to some embodiments.

FIG. 28 shows a sequence diagram that describes the process through which SCADA (DNP3) messages flow from the RT SCADA source, through the Server and Client, to the End Device and back that is not dictated by the IEEE 2030.5 specification according to some embodiments.

FIG. 29 shows a sequence diagram that describes the process through which SCADA (DNP3) messages flow from the RT SCADA source, through the Server and Client, to the meter assembly and back that is not dictated by the IEEE 2030.5 specification according to some embodiments.

FIG. 30 illustrates a UC2, UC6, and UC7 field test logical architecture diagram 3000 used in conjunction with one or more Use Cases according to some embodiments.

FIGS. 31-38 show the field test logical architecture diagram 3000 sections 3001-3008 enlarged in for clarity according to some embodiments.

FIG. 39 illustrates a UC2 Field Testing Diagram according to some embodiments.

FIG. 40 shows a UC2 field test architecture diagram 4000 according to some embodiments.

FIGS. 41-44 show the field test logical architecture diagram 4000 sections 4001-4004 enlarged in for clarity according to some embodiments.

FIG. 45 illustrates a UC2 field testing diagram according to some embodiments.

FIG. 46 shows a UC6 Field Testing Architecture Diagram according to some embodiments.

FIGS. 47-51 show the field test logical architecture diagram 4000 sections 4601-4605 enlarged in for clarity according to some embodiments.

FIG. 52 shows a UC6 Field Testing Diagram according to some embodiments.

FIG. 53 is a UC7 field testing architecture diagram 5300 according to some embodiments.

FIGS. 54-58 show the field test logical architecture diagram 4000 sections 4601-4605 enlarged in for clarity according to some embodiments.

FIG. 59 is a UC7 Field Testing Diagram according to some embodiments.

FIG. 60 is a RFID Field Test Block Diagram according to some embodiments.

FIG. 61 shows Tag UML according to some embodiments.

FIG. 62 depicts Location UML according to some embodiments.

FIG. 63 illustrates sample XML Metering data according to some embodiments.

FIG. 64 shows Server and Client Function Set assignments according to some embodiments.

FIG. 65 shows IEEE 2030.5 Data Model UML-DER Curves according to some embodiments.

FIG. 66 shows Server GUIs—DER Program according to some embodiments.

FIG. 67 shows a Registration sequence diagram according to some embodiments.

FIG. 68 shows a Time Sync sequence diagram according to some embodiments.

FIG. 69 shows a Subscription/Notification sequence diagram according to some embodiments.

FIG. 70 shows a Log Event sequence diagram according to some embodiments.

FIG. 71 shows a Mirrored Metering sequence diagram according to some embodiments.

FIG. 72 shows a DER Program sequence diagram according to some embodiments.

FIG. 73 shows a DRLC Program sequence diagram according to some embodiments.

FIG. 74 shows a SCADA OTA 2030.5 sequence diagram according to some embodiments.

FIG. 75 shows a SCADA OTA HTTP sequence diagram according to some embodiments.

FIG. 76 shows an example of overlapping DER Programs from CSIP for Use Case 2 according to some embodiments.

FIG. 77 shows another example of overlapping DER Programs from CSIP for Use Case 2 according to some embodiments.

### DETAILED DESCRIPTION

Before any embodiments of the system are explained in detail, it is to be understood that the system is not limited in its application to the details of construction and the arrangement of components set forth in the following description or illustrated in the following drawings. The system is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The following discussion is presented to enable a person skilled in the art to make and use embodiments of the system. Various modifications to the illustrated embodiments will be readily apparent to those skilled in the art, and the generic principles herein can be applied to other embodiments and applications without departing from embodiments of the system. Thus, embodiments of the system are not intended to be limited to embodiments shown, but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the system. Skilled artisans will recognize the examples provided herein have many useful alternatives and fall within the scope of embodiments of the system.

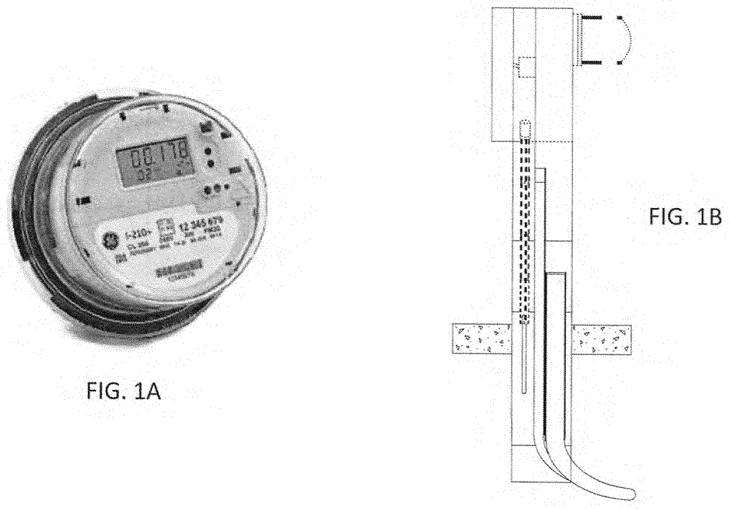

FIG. 1A illustrates a traditional self-contained meter. The meter includes a display that can show energy usage, instantaneous power, voltage, and direction of power flow (i.e., received power from a provided or delivered to a provider's grid). Meters of this type include an optical pick-up/pulse output used for programming the meter, and for testing the meter for accuracy. The meter can also include an advanced metering infrastructure (“AMI”) network communication card to remotely send energy usage back to the head-end system. The ampere rating is typically 200 A maximum continuous. Other conventional traditional meters include transformer-rated meters coupled to a transformer for power that can provide the ability to provide an ampere rating of unlimited with step down current transformers. Meters of this type can include a display that can show energy usage, instantaneous power, voltage, and direction of power flow (i.e., received power from a provided or delivered to a provider's grid). Meters of this type can also include an optical pick-up/pulse output used for programming the meter, and for testing the meter for accuracy. Meters of this type can also include an AMI network communication card to remotely send energy usage data back to the head-end system.

The attachment of traditional self-contained meters to power infrastructure is usually accomplished using a pedestal mount. For example, FIG. 1B illustrates a pedestal for the meter shown in FIG. 1A. The pedestal is bulky, requires added space, and the panel and construction cost is not insignificant.

Some embodiments of the system described herein include improvements over the traditional self-contained meters and mounting solutions described above. For example, some embodiments include an electric meter end point hardware assembly including an electric meter socket and removable or portable meter. Some embodiments include a panel socket that in some instances can be a customer-owned device. The socket provides a coupling point for at least one electric meter end point hardware assembly. For example, some embodiments include a meter socket that can function as a hub, receptacle, and/or contact point for one or more further components of an electric metering system. In some embodiments, the meter socket can contain voltage and/or current sensors. Further, the meter socket can provide DC and/or induction power supply and female connection for other metrology and communication devices such as electric, gas, water, data, etc. In some embodiments, the meter socket can include at least one standard connection known in the art, at least one of which can be replaceable. The meter socket can include sensing of AC and/or DC values of phase voltage, phase current, and phase angle.

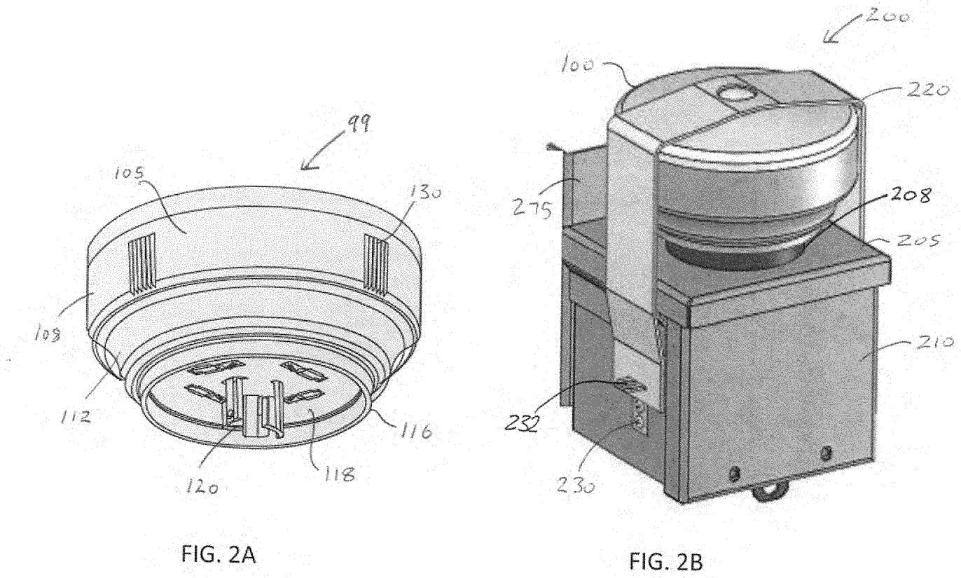

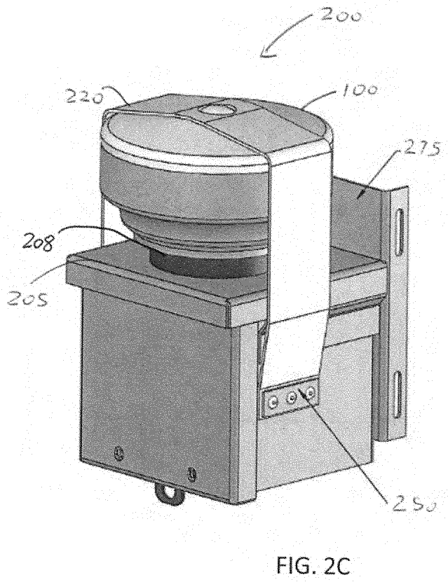

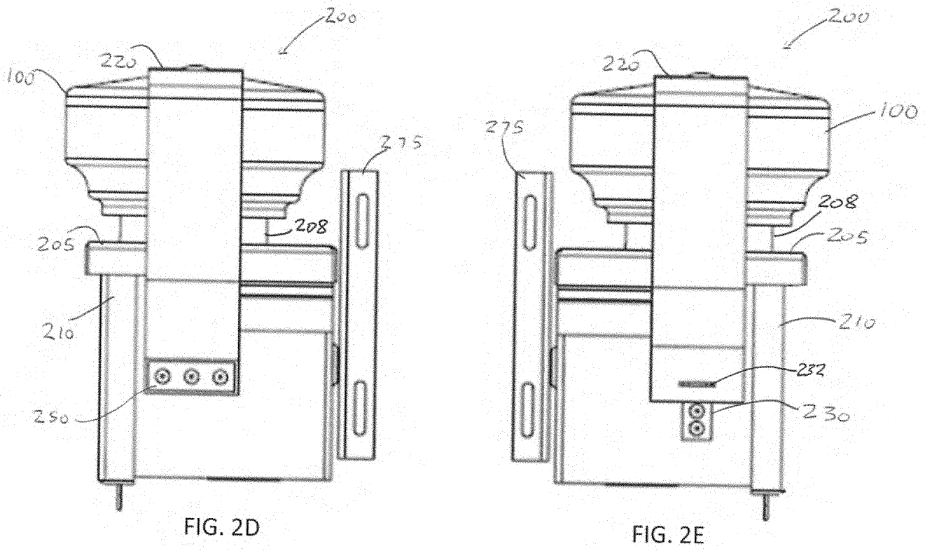

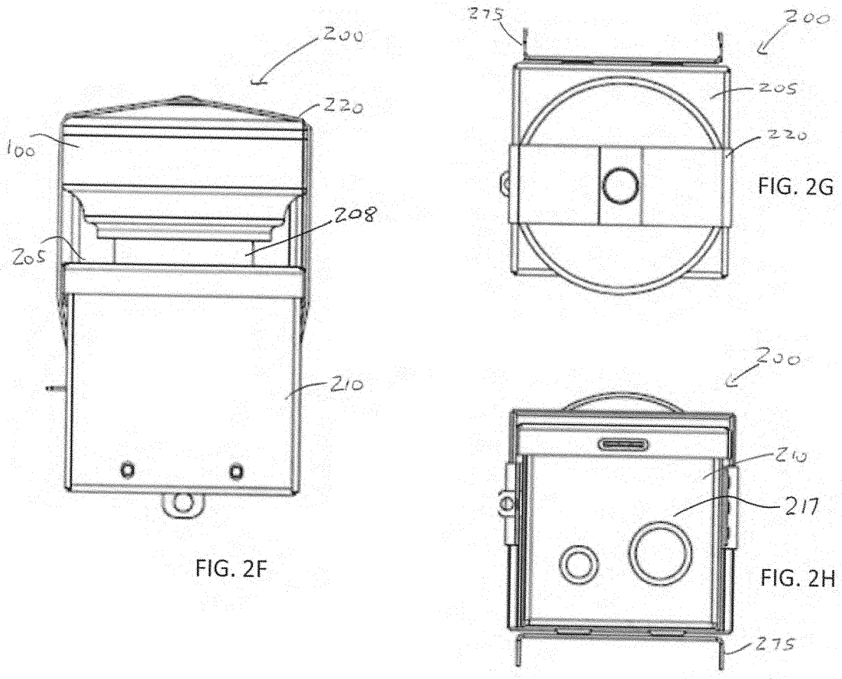

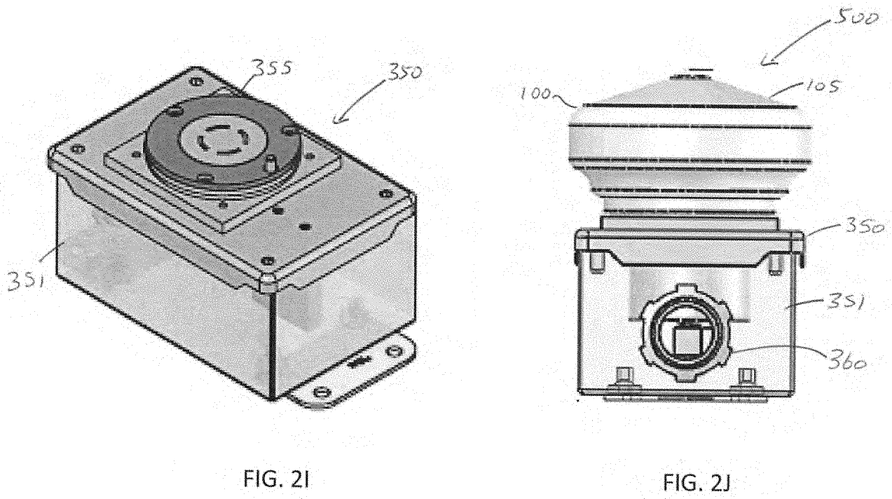

FIG. 2A illustrates a smart self-contained pole meter 99 in accordance with some embodiments of the system. In some embodiments, the pole meter 99 can comprise a meter housing 105 including an upper section 108 and a lower section 112. In some embodiments, the lower section 112 can include a receptacle side 118. In some embodiments, a rim 116 can extend from the lower section 112, circumferentially enclosing the receptacle side 118. Some embodiments include one or more plug contacts 120 extending from the receptacle side 118. Further, in some embodiments, the meter housing 105 can include one or more grills, vents, or apertures. For example, some embodiments include one or more grills, vents, or apertures 130 positioned on the upper section. In some embodiments, the meter housing 105 can include grills, vents, or apertures 130 evenly spaced around the circumference of the meter 99. Some embodiments include one or more grills, vents, or apertures 130 positioned on an opposite side than shown in FIG. 2A. In other embodiments, the one or more grills, vents, or apertures 130 can extend a partial wide of the upper section 108. In other embodiments, the one or more grills, vents, or apertures 130 can extend fully across the width of the upper section 108. In some embodiments, the one or more grills, vents, or apertures 130 can extend a partial wide of the lower section. The non-limiting embodiment shown in FIG. 2A illustrates a meter housing 105 that is generally round or circular-shaped, however other embodiments can include ellipsoidal-shaped housings, or square or rectangular housings.

FIGS. 2B-2H illustrate various perspective views of a smart pole meter and socket assembly 200 in accordance with some embodiments of the system. In some embodiments, the smart pole meter and socket assembly 200 can comprise a smart self-contained pole meter 100 coupled to a socket 210. For example, in some embodiments, the smart pole meter and socket assembly 200 can include a meter 100 plugged into or otherwise coupled to a socket interface 208 extending from a top side 205 of the socket 210. In some embodiments, the smart self-contained pole meter 100 can comprise the smart self-contained pole meter 99. In some embodiments, the smart self-contained pole meter 100 can comprise the smart self-contained pole meter 99 within the grills, vents, or apertures 130. In some embodiments, the smart self-contained pole meter 100 can comprise all of the elements of the smart self-contained pole meter 99 where the illustrations of FIGS. 2B-2H show the grills, vents, or apertures 130 missing for the purposes of illustration only. FIGS. 2B-2C illustrate perspective views of a smart pole meter and socket assembly 200 in accordance with some embodiments of the system. FIG. 2D illustrates a side view of a smart pole meter and socket assembly 200 in accordance with some embodiments of the system. Further, FIG. 2E illustrates a side view of a smart pole meter and socket assembly 200 opposite to the side of FIG. 2D in accordance with some embodiments of the system. FIG. 2F illustrates a rear view of a smart pole meter and socket assembly 200 in accordance with some embodiments of the system, and FIG. 2G illustrates a top view of a smart pole meter and socket assembly 200 in accordance with some embodiments of the system. FIG. 2H illustrates a bottom view of a smart pole meter and socket assembly 200 in accordance with some embodiments of the system. As compared to the pedestal shown in FIG. 1B, some embodiments of the adapter can comprise a compact architecture that is not stand-alone, requires minimal space, and has low construction costs.

In some embodiments, at least one hold-down strap can be implemented for securing the meter 100 to a meter socket 210. In some embodiments, a hold-down strap can be positioned over the meter 100, with each end of the strap secured to opposite sides of the socket. In some embodiments, the hold-down strap can be pre-bent to an approximate final shape for ease of installation. In some embodiments, the socket 210 can include a strap-latch for securing one end of the hold-down strap to one side of the socket 210. In some embodiments, two strap latches can be used, one positioned on each side of the meter socket. In some embodiments, the strap latch can be riveted to the enclosure of the socket. In some embodiments, a tamper-resistant seal location can be coupled to the strap latch. In some embodiments, the opposite end of the hold-down strap can be secured to the meter socket using a riveted weather sealed metal plate. In some embodiments, a pole bracket can be coupled to one side of the enclosure. The bracket can be used as an attachment structure enabling the meter socket and meter to be mounted to another structure or surface. For example, referring to FIGS. 2B and 2C, in some embodiments, the smart pole meter and socket assembly 200 includes a tie-down strap 220. In some embodiments, the tie-down strap 220 can extend over the meter 100 from one side of the socket 210 to an opposite side of the socket 210. For example, as shown in FIG. 2C, in some embodiments, the tie-down strap 220 can coupled to a plate 250 on one side of the socket 210. In some embodiments, the tie-down strap 220 can be riveted to the plate 250. In other embodiments, any conventional coupling mechanism can be used to couple the tie-down strap 220 to the plate 250.

In some embodiments, the tie-down strap 220 can extend over the meter 100 and couple to a strap-latch 230 (shown in FIG. 2B). In some embodiments, the tie-down strap 220 can be riveted to the strap-latch 230. In other embodiments, any conventional coupling mechanism can be used to couple the tie-down strap 220 to the strap-latch 230. In some embodiments, the tie-down strap 220 can comprise metal or metal alloy. In some embodiments, the tie-down strap 220 can comprise a polymer such as polyethylene. For example, in some embodiments, the tie-down strap 220 can comprise marine-grade high-density polyethylene.

In some embodiments, the strap-latch 230 can comprise a tamper-resistant seal. For example, some embodiments include a seal 232 that can be threaded through an aperture in the tie-down strap 220. The non-limiting embodiment of FIGS. 2B-2C shows a single tie-down strap 220, however any number of tie-down straps 220 can be used. Further, a single strap-latch 230 and plate 250 is shown, whereas any number of single strap-latches 230 and plates 250 can be used and positioned on the sides shown or one or more of the other sides of the socket 210. Further, the non-limiting embodiment of FIGS. 2B-2C shows a tie-down strap 220 of the width that can be increased or decreased from that shown. Further, the tie-down strap 220 can comprise or include other sections or conventional coupling elements for wrapping, coupling or attaching to the meter 100. In some embodiments, the smart pole meter and socket assembly 200 in include one or more attachment plates. For example, some embodiments include an attachment plate 275 coupled to one side of the socket 210. In some embodiments, the attachment plate 275 can be used to mount or otherwise couple the socket 210 to a structure or surface. In some embodiments, the socket 210 can include one or more apertures for coupling to electrical and/or signal wiring. For example, in reference to FIG. 2H, some embodiments include apertures 217.

In one non-limiting embodiment, the smart pole meter 99 of FIG. 2A and/or the assembly 200 of FIGS. 2B-2H can include a controller, and power parameters metered or measured with an accuracy of about 0.5%. In some embodiments, the power supply can include a universal AC input of about 85V to 264V, 50/60 Hz in some embodiment. In some embodiments, the radio controller can include a processor that can be an ARM 7 with RAM memory of 8 MB, FLASH memory of 16 MB and network parameters of about 50-300 kbps, a frequency range of about 902-928 MHz, spread spectrum frequency hopping, transmitter output of about 27-30 dBm (1 W), −98 dBm for 10% PER, and an operating protocol of 802.15.4.g.

In one non-limiting embodiment, the smart pole meter 99 of FIG. 2A and/or the meter 100 and assembly 200 of FIGS. 2B-2H can include security addressing that can be IPv6, advanced encryption standard (AES-128 or AES-256), secure hash algorithm 256-bit (SHA-256) and RSA-1024 or ECC-256, and secure NVRAM with tamper detection and key erasure. Further, some embodiments include surge protection standard: 445 Joule CATB (6 kV/3 kA), optional 700 Joule CATC (20 kV/10 kA), and the operating conditions can include a range of about −400° C. to + of 0° C./−400° F. to +1580° F., about 20% to 90% Rh non-condensing; IP66, and can be RoHS compliant. In some embodiments, web-based software can allow remote configuration, monitoring, control, and reporting.

FIG. 2I illustrates a top perspective view of a transformer-rated meter socket 350 in accordance with some embodiments of the system, and FIG. 2J illustrates a side view of a transformer-rated meter socket/meter assembly 500 with coupled smart meter 100 in accordance with some embodiments of the system. As shown, in some embodiments, the meter socket 350 can include a main housing 351 comprising an electrical box with a socket interface 355 that can provide a coupling point for at least one electric meter end point hardware assembly (e.g., meter 100). Consequently, in some embodiments, the meter socket 350 that can function as a hub, receptacle, and/or contact point for one or more further components of an electric metering system. In some embodiments, the meter 100 does not include a display. In some embodiments, the accuracy of the meter can be analyzed by polling read from an AMI network communication card configured to remotely send energy usage back to a head-end system. In some embodiments, the ampere rating can be unlimited with step down current transformers (i.e., 50:5, 100:5, 150:5, 200:5, 300:5, 400:5, 500:5, 600:5, 700:5, 800:5, 900:5, 1000:5, etc.).

In some embodiments, the smart pole meter can be coupled in close proximity to a transformer. In some embodiments, the transformer-rated smart pole meter socket can comprise an assembly that can be used to mount a transformer-rated meter, typically used in smart pole applications. In some embodiments, the assembly can comprise a current transformer with a ratio of between 50:5 and 200:5, an electrical box, a custom 4 pole meter socket with automatic current transformer (“CT”) shunt circuit, and a mounting plate, which can be adapted to any mounting hole pattern. In some embodiments of the system, the current transformer can be mounted directly to the mounting plate, above the meter socket electrical box. The CT is used to step down the service current from up to 200 A to 5 A. The 5 A secondary is required to bring the measured current down to a level suitable for the meter to measure. The electrical box houses the wiring required to get the voltage and current to the meter socket, and then to the meter. In some embodiments, the meter socket comprises a modified ANSI 19-20 twist-lock female four pole connector. The connector is physically modified on the upper section to allow clearance for the bottom face of the meter. It is also mechanically modified to allow for two redundant custom designed plunger switches to protrude through the top of the connector. The connector can be rated for 480 VAC and 20 AAC or other voltage ranges.

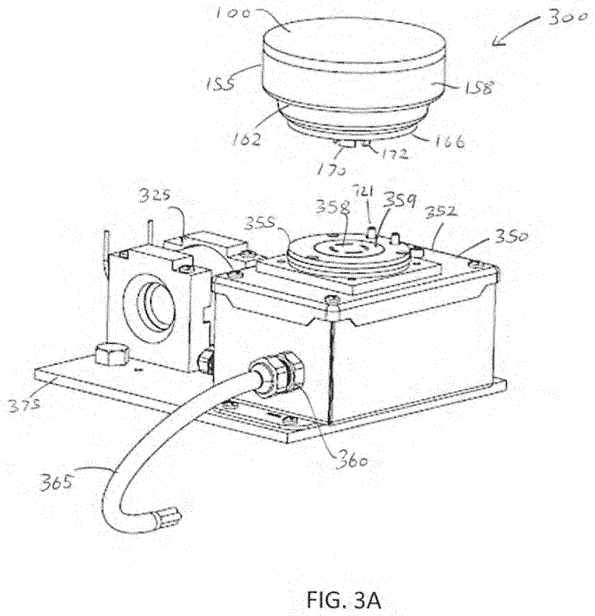

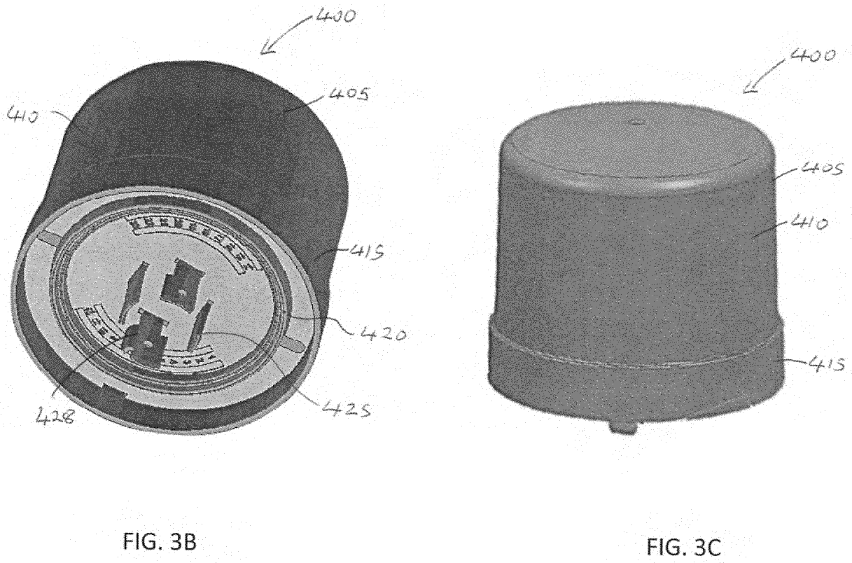

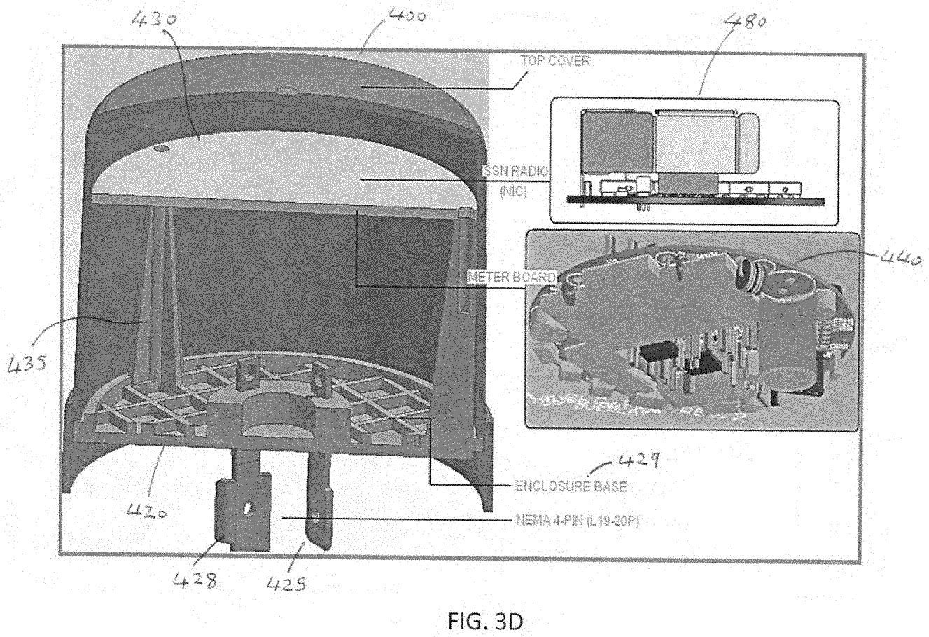

In some embodiments, an assembly, such as a meter socket assembly, can be used to mount a transformer-rated meter (e.g., such as a smart meter typically used in smart pole applications). In some embodiments, the assembly can be made up of a current transformer, having a ratio of between 50:5 and 200:5; an electrical box; a custom 4 pole meter socket with automatic current transformer shunt circuit, and a mounting plate, which can be adapted to any mounting hole pattern. In some embodiments, the current transformer can be mounted directly to the mounting plate, above the meter socket electrical enclosure. In some embodiments, the current transformer can be used to step down the service current from up to 200 A to 5 A. The 5 A secondary is required to bring the measured current down to a level suitable for the meter to measure. In some embodiments, the electrical box can house the wiring required to get the voltage and current to the meter socket, and then to the meter. In some embodiments, the meter socket can be made up of a modified ANSI 19-20 twist-lock female four pole connector. In some embodiments, the connector can be physically modified on the upper section to allow clearance for the bottom face of the meter. Further, in some embodiments, it can be mechanically modified to allow for two redundant custom designed plunger switches to protrude through the top of the connector. In some embodiments, the connector can be rated for 480 VAC and 20 AAC. For example, FIG. 3A illustrates an exploded assembly view of a small foot print metering solution 300 including a transformer-rated meter socket assembly 305 (shown in exploded assembly view with meter 100) in accordance with some embodiments of the system. In some embodiments, the meter socket assembly 305 can include a platform 375 supporting at least one transformer 325 and/or at least one socket 350. In some embodiments, the at least one transformer 325 and/or at least one socket 350 can be coupled to the platform 375. Further, in some embodiments, the meter socket assembly 305 can include a power receptacle 360 and wiring 365 coupled to the receptacle 360. In some embodiments, the meter 100 can comprise a housing 155 including an upper portion 158 coupled to a lower portion 162. Further, in some embodiments, the meter 100 can comprise a socket interface 166 and a plug assembly 170 extending from the interface 166. In some embodiments, the meter 100 can be coupled to a socket interface 355 extending from the upper housing 352 of the socket 350. For example, in some embodiments, the meter 100 can be coupled to the socket 350 by inserting one or more prongs 172 into one or more inlets 358 of an adaptor socket 359 of the socket interface 355.

In some embodiments of the system, the meter 100 can comprise the smart meter shown in FIGS. 3B-3C. For example, FIG. 3B illustrates a bottom perspective view of smart pole meter 400 in accordance with some embodiments of the system, and FIG. 3C illustrates a side perspective view of smart pole meter 400 in accordance with some embodiments of the system. In some embodiments, the meter 400 can comprise a housing 405 including an upper portion 410 coupled to a lower portion 415. Further, in some embodiments, the meter 400 can comprise a socket interface 420 and a plug assembly 425 extending from the interface 420. In some embodiments, the meter 400 can be coupled to a socket interface (e.g., such as interface 355 extending from the upper housing 352 of the socket 350). For example, in some embodiments, the meter 400 can be coupled to the socket 350 by inserting one or more prongs 428 into one or more inlets 358 of the socket interface 355.

FIG. 3D illustrates a cross-section and internal component view of the smart pole meter 400 of FIGS. 3B-3C in accordance with some embodiments of the system. In some embodiments, the interface 420 includes enclosure base 429 supporting a meter board 440 with one or more supports 435 extending from adjacent one end of the meter 400 towards the other end of the meter 400. In some embodiments, the meter board 440 can include and/or support at least one network interface card including a radio or other wireless received or transceiver (shown as 480). In some embodiments, the meter 400 can comprise a wireless single phase transformer rated (120V and 240V) “smart pole” power meter designed to measure power consumption of equipment attached to, or contained within, a streetlight pole. In some embodiments, the meter can include a “microcell” low power cellular base station or electronic vehicle charger(s). In some embodiments, data collected by the meter is transmitted back to the central management or metering system (UIQ) via a self-forming, self-healing wireless mesh network. In some embodiments, the meter is designed for greater than 15 A max using the input current from a step down current transformer (CT), rated as primary/secondary current such as 50 A/5 A. In some embodiments, the current transformer can be internally located within power sockets. In some embodiments, the “smart” meter can include four NEMA prongs to mount to the power socket, where two prongs can act as an input for line voltage, and two prongs can have input for current. In some embodiments, the two voltage inputs and two current inputs can be used solely for the purpose of metering consumption data rather than controlling equipment so output from this device is not required

Table 4 outlines the technical specifications for one embodiment of the transformer-rated meter 400 shown in FIGS. 3B and 3C.

TABLE 4
Transformer-Rated Meter Specifications

| OUTPUT | DC VOLTAGE | 3.3 V | 5 V | 12 V | 15 V | 24 V |
|---|---|---|---|---|---|---|
| | RATED CURRENT | 2.5 A | 2 A | 0.85 A | 0.67 A | 0.42 A |
| | CURRENT RANGE | 0~2.5 A | 0~2 A | 0~0.85 A | 0~0.67 A | 0~0.42 A |
| | RATED POWER | 8.25 W | 10 W | 10.2 W | 10.05 W | 10.08 W |
| | RIPPLE & NOISE | 200 mVp-p | 200 mVp-p | 200 mVp-p | 200 mVp-p | 200 mVp-p |
| | (max.) | | | | | |
| | VOLTAGE | ±2.5% | ±2.5% | ±2.5% | ±2.5% | ±2.5% |
| | TOLERANCE Note. 3 | | | | | |
| | LINE REGULATION | ±0.3% | ±0.3% | ±0.3% | ±0.3% | ±0.3% |
| | LOAD REGULATION | ±0.5% | ±0.5% | ±0.5% | ±0.5% | ±0.5% |
| | SETUP, RISE TIME | 600 ms, 30 ms at Full load | | | | |
| | HOLD UP TIME | 30 ms/230 VAC 8 ms/115 VAC at Full load | | | | |
| | (Typical) | | | | | |
| INPUT | VOLTAGE RANGE | 85~264 VAC 120~370 VDC | | | | |
| | FREQUENCY RANGE | 47~440 Hz | | | | |
| | EFFICIENCY (Typical) | 74% | 77% | 82% | 82% | 82% |
| | AC CURRENT (Typical) | 0.25 A/115 VAC 0.15 A/230 VAC | | | | |
| | INRUSH CURRENT | COLD START 20 A/115 VAC 40 A/230 VAC | | | | |
| | (Typical) | | | | | |
| | LEAKAGE CURRENT | <0.25 A/240 VAC | | | | |
| PROTECTION | OVERLOAD | 115%~190% rated output power | | | | |
| | | Protection type: hiccup mode, recovers automatically after fault condition is removed | | | | |
| | OVER VOLTAGE | 3.8~4.95 V | 4.75~6.75 V | 13.8~16.2 V | 17.25~20.25 V | 27.6~32.4 V |

| | | |
|---|---|---|
| | | Protection type: Shut off o/p voltage, clamping by zener diode |
| ENVIRON- | WORKING | −30~+70° C. (Refer to “Derating Curve) |
| MEN | TEMPERATURE | |
| | WORKING HUMIDITY | 20~90% RH non-condensing |
| | STORAGE | −40~+80° C., 10~95% RH |
| | TEMPERATURE, | |
| | HUMIDITY | |
| | TEMPERATURE | ±0.03%/° C. (0~50° C.) |
| | COEFFICIENT | |
| | VIBRATION | 10~500 Hz, 5G 10 min/1 cycle, period for 60 min, each along X, Y, Z axis |
| SAFETY & | SAFETY STANDARDS | UL60950-1, TUV EN60950-1 approved |
| EMC | WITHSTAND | I/P-O/P: 3 KVAC |
| | VOLTAGE | |
| | ISOLATION | I/P-O/P: 100M Ohms/500 VDC/25° C./70% RH |
| | RESISTANCE | |
| | EMC EMISSION | Compliance to EN55022 (CISPR22) Class B, EN61000-3-2, -3 |
| | EMC IMMUNITY | Compliance to EN61000-4-2, 3, 4, 5, 6, 8, 11 EN55024, heavy industry level (Surge L-N: 1 KV), criteria A |
| OTHERS | MTBF | 1495.8 KHrs min. MIL-HDBK −217 F. (25° C.) |
| | DIMENSIONS | 47.7*25.4*21.5 mm (L*W*H) |
| | PACKING | 0.04 Kg: 270 pcs//11.8 Kg/0.97 CUFT |

In some embodiments, the meter 400 can be configured for remote monitoring enabling an RF network to send captured meter data back to a central monitoring system. In some embodiments, the meter 400 can include a NIC 451 board from Silver Spring Networks, Redwood City, Calif. In some embodiments, the smart pole meter 400 can include a network communication card to remotely send energy usage back to a head-end system (e.g., such as a network communication card from American Megatrends, Inc.)

In some embodiments, the meter 400 can include power metering. In some embodiments, the meter 400 can monitor electrical parameters such as current, voltage, frequency, power factor, kW and kWh with an accuracy of 0.2%. For example, some embodiments include an on-chip metering engine that can provide a value to the NIC 451 board upon request. Some embodiments include instant power measurement where the meter starts measuring power parameters the moment it is powered on. Some embodiments include over-the-air upgrade capability, where the meter's host controller firmware can be upgraded over the air. In some embodiments, the meter's microcontroller can be a 16-bit microcontroller with the following specifications: a modified “Harvard Architecture” with up to 16 MIPS operation @ 32 MHz, 8 MHz internal oscillator, 4× PLL option, multiple divide options, 17-bit×17-bit single-cycle hardware, fractional/integer multiplier, 32-bit by 16-bit hardware divider, 16×16-bit working register array, C compiler optimized instruction set architecture, 76 base instructions, flexible addressing modes, linear program memory addressing up to 8 Mbytes with unlimited number of ota-programmable data channels until memory is exhausted, linear data memory addressing up to 64 Kbytes with unlimited number of OTA-programmable data channels until memory is exhausted, and two address generation units for separate read and write addressing of data memory.

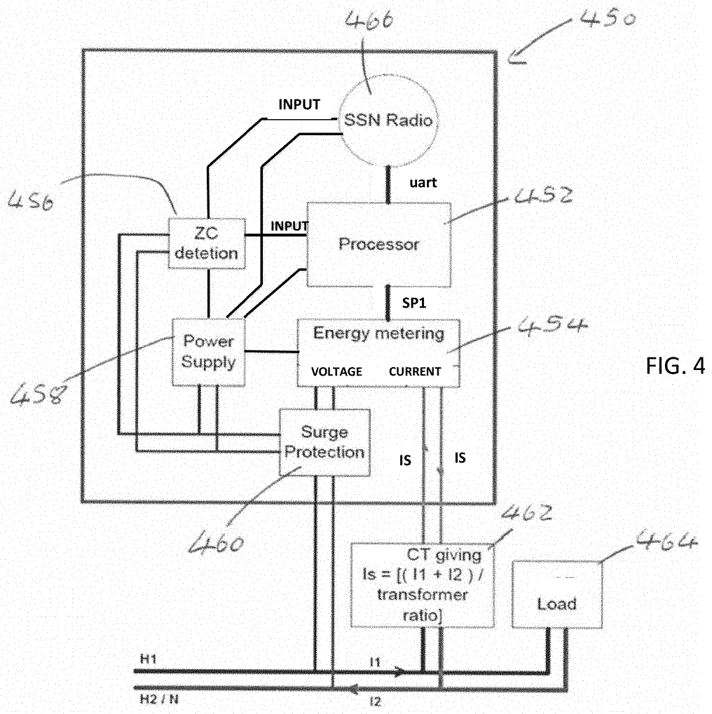

FIG. 4 illustrates meter interface design 450 in accordance with some embodiments of the system. In some embodiments, the design 450 includes a circuit comprising processor 452, “SSN radio” 466, power supply 458, ZC detection 456, energy metering 454, surge protection 460, CT input 462, and load 464. In some embodiments, the NIC 451 board couples directly to a standard physical interface to the meter's 16-bit processor through a universal asynchronous receiver/transmitter (“UART”). In some embodiments, there is buffer between UARTs of both SSN & processor. ZC signal (detection 456) can be derived from 50/60 Hz AC supplies by use of opto-isolator. This physical interface/pin can be used for other third party telecommunication modules provided all its connection details match to 12-pin connector of SSN in terms of power, signal levels, voltage levels, mechanical pin sequence & any other characteristics. In some embodiments, there are 4-pins as per the L19-20P, out of which two will be for the voltage input and two will be for the current input. In some embodiments, voltage input can be single phase 240 VAC or dual phase split type supply. In some embodiments, two current pins can receive output of current transformer. In some embodiments, the smart pole meter 400 does not include a display, although a display can be included as required or specified by a user. In some embodiments, the ampere rating can be 15 A maximum continuous.

In some embodiments, a transformer-rated pole meter socket and transformer assembly can include a CT shunt circuit. The purpose of this mechanism is to allow for the safe removal of the meter from the socket. If this circuit were not in place, dangerous voltages could be present at the socket/meter connection at the point of first contact breakage (up to 4800V), caused by an open CT secondary. In normal socket based meter applications, this function is performed with mechanical test switches. In some embodiments, the CT shunt circuit can comprise two redundant plunger switches, each of which are spring loaded to allow an plunger actuator shaft to protrude through the top of the connector housing and make contact with the plastic base of the meter. In some embodiments, when the meter is seated into the connector, the plunger switch actuators can be pushed into the switch assembly, causing the springs to be compressed. In some embodiments, the actuator motion can cause machined cams in the shaft of the plunger to be pushed down and off spring loaded roller arms on two redundant electrical switches. In some embodiments, as the cams move off the roller arms of the switches, the contacts on the two switches can move from a closed to an open state. In some embodiments, the switch contacts are wired in parallel for redundant safety purposes. In some embodiments, when the switch contacts open, current can flow from the CT secondary to the meter current elements. In some embodiments of the system, when the meter is being removed (e.g., by an electrical technician), the technician will first rotate the meter, and then lift the meter up and out of the socket. As the meter is raised off the top face of the connector, but before the connector contacts of the meter disengage from the contacts of the meter socket, the plunger cam can move up to the point where the roller arms of the switches are pushed back to the position that causes the switch contacts to close, shunting the secondary current from the CT safely to ground.

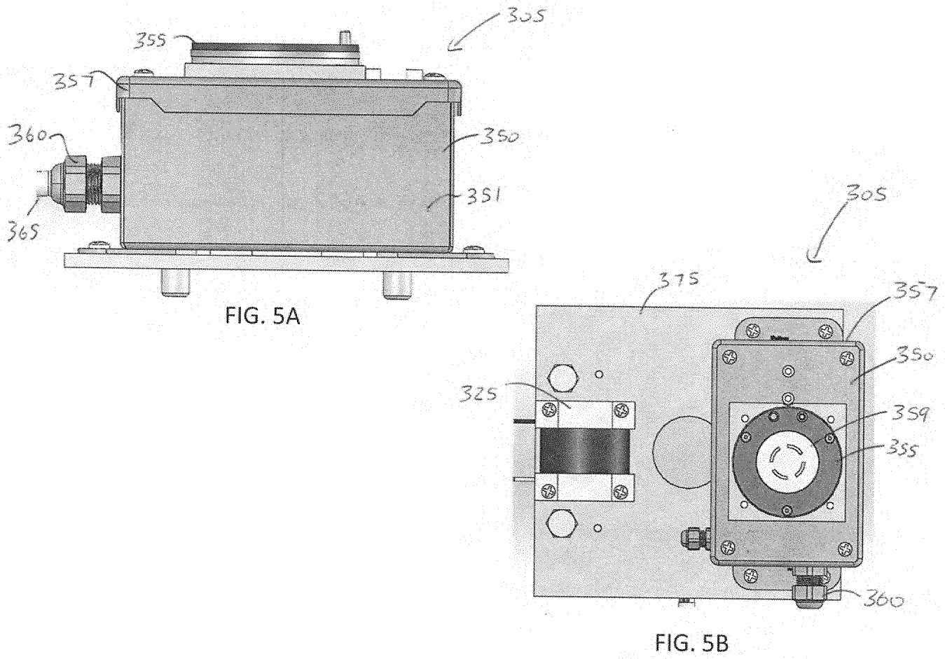

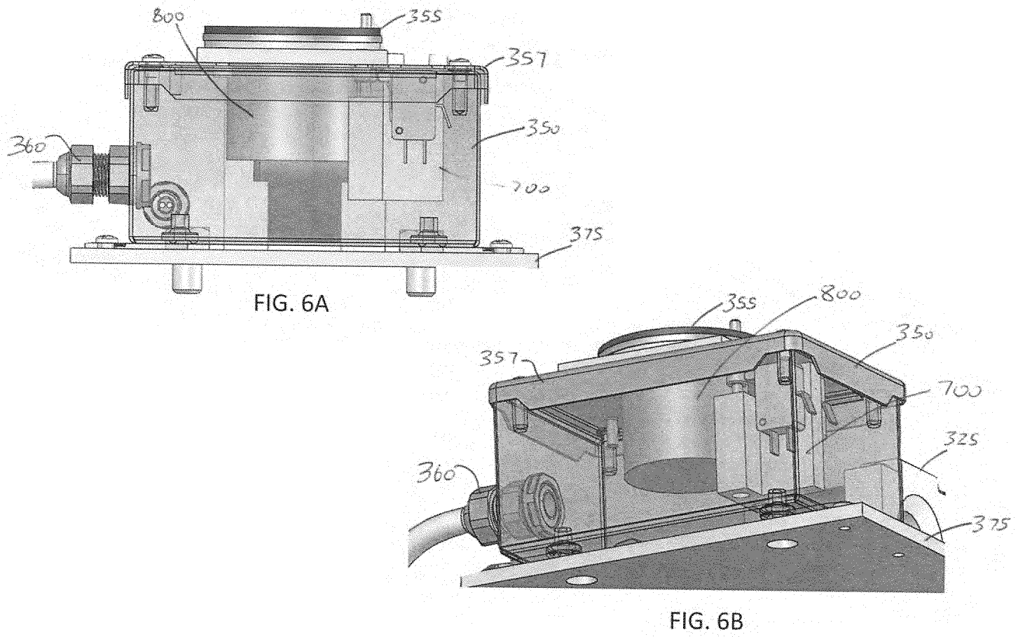

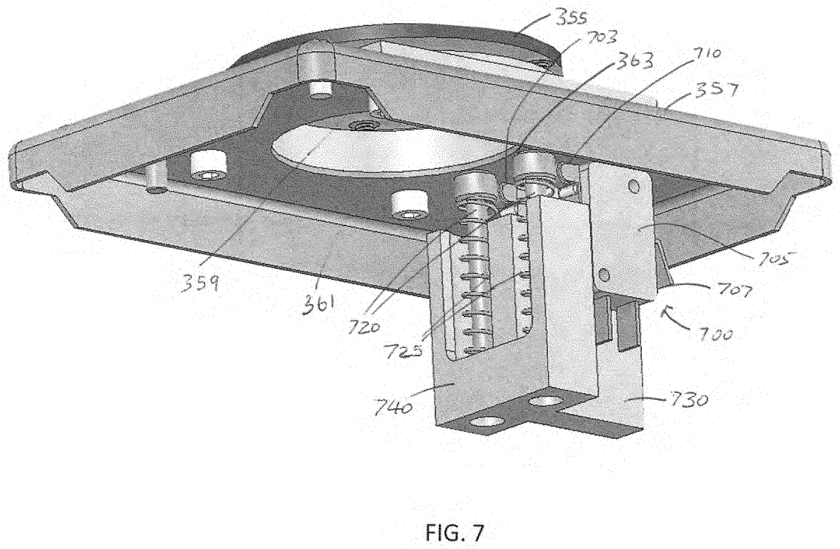

Referring to FIG. 5A, illustrating a side view of a transformer-rated meter socket assembly 305 in accordance with some embodiments of the system, the transformer-rated pole meter socket 350 is shown coupled to the platform 375, with power receptacle 360 and wiring 365 coupled to the receptacle 360 coupled to one end of the main housing 351 which houses the wiring required to get the voltage and current to the socket interface 355. Further, FIG. 5B illustrates a top view of a transformer-rated meter socket 350 in accordance with some embodiments of the system, and FIG. 6A illustrates a partially transparent internal side view of a transformer-rated meter socket 350 in accordance with some embodiments of the system. In some embodiments, the socket interface 355 includes an adapter socket 359 at one end of a secondary housing 800 including a CT shunt as discussed above. (See FIGS. 7-8, and 9A-9B below for descriptions related to components of the secondary housing 800 and CT shunt.) FIG. 6B illustrates a bottom side perspective partially transparent view of a transformer-rated meter socket 350 in accordance with some embodiments of the system. In some embodiments, the current transformer 325 can be mounted directly to the platform 375 at some distance from the meter socket 350 and adjacent a plunger switch assembly. In some embodiments, the transformer assembly and transformer-rated pole meter socket can be mounted closer than shown or in other orientations.

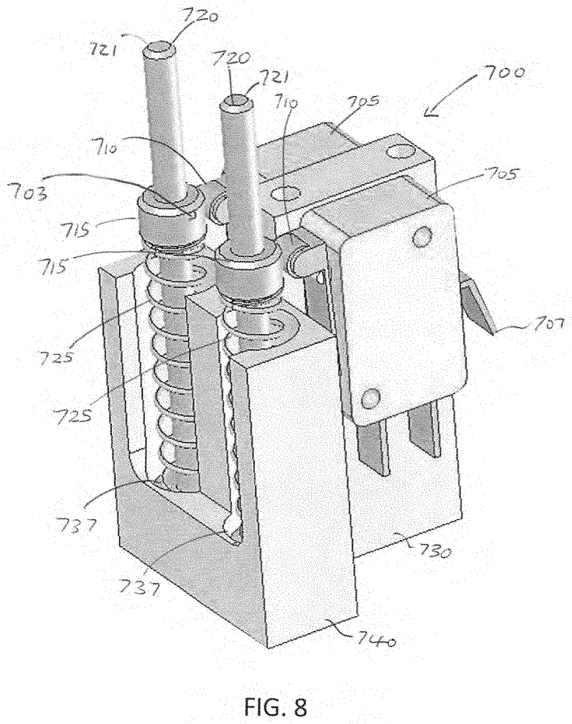

Some embodiments of the system include one or more safety devices. For example, FIG. 7 illustrates a perspective view of a plunger switch assembly 700 attached on adaptor socket 359 in accordance with some embodiments of the system. In some embodiments, the plunger switch assembly 700 can comprise components of a CT shunt circuit that can include two spring loaded plunger switches 703 comprising generally identical assemblies including plunger actuator shafts 720 configured to couple to CT shunts 705 via roller contacts 710. In some embodiments, each plunger actuator shaft 720 is positioned in a plunger housing 740 with one end supported in a cavity 737, and the opposite end 721 protruding through aperture 363 in the top housing 361 of the adapter socket 359. The plunger actuator shafts 720 are shown adjacent to shunts 705 that include electrical contacts 707 and roller contacts 710 that can couple and decouple from the plunger actuator shafts 720. For example, FIG. 8 shows plunger switch assembly 700 with roller contacts 705 in accordance with some embodiments of the system. In some embodiments, a CT shunt support 730 can extend from the plunger housing 740 that can support two CT shunts 705, each positioned on opposite sides of the CT shunt support 730. Further, each CT shunt 705 can be positioned adjacent a plunger actuator shaft 720 and can be configured to enable the roller contacts 705 to couple to and decouple from the contacts 715 of the plunger actuator shaft 720 based on force applied to the end 721 of the plunger actuator shafts 720, where each of the contacts 715 couple to and are supported by springs 725.

In some embodiments, when force is applied to the end 721 of a plunger actuator shaft 720, the plunger actuator shaft 720 can be forced towards the cavity 737 compressing the spring 725 through contact with the contacts 715. In some embodiments, when force is released or lessened from the end 721 of a plunger actuator shaft 720, the plunger actuator shaft 720 can be forced away from the cavity 737 as the spring 725 applies force to contacts 715. In some embodiments, as the meter 100 is coupled to socket interface 355 of adaptor socket 359 (e.g., see exploded assembly view of FIG. 3A), the meter 100 can mechanically couple to the plunger actuator shafts 720.

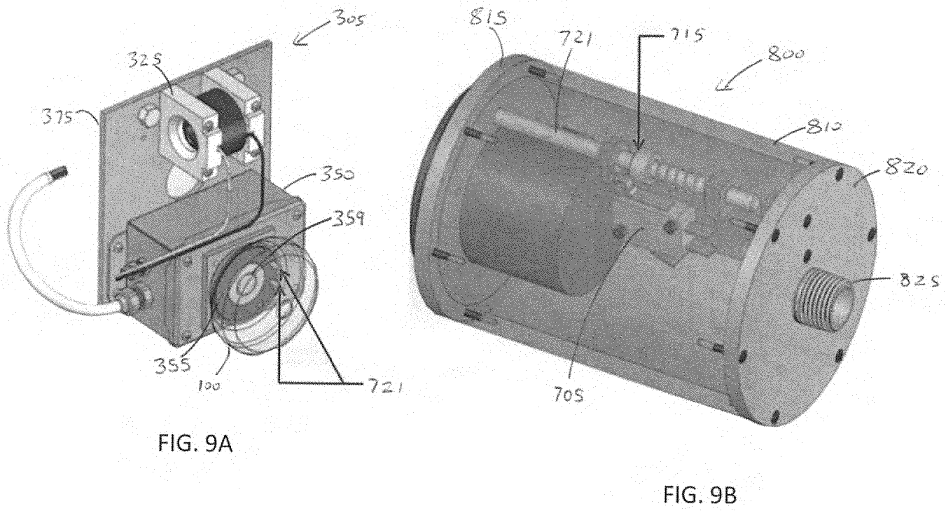

FIG. 9A illustrates a transformer-rated meter socket assembly 305 in accordance with some embodiments of the system, and shows the meter 100 as partially transparent revealing the ends 721 of the plunger actuator shaft 720 beneath the meter 100. When the meter 100 is positioned coupled to the socket interface 355, electrical current can flow to the meter 100, and when the meter 100 is separated from the socket interface 355 electricity can flow through the CT shunt 705. Further, the secondary housing 800 including CT shunts as discussed above is shown in FIG. 9B illustrates a partially transparent transformer-rated plunger switch assembly 700 in accordance with some embodiments of the system. In some embodiments, the secondary housing 800 comprising a generally cylindrical wall 810 capped by a first end 815 and a second end 820 is positioned in the transformer-rated meter socket 350 with the first end 815 supporting the adaptor socket 359, and the second end 820 adjacent the platform 375 and secured using coupler 825. During operation, in an open operation condition, the current can flow to the meter 100 when it is in normal operation. In a closed operation, current can flow safely to ground to prevent electric shock to maintenance personnel.

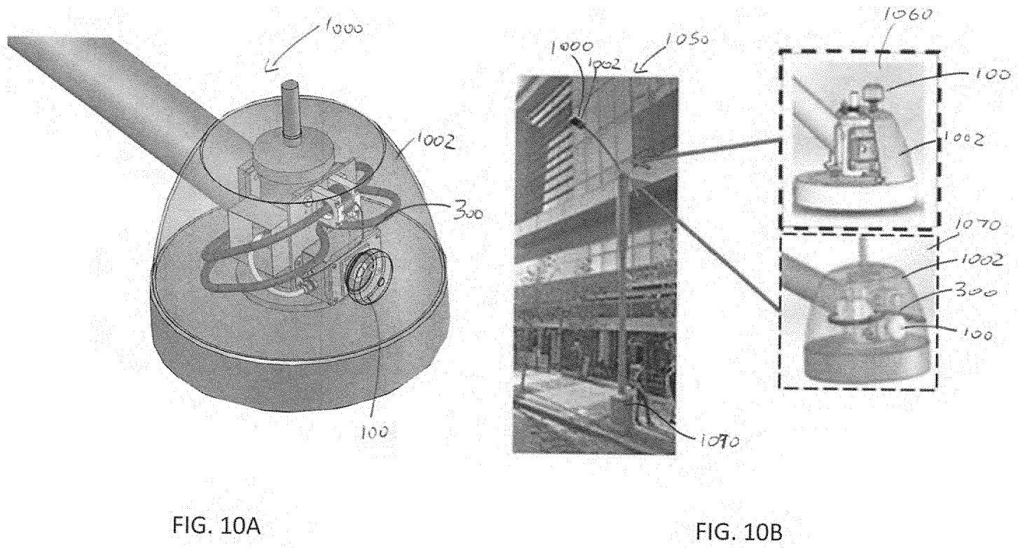

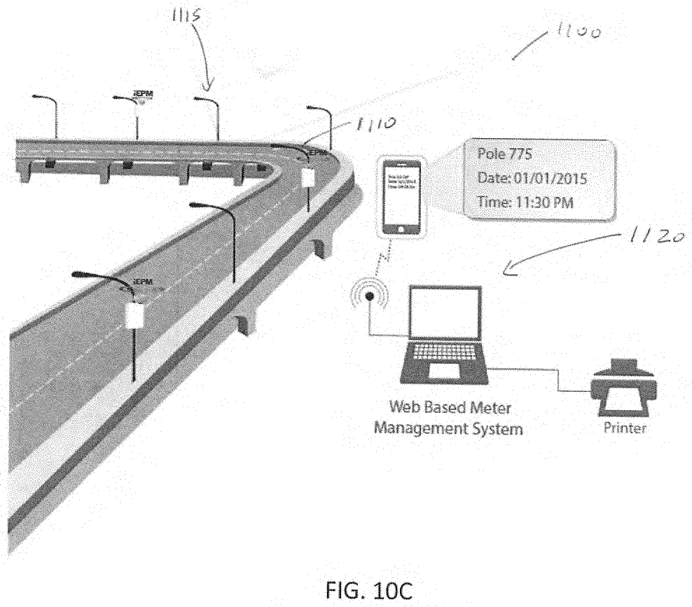

In some embodiments, one or more components, modules or assemblies of a smart pole meter system can be configured as a stand-alone unit capable of integrating externally or internally with various devices and applications. In some embodiments of the system, one or more components, modules or assemblies of a smart pole meter system can be integrated with various other systems to provide additional and augmented functions. For example, FIG. 10A illustrates a perspective view of a pole 1000 (e.g., such as a light pole) including an integrated transformer-rated pole meter system (foot print metering solution 300 including a transformer-rated meter socket assembly 305 with coupled meter 100 within the light dome 1002). Further, FIG. 10B illustrates an image 1050 showing pole meter systems including pole 1000 (e.g., such as a light pole) showing options for an integrated meter system of FIG. 10A (inset view 1070) or coupled transformer-rated pole meter system (inset view 1060). In some embodiments, power delivery or access can be coupled to the pole base 1090 and metered by the pole 1000 using foot print metering solution 300.

In some embodiments, transformer-rated pole meter systems as shown in FIGS. 10A and 10B can be utilized in other forms of infrastructure and can be integrated with an energy delivery network. For example, FIG. 10C illustrates pole meter power system 1100 including one or more poles 1110 configured for delivery and metering of power. In some embodiments, one or more web-enabled applications and/or a cloud service system 1120 can enable customer access to various metering services of a lighting infrastructure 1115. In some embodiments, data can be accessed through a web application in a desktop computer or any mobile computer and/or telecommunication device such as a smartphone.

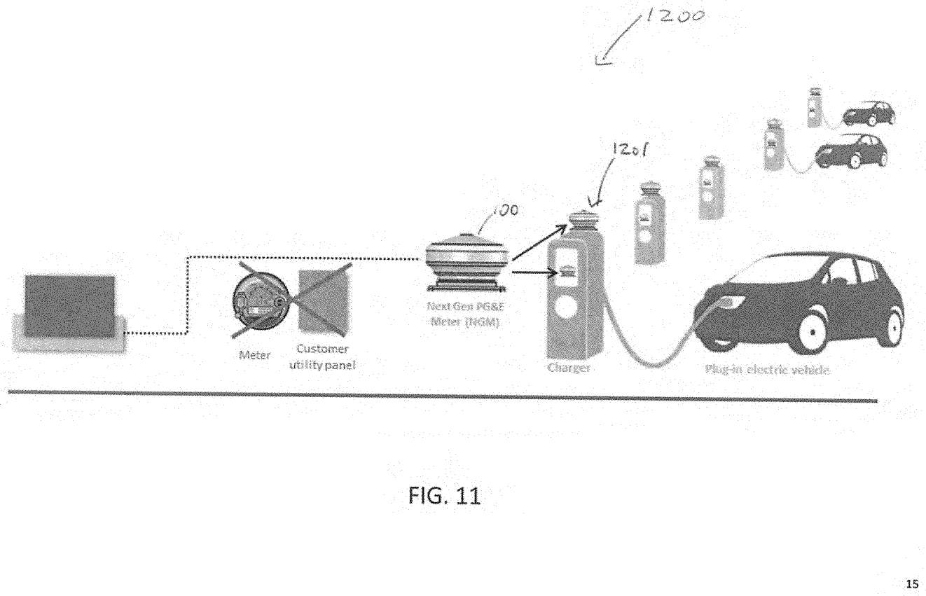

Further, FIG. 11 illustrates a system overview 1200 of infrastructure integration of smart pole meter with an EV charging stations 1201 in accordance with some embodiments of the system. In some embodiments, the system can function as a fixed, semi-permanent, or portable energy meter, enabling customers and utilities to monitor and track energy usage and operations of customer appliance/devices/vehicles and utility infrastructure operations (electric, gas, water, data, information, etc.) real-time and by location. Some embodiments of the system include a smart pole meter system functioning within an operational energy metering system and method in accordance implemented with smart poles (e.g., such as pole 1000). In some embodiments, more modules of the smart pole meter system can be installed with an infrastructure (e.g., such as a power delivery infrastructure using one or more poles 1000) and can couple to a utility data management system (e.g., by coupling to at least one computing network) as described earlier with respect to FIGS. 10B and 10C.

In some embodiments, through one or more web-enabled applications and/or a cloud service system, customer access to various metering services can be provided, including, but not limited to billing, energy (and/or gas, water, data, information, etc.) usage and statistics, current energy (and/or gas, water, data, information, etc.) use and system/device status. Once integrated or coupled to a client's infrastructure, energy use (kWh and kVARh) and operational function such as real time (or substantially real time) voltages and current, and grid awareness such as the physical location of the meter can be processed through the cloud resource linked with a utility data management system. Some embodiments can include provisions for phase voltage, current and phase angle in real (or substantially real) time. In some embodiments, computation of kWh consumption and other power metrics can be processed by cloud computing with various communication back-haul options. In some embodiments, the customer can deploy at least one smart pole energy meter at, for example, a fixed location (such as a residential or commercial building or business), and monitor any of the aforementioned parameters at the location or at a remote location using a mobile device. For example, in some embodiments, the customer can use a mobile laptop computer and/or mobile phone or smart phone to monitor at least one parameter of the energy meter. Personal digital assistants, pagers, digital tablets, or other processor-based devices can be used to access the cloud resource either through a wireless (e.g., a cellular or WiFi signal) or through a wired link coupled to the cloud resource.

In some embodiments, a customer can deploy at least smart pole meter system with a temporary or seasonal residential or commercial building or business, or with a remote charging station for an electric vehicle, and monitor any of the aforementioned parameters at the location or at a remote location. In the latter example embodiments, smart pole meter system can be used to guide customers when and where to plug in either to charge or discharge, and potentially lower operating/maintenance cost of an EV. This can enable customers and utilities to better manage EV loads (when charging) and generations (when discharging), and help lower costs of the grid construction, maintenance and operation. Thus, EVs with embodiments of the smart pole meter systems described herein can support and benefit the electrical grid system, and customers can be provided with real time charging/discharging cost and kWh quantity. Furthermore, because the cloud-based system can be managed by and/or coupled to at least one utility data management system, the system can be used to guide customers when and where to plug in either to charge or discharge based on location, charging station status, local and area-wide grid loads, etc., providing real time location based charge/discharge updates, operating with real time data on the grid. Some embodiments can include a two-way inverter safety switch for inverter application for charge/discharge.

In some other embodiments, the smart pole metering system can include a gas metering system, multi-color streetlight, electric vehicle induction charging, data and information metering systems, streetlight metering and/or telecom data metering, and vehicle telemetry. Thus the electrical outages, gas/water leakage, and usage information/data can be monitored and detected in real or near real time. Further, in some embodiments, the smart pole meter system can function as a telecommunication conduit for other services such as internet, video, TV, advertisements, etc. Moreover, in some embodiments, using customer identification information, the smart pole meter system can function as a telecommunication conduit for services (i.e., internet, video, TV, advertisements, etc.) that are tailored or targeted to the customer's needs, preferences, or geographic location. In some embodiments, the system can generate licensing fees for revenues that can help lower the customer's energy rate. Further, in some embodiments, the system can enable customers to be informed about commercial services, public safety (i.e., shopping, police, fire, hospital, etc.), and can be used to improve public and personal safety (i.e., an emergency situation, such as accidents, stranded vehicle, etc.). Some embodiments can also include electrical outage and gas/water leakage monitoring and/or call notifications and identifications. Further, some embodiments can function as or couple to telecom hubs that can provide improved bandwidth for field personnel communications and provide mobile telemetry. In some embodiments, the system can provide local, area-wide, and/or global Internet services. Further, in some embodiments, the smart pole meter system can function to provide vehicle telemetry and/or form part of a self-driving infrastructure. In some embodiments, using a combination of smart poles and/or micro cell sites, the smart pole meter system relay vehicle telemetry information, and provide remote monitoring of charge/discharge within an electric vehicle route.

Some embodiments of the system include at least one RFID module that provides tracking and asset management capability. For example, in some embodiments, the meter socket 350 and/or meter 100 can include at least one RFID module. In some embodiments, the RFID module can comprise a variety of modules types, including common RF protocols and standards. For example, in some embodiments, the RFID module can include class 1 including a simple, passive, read-only backscatter tag with one-time, field-programmable non-volatile memory. Other embodiments can utilize class 2, a passive backscatter tag with up to 65 KB of read-write memory. Other embodiments can use a class 3: a semi-passive backscatter tag, with up to 65 KB read-write memory; essentially, and with a built-in battery. Some embodiments include a class 4: an active tag with built-in battery, an internal transmitter for transmitting to the reader. Some embodiments can implement a class 5: an active RFID tag that can communicate with other class 5 tags and/or other devices. Some embodiments include RFID standards for automatic identification and item management (ISO 18000 series standards). Some embodiments of the system include an 18000-1 standard that uses generic parameters for air interfaces for globally accepted frequencies. Some embodiments can use an 18000-2 standard with an air interface for 135 KHz. Some embodiments can use a 18000-3 standard with an air interface for 13.56 MHz. In some embodiments of the system, standard 18000-4 can use an air interface for 2.45 GHz. In other embodiments of the system, standard 18000-5 with an air interface for 5.8 GHz can be used. In some other embodiments, 18000-6 with an air interface for 860 MHz to 930 MHz can be used. In some alternative embodiments, standard 18000-7 with an air interface at 433.92 MHz can be used. Some embodiments include RF components operating at a 2.4 GHz-ISM frequency band. Some embodiments include an RF system and method of operation compatible with Bluetooth® and IEEE 802.11x within a mobile device. Bluetooth is a registered trademark owned by Bluetooth® SIG.

In some embodiments, the meter socket 350 and/or meter 100 can be equipped with various radio frequency communication technologies that can switch between, receive and provide, including but not limited to, Cellular 4G/LTE, WiFi, WiMAX, WiSun, 400 MHz RF, 900 MHz RF, etc. In some embodiments of the system, the meter socket can be replaceable, interchangeable and/or upgradeable depending on the energy needs and requirements of the customer or the utility company. For example, some embodiments of the system also include an RF module that can provide sub-metering and communication interconnections between sub-meters and main meters, and interconnectivities with other sub-meters. Moreover, in some embodiments of the system, the system can provide services such as Internet, home phone, TV, and video. In some embodiments, the RF module can be coupled to a fixed energy meter. For example, in some embodiments, the RF module can be mounted or otherwise coupled to a fixed energy meter. In some other embodiments, the RF module can be mobile and not mounted or otherwise physically coupled to an energy meter. In some embodiments, the RF module can be removably mounted or coupled to an energy meter. In some embodiments, when the RF module is mounted or coupled to the energy meter, information can be transferred between the energy meter and the RF module. In some embodiments, a user can move the RF module to within a specific distance from the energy meter to enable transfer of information between the RF module and the energy meter. The specific distance includes distances that are known in the art for RF data transmission distances for known RF standards.

In some embodiments, the energy and data/information metering system can include an energy and data/information meter including at least one sensor and power supply. The system can include a socket based—ANSI (CL 200, CL20), a disconnect switch, and a communication Module with display and switchable multi-communication technologies (4G/LTE, WiFi, WiMAX, WiSun, 400 MHz & 900 MHz RF, etc.) Standard male/female pins can be used to make connection to the meter, and can comprise neutral, phase a+b+c voltage ac signals, phase a+b+c current ac signals, as well as +/−dc power supply connections to electric, gas, water, data/information meters/metering systems. The system can be modular and enable mobility, and be configured for multi-network and cloud computing (described earlier). Further, the energy meter can include an internal-meter temperature monitoring system. When coupled to the cloud system, billing information can be processed and billing data transferred to the utility MDM. The system can be utilized across a wide variety of application including fixed premises, circuit breakers, appliances, EVs, PVs, electric charging stations, battery storage, Microcell Tower/Pole, etc., capable of monitoring phase voltage, current and angle real time. In some embodiments, the system can provide hotspot services (Internet, home/car/cell phone, TV, Video, etc.) In some embodiments, the voltage and current sensors of the system can include potential and current transformers and/or Hall Effect technology. In some embodiments, the system can implement a 200 Amp disconnect switch for residential systems, and an AC/DC power supply for utility block. Standard male/female pins can be used to make connection to the block: Neutral, Phase A+B+C voltage AC signals, Phase A+B+C current AC signals, AC or +/−DC Power Supply.

In some embodiments of the system, any of the meters or assemblies described herein can be mounted or coupled to multiple applications such as buildings, homes, appliances, circuit breakers, PVs, battery storages, EVs, charging stations, microcell tower/pole, etc. Applications can include parking lot lighting, mobile home power, residential/commercial, electric vehicle charging station at streetlight poles, photovoltaic (PV), PV inverter, distribution capacitor monitoring.

In some embodiments, any of the meters or assemblies described here can perform, provide, store, and poll/communicate/transfer routinely, on demand, and ad-hoc the telecommunication bits/bytes metrology in utility cloud computing and/or in the meter. In some embodiments of the system, power quality information voltage, current and phase angle values at a user-specified interval, and/or sampling technique on phase voltage and current wave forms can be used by the system to provide a variety of energy metrics. For example, in some embodiments, the system can calculate the energy usage, and/or interval temperature, electric energy kWh and kVARh values in a user-specified period, and/or electric service analyses and information to detect wrong meter socket installations, and/or electric service analyses and information to detect tampering and provide potential tampering leads. In some embodiments, the system can include communication that can switch between technologies or not switch (are fixed). Some embodiments include communication that can utilize and/or provide any one of telecommunication technologies as designated or programmed. In some embodiments, communications can be bidirectional between the meter and the cloud platform, and live monitoring/display can occur in the office. In some embodiments, communications frequency is user-specified in milliseconds, shorter, or longer, on demand, ad-hoc, etc.

In some embodiments, any of the meters or assemblies described herein can assemble data for a graphical presentation of electric phase voltage and current waveforms, and provide access to display of voltage, current and phase angle values real time. Further, some embodiments can provide and store voltage, current and phase angle values at a user-specified interval, and transfer the interval data to other utility applications coupled to the network (e.g., the cloud network). Some embodiments provide a user with the capability to provide and store power quality information voltage, current and phase angle values at a user-specified interval. Moreover, in some embodiments, the system can perform sampling techniques on phase voltage and current wave forms to calculate the energy usage.

In some embodiments, any of the meters or assemblies described herein, the RF module, the RFID module and/or the meter component of the system can include one or more security protocols. For example, some embodiments include advanced encryption standard (AES). Some embodiments can include performance of cryptographic challenge and response protocols, including dynamic challenge-response protocols.

In some embodiments of the system, any of the meters or assemblies described herein can incorporate various semiconductor technologies that enable mobility metering and broadband metering within an integrated device with reduced size compared with conventional metering systems. For example, some embodiments utilize various system-on-chip technologies that can integrate a variety functions that would normally reside in separate modules and/or coupled devices. In some embodiments, the system-on-chip systems can incorporate an operating system, and a host interface along with data collection and error control processing. Further, the system-on-chip can integrate mobility and communications modules, with seamless integration with the operating system, data collection, and host interface.

Some embodiments of the energy metering system include and/or communicate with the electric meter assembly described herein and shown in FIGS. 1-12. In some embodiments, the electrical meter assembly is Use Case 1. In some embodiments, one or more components, steps, programs and/or interactions described in conjunction from one Use Case is applicable in integratable into another Use Case. In some embodiments, the system is capable of communicating with any electrical device that is able to receive, process, and return data. In some embodiments, further Use Cases pertaining to electrical devices compatible with the system are described below.

The following is an overview of the Use Cases (UCs) described herein according to some embodiments. In some embodiments, UC 2 includes DER devices (such as, but not limited to, a Smart Inverter); UC 3 includes Environmental Sensor Communication; UC 4 includes smart Thermostat Control; UC 5 includes communications and control of remote SCADA devices; UC 6 includes data acquisition and control telemetry; UC 7 includes data acquisition and control telemetry.

In some embodiments, UC 2 End Devices include SolarEdge SE5000A and Fronius Primo 5.0-1 208-240. In some embodiments, UC 2 End Device Connectivity and Protocols include MODBUS on TCP/IP over ethernet. In some embodiments, UC 2 Server-Client Communication includes IEEE 2030.5. In some embodiments, UC 2 Server Functions include UI for creation of DER Programs and sending IEEE 2030.5 Notifications to the Client.

In some embodiments, UC 2 Client Functions include Scheduled polling of devices; DER Program Management (Primacy, Overlapping Events, Randomization) and POSTing to Server of MirroredMetering and LogEvent messages. In some embodiments, UC 2 included scheduled reactive power dispatch; scheduled real power curtailment; DER curve set/change; data collection (scheduled and on demand); firmware updates; time sync; and asynchronous notifications of diagnostic, alarm, or errors on inverter.

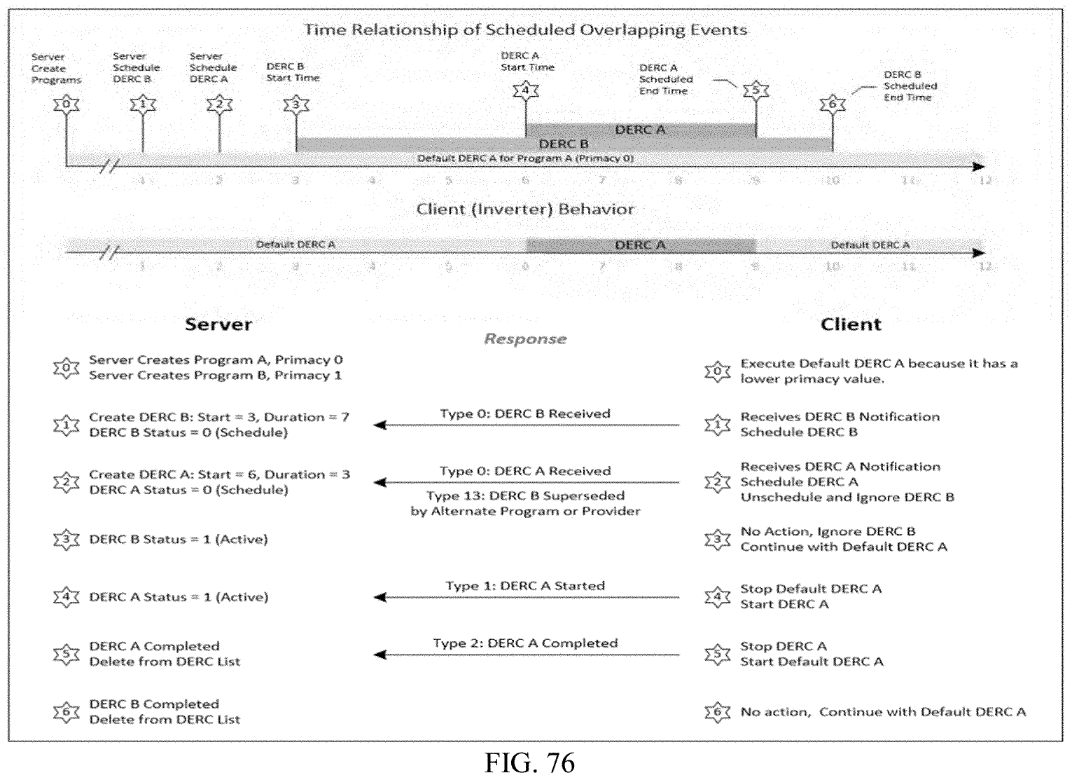

In some embodiments, FIG. 76 shows a first example of overlapping DER programs from CSIP. In some embodiments, if DERC A is scheduled before DERC B starts, DERC B is overridden (removed) entirely.

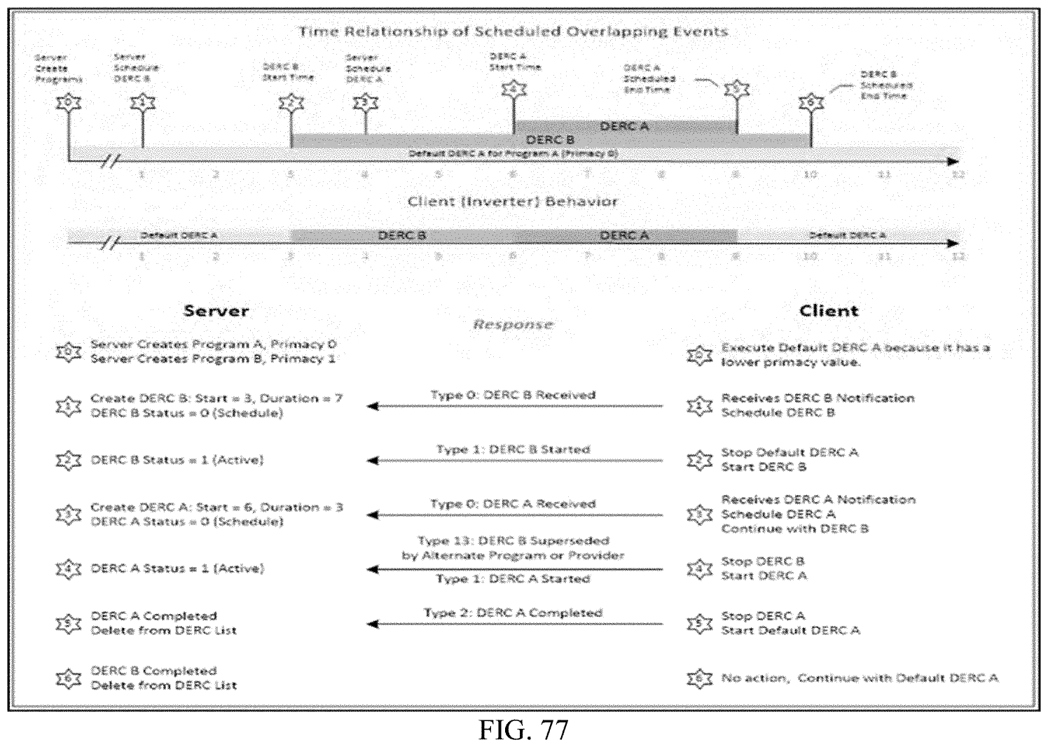

In some embodiments, FIG. 77 shows a second example of overlapping DER programs from CSIP. In some embodiments, if DERC A is scheduled after DERC B starts, DERC B is allowed to continue until DERC A starts and not resumed when DERC A ends.

In some embodiments, Use Case 2 included DER Communications. In some embodiments, For Use Case 2, the Server and Client facilitates communication between the Server and two different makes and models of Smart Inverter. In some embodiments, the primary method of reading data from and performing control on the Smart Inverter was through a MODBUS interface. In some embodiments, MODBUS register maps for each of the Smart Inverters can be found in the appendix. In some embodiments, the device details were as follows: SolarEdge SE5000A, Software ver. 3.1803; Fronius Primo 5.0-1 208-240, Software ver. 3.3.5-22. In some embodiments, each inverter was connected directly to separate IoT routers staged in the ATS lab via direct Ethernet cable. In some embodiments, the inverters were configured to either pull an IP from the IoT router via DHCP or assigned a static IP on the subnet of the IoT router. In some embodiments, each Client was configured with details for each device including the TLS certificate, PIN, and local IP address of the End Device. In some embodiments, the Server was configured with End Device details required for registration including the SFDI and PIN as well as FunctionSetAssignment associations, ACLs, and Device Capabilities. In some embodiments, with regard to End Device Protocol, all messaging to the End Device was forwarded by or translated locally within the Client to MODBUS for communication to the End Device. In some embodiments, the Client had an End Device polling process that began automatically to poll the Smart Inverter registers on a configurable schedule. In some embodiments, the polling process read, translated, and recorded to a flat file database in a plain text file from the registers. In some embodiments, the register addresses, size, and type are configurable, but by default the polling process polled the standard model SunSpec 111—Inverter registers.

In some embodiments, Use Case 2 IEEE 2030.5 Interface included Subscription/Response, DER Program/Control, Firmware Update, Metering, and/or Events. In some embodiments, upon device registration, the Client was configured to subscribe to the DER Program Function Set to receive Notifications of changes to DERPrograms that affect the End Device. In some embodiments, the Server GUI is configured to allow a user to specify the details of a DERProgram (primacy, start/end times, DERControls, FunctionSetAssignments, etc.). In some embodiments, the DERProgram details were sent to all appropriate Clients based on the FunctionSetAssignments. In some embodiments, the Clients managed the schedule of Events and issued commands to the End Devices as required. In some embodiments, End Device Firmware updates are configured to be managed by the FileDownload Function Set. In some embodiments, the firmware files were uploaded to and hosted on the Server for retrieval by the Client. In some embodiments, once the files were retrieved to the Client, they were be pushed to the End Device using a device-specific process and/or protocol. In some embodiments, the system was configured to post metering data (Voltage, Current, Power, Reactive Power, etc.) that is polled by the Client from the End Device to the Server via the Mirrored Metering Function Set. In some embodiments, polling and translation of asynchronous events (alarms, etc.) was performed against the MODBUS registers and posted to the Server via the Log Event Common Resource.

In some embodiments, Use Case 3 included Environmental Sensor Communications. In some embodiments, UC 3 End Devices include Kinemetrics (seismic); Raspberry Shake (seismic); and/or Raspberry Pi+Gas Sensor. In some embodiments, UC 3 End Device Connectivity and Protocols include HTTP/SeedLink on TCP/IP over ethernet. In some embodiments, UC 3 Server-Client Communication IEEE 2030.5. In some embodiments, Server Functions include UI to initiate commands to Sensor and to view data and/or sending IEEE 2030.5 Notifications to Client.

In some embodiments, UC 3 Client Functions include translating IEEE 2030.5 messages to SeedLink/HTTP requests and send to the End Device; polling End Device regularly to record data over time; and/or sending Notification Responses and collecting data back to Server. In some embodiments, UC 3 testing included Earthquake Sensor—Real time magnitude query; Earthquake Sensor—Telemetry (Display data collected over time); Gas Sensor—Real time gas concentration query; and/or Gas Sensor—Telemetry (Display data collected over time).

In some embodiments, for UC 3 the Server and Client was configured to facilitate communication between the Server and three different sensor End Devices. In some embodiments, the Server provided a web-based GUI for which to initiate the desired command sent to the sensor End Devices and displayed response data. In some embodiments, communication between the Server and Client used IEEE 2030.5 as the OTA protocol. In some embodiments, with regard to device details, the following were the sensor devices that were staged for testing of the environmental sensors: Kinemetrics® Etna, Raspberry Shake®; Gas Sensor (attached to Raspberry Pi®). In some embodiments, each sensor device was connected directly to an IoT router staged in the ATS lab via direct Ethernet cable. In some embodiments, each sensor device was configured to either pull an IP from the IoT router via DHCP or assigned a static IP on the subnet of the IoT router. In some embodiments, with regard to End Device protocol, all messaging to the End Devices was translated locally within the Client to HTTP for communication to the End Devices. In some embodiments, data retrieval from the seismic devices (e.g., Raspberry Shake®) was supported locally by the SeedLink® protocol. In some embodiments, each Client was configured with details for each device including the TLS certificate, PIN, and local IP address of the End Device. In some embodiments, the Server was configured with End Device details required for registration including the SFDI and PIN as well as FunctionSetAssignment associations, ACLs, and Device Capabilities. In some embodiments, the Client had an End Device polling process that began automatically to poll the sensor devices on a configurable schedule. In some embodiments, the polling process read, translated, and recorded to a flat file database data from the devices. In some embodiments, the Client process also included the business logic to identify events or conditions required to generate asynchronous alerts to the Server.

In some embodiments, Use Case 3 IEEE 2030.5 Interface included Subscription/Response and Log Events. In some embodiments, upon device registration, the Client subscribed to the Proprietary Extension for sensor communication to receive Notifications of inbound sensor commands. In some embodiments, upon communication of the sensor command to the End Device by the Client, communication back to the Server was facilitated by the Response Function Set. In some embodiments, any events or conditions identified by the Client polling process that required an asynchronous message sent to the Server was facilitated by the Log Event Function Set.

In some embodiments, Use Case 4 included Smart Thermostat Communications. In some embodiments, the UC 4 End Devices include at least one Raspberry Pi Thermostat. In some embodiments, UC 3 End Device Connectivity and Protocols include HTTP on TCP/IP over ethernet. In some embodiments, UC 3 Server-Client Communication include IEEE 2030.5. In some embodiments, UC 3 Server Functions include UI for creation of DRLC Events and sending IEEE 2030.5 Notifications to the Client.

In some embodiments, UC 4 Client Functions include translating IEEE 2030.5 messages to HTTP requests and sending to End Device; polling the End Device regularly to record data over time; and sending Notification Responses and collected data back to Server. In some embodiments, UC 4 testing includes Demand Response Functionality; Energy Efficiency Functionality (setting duty cycle and temperature set points); and/or Read device information.

In some embodiments, for UC 4, the Server and Client facilitated communication between the Server and one Smart Thermostat End Device. In some embodiments, the Server provided a web-based GUI to initiate the desired command sent to the Smart Thermostat End Device and displayed response data. In some embodiments, communication between the Server and Client used IEEE 2030.5 as the OTA protocol. In some embodiments, the Smart Thermostat devices were Honeywell® brand thermostats including T6, WiFi 9000, Lyric TH, and T5. In some embodiments, the Smart Thermostat device was connected directly to an IoT router staged in the ATS lab via direct Ethernet cable. In some embodiments, the Smart Thermostat device was configured to either pull an IP from the IoT router via DHCP or was assigned a static IP on the subnet of the IoT router. In some embodiments, all messaging to the End Devices was translated locally within the Client to a corresponding HTTP request for communication to the End Devices. In some embodiments, each Client was configured with details for each device including the TLS certificate, PIN, and local IP address of the End Device. In some embodiments, the Server was configured with End Device details required for registration including the SFDI and PIN as well as FunctionSetAssignment associations, ACLs, and Device Capabilities. In some embodiments, the Client had an End Device polling process that began automatically to poll the End Device on a configurable schedule. In some embodiments, the polling process read, translated, and recorded to flat file data from the End Device.

In some embodiments, Use Case 4 IEEE 2030.5 Interface included Subscription/Response. In some embodiments, upon device registration, the Client subscribed to the DRLC Function Set to receive Notifications of inbound Smart Thermostat commands. In some embodiments, upon communication of the DRLC command to the End Device by the Client, communication back to the Server was facilitated by the Response Function Set.

In some embodiments, UC 5 includes SCADA devices. In some embodiments, UC 5 End Devices include Form 6 Line Recloser; Intellicap 2000 Controller; and/or 5802 Underground Switch Controller. In some embodiments, UC 5 End Device Connectivity and Protocols include DNP3 on Serial over USB. In some embodiments, UC 5 Server-Client Communication include DNP3 over IEEE 2030.5 and/or DNP3 over HTTP. In some embodiments, UC 5 Server Functions include receiving and decoding DNP3 from RT SCADA and returning responses and/or wrapping and sending DNP3 message to Client and receiving responses.

In some embodiments, UC 5 Client Functions include forwarding DNP3 messages to the End Device and/or returning Response to Server. In some embodiments, UC 5 testing includes Binary points (all 3 devices); Analog points (all 3 devices); and/or Control points (all 3 devices).

In some embodiments, Use Case 5 included SCADA Communications. In some embodiments, the Server and Client facilitated communication between an instance of DC Systems SCADA management software, RT SCADA, and three different types of SCADA devices. In some embodiments, the Server performed two functions: communicating with RT SCADA via the DNP3 API and forwarding messages to the appropriate Clients. In some embodiments, SCADA communications Use Case was configured to support the use of both IEEE 2030.5 and DNP3 as the OTA protocol. In some embodiments, the following were the three SCADA device types that were staged in the TicNet lab for testing of the Use Case: Cooper Form 6 Line Recloser (Ethernet); S&C Intellicap Plus Cap Bank Controller (Serial); and S&C 5802 Underground Switch Controller (Serial). In some embodiments, Each SCADA End Device supported either serial or TCP/IP connectivity and were connected to the IoT router via a serial or Ethernet over USB cable. In some embodiments, with regard to End Protocol, all messaging to the End Device was forwarded by or translated locally within the Client to DNP3 for communication to the End Device. In some embodiments, each Client was configured with details for each device including the TLS certificate, PIN, and local IP address of the End Device. In some embodiments, the Server was configured with End Device details required for registration including the SFDI and PIN as well as FunctionSetAssignment associations, ACLs, and Device Capabilities. In some embodiments, no background processes were required for the SCADA Use Case. In some embodiments, the DNP3 API was used in the SCADA Use Case to receive DNP3 control commands from the SCADA Master software, RT SCADA.

In some embodiments, Use Case 5 IEEE 2030.5 Interface included Subscription/Response. n some embodiments, upon device registration, the Client subscribed to the Proprietary Extension for SCADA communication to receive Notifications of inbound DNP3 messages. In some embodiments, upon communication of the DNP3 message to the End Device by the Client, communication back to the Server was facilitated by the Response Function Set.

In some embodiments, UC 6 End Devices include Zebra FX9600 and/or Impinj xArray. In some embodiments, UC 6 End Device Connectivity and Protocols includes LLRP on TCP/IP over ethernet. In some embodiments, UC6 Server-Client Communication includes IEEE 2030.5. In some embodiments, UC 6 Server Functions include UI to initiate commands to RFID Reader and to view data and/or sending IEEE 2030.5 Notifications to the Client.

In some embodiments, UC 6 Client Functions Client Functions include Translating IEEE 2030.5 messages to LLRP and sending to the End Device and return Response to Server. In some embodiments, UC 6 testing include Reader Management; Radio Management; Firmware Updates; and/or retrieving tag data.

In some embodiments, Use Case 6 included RFID Reader Communications. In some embodiments, for Use Case 6 the Server and Client facilitated communication between the Server and two different RFID reader End Devices. In some embodiments, the Server provided a web-based GUI for which initiate the desired command sent to the RFID reader End Devices and for display of response data. In some embodiments, Communication between the Server and Client used IEEE 2030.5 as the OTA protocol. In some embodiments, the following were the two RFID reader devices for testing of the RFID reader Use Case: Zebra® FX9500; and Impinj® xArray. In some embodiments, each RFID reader was connected directly to an IoT router via direct Ethernet cable. In some embodiments, Each RFID reader was configured to either pull an IP from the IoT router via DHCP or assigned a static IP on the subnet of the IoT router. In some embodiments, with regard to End Device Protocol, all messaging to the End Device was translated locally within the Client to LLRP for communication to the End Device. In some embodiments, each Client was configured with details for each device including the TLS certificate, PIN, and local IP address of the End Device. In some embodiments, the Server was configured with End Device details required for registration including the SFDI and PIN as well as FunctionSetAssignment associations, ACLs, and Device Capabilities. In some embodiments, no background processes are required for the RFID Use Case.

In some embodiments, the Use Case 6 IEEE 2030.5 Interface included Subscription/Response and Firmware Update functionality. In some embodiments, End Device firmware updates were managed by the FileDownload Function Set. The files containing the firmware were uploaded to and hosted on the Server for retrieval by the Client. Once the files are retrieved to the Client, they were pushed to the End Device using a device-specific process and/or protocol.

In some embodiments, UC 7 End Devices include Bloom Energy® Storage. In some embodiments, UC 7 End Device Connectivity and Protocols include DNP3 on TCP/IP over ethernet. In some embodiments, UC 7 Server-Client Communication include IEEE 2030.5. In some embodiments, UC 7 Server Functions include receiving and decoding DNP3 from RT SCADA and return responses and/or wrapping and sending DNP3 message to Client and receiving responses.

In some embodiments, UC 7 Client Functions include forwarding DNP3 messages to the End Device and/or returning the Response to the Server.

In some embodiments, Use Case 7 included Data Acquisition and Control Telemetry Communications. In some embodiments, for Use Case 7, the Server and Client facilitated communication between an instance of DC Systems SCADA management software, RT SCADA, and a DG (Distributed Generator). In some embodiments, due to the physical size of the DG under test, only the control module of the DG was staged for testing. In some embodiments, the Server was configured to perform two functions: communicating with RT SCADA via the DNP3 API and forwarding of messages to the Client. In some embodiments, a Bloom Energy® Fuel Cell was the DG whose controller was staged for testing. In some embodiments, the DG controller was connected directly to an IoT router staged in the ATS lab via direct Ethernet cable. In some embodiments, the DG controller was configured to either pull an IP from the IoT router via DHCP or assigned a static IP on the subnet of the IoT router. In some embodiments, with regard to End Device Protocol, all messaging to the End Device was forwarded by or translated locally within the Client to DNP3 for communication to the End Device. In some embodiments, the Client was configured with details for the End Device which included the TLS certificate, PIN, and local IP address. In some embodiments, the Server was configured with End Device details required for registration including the SFDI and PIN as well as FunctionSetAssignment associations, ACLs, and Device Capabilities. In some embodiments, no background processes were required for this Use Case. In some embodiments, The DNP3 API was used to receive DNP3 control commands from the SCADA Master software, RT SCADA.

In some embodiments, the Use Case 7 IEEE 2030.5 Interface included Subscription/Response functionality. In some embodiments, upon device registration, the Client subscribed to the Proprietary Extension for SCADA communication to receive Notifications of inbound DNP3 messages. In some embodiments, upon communication of the DNP3 message to the End Device by the Client, communication back to the Server was facilitated by the Response Function Set.

Field test and non-functional requirements for one or more use cases are described further below. In some embodiments, the term “require” and its plurals, tenses, and derivatives do not denote limitations for the system and are only meant to convey that components, methods, and/or connections associated with the word “require” were included for that particular example and/or Use Case.

In some embodiments, the following section describes requirements for both the IEEE 2030.5 Server and Client software that were required to perform field testing across Use Cases: 2 (Smart Inverter), 6 (RFID), and 7 (Telemetry).

In some embodiments, the field testing occurred following the completion of successful lab testing and involved deploying the IEEE 2030.5 Server and Client software on virtual servers and IoT routers deployed with the production network. In some embodiments, two zones within the production environment (CD03) were created as follows: Pre-Test Zone: Used for end-to-end field test deployment in demonstration zone; and Demonstration Zone: Used by business owners to demonstrate business use cases.

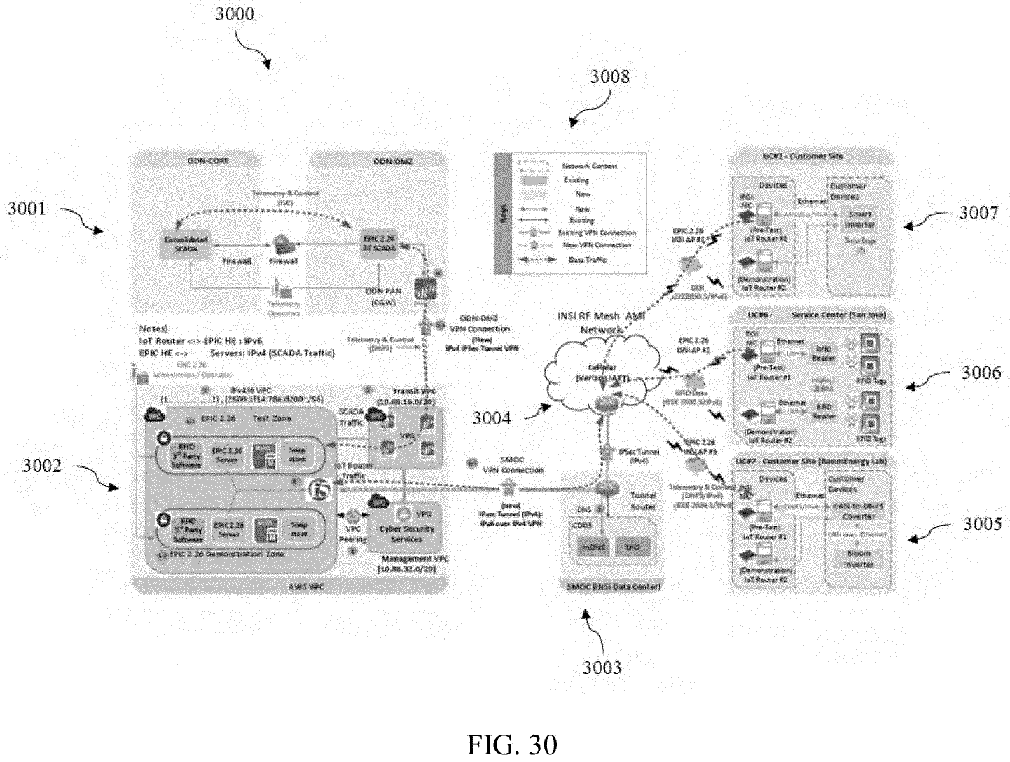

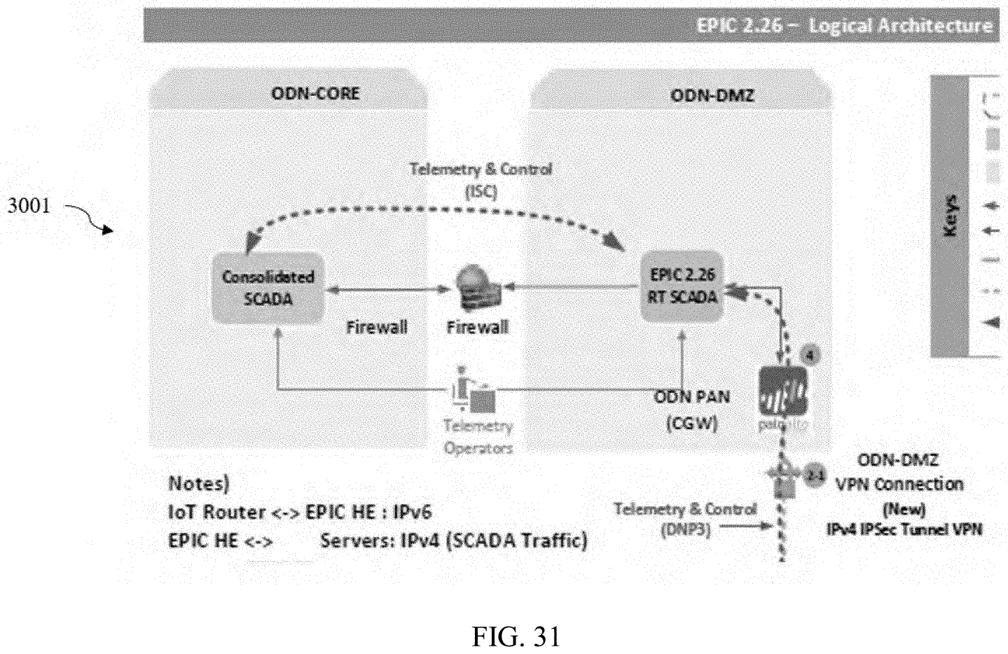

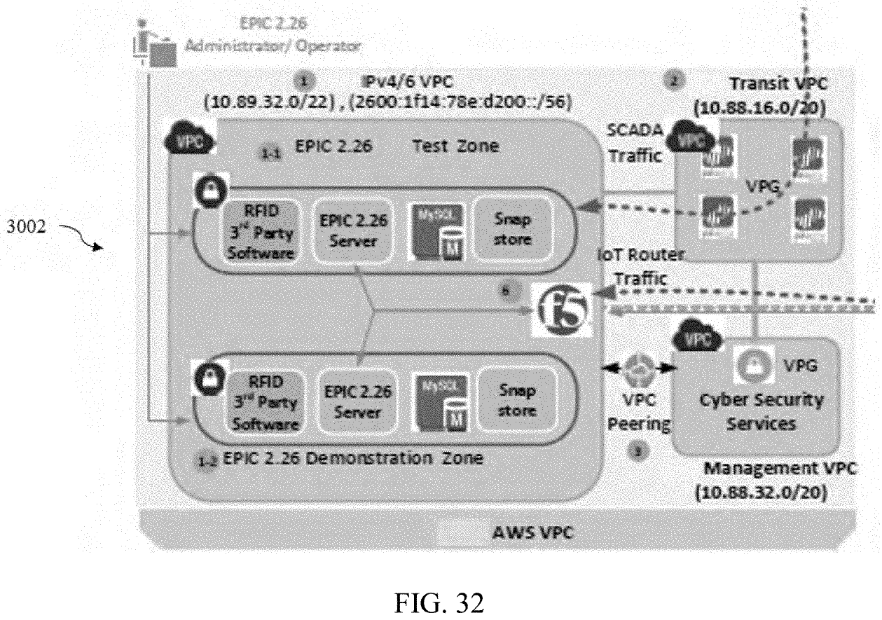

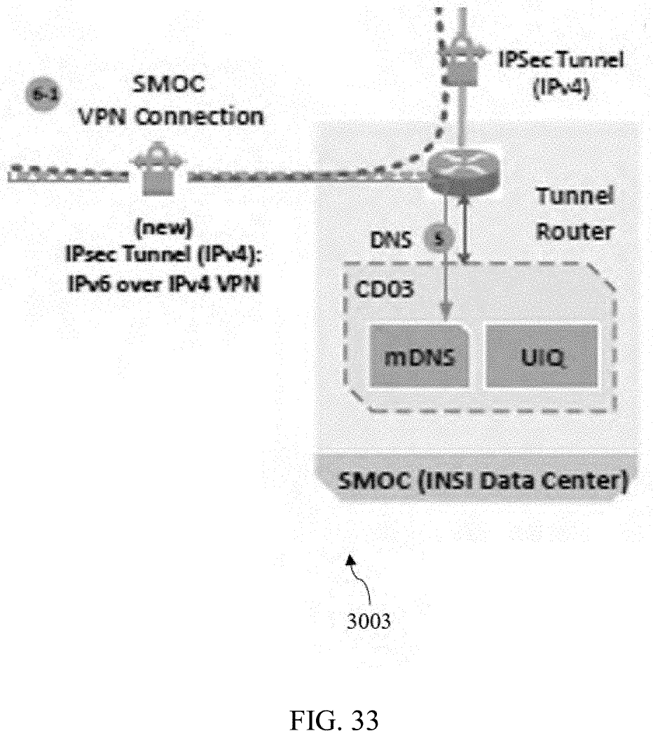

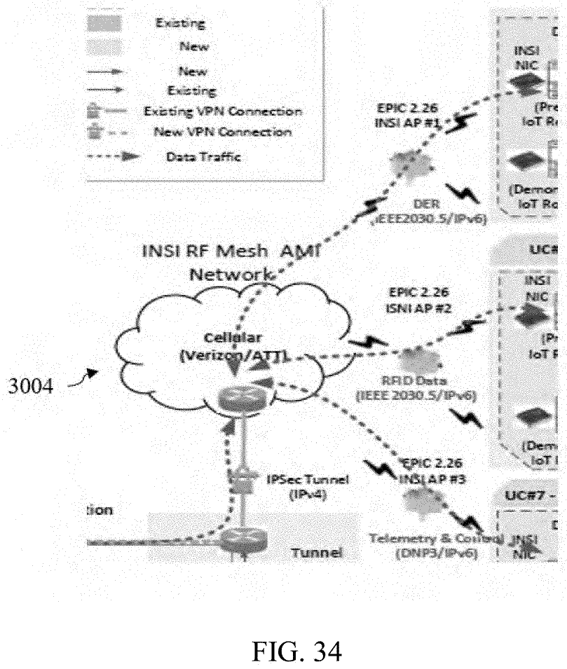

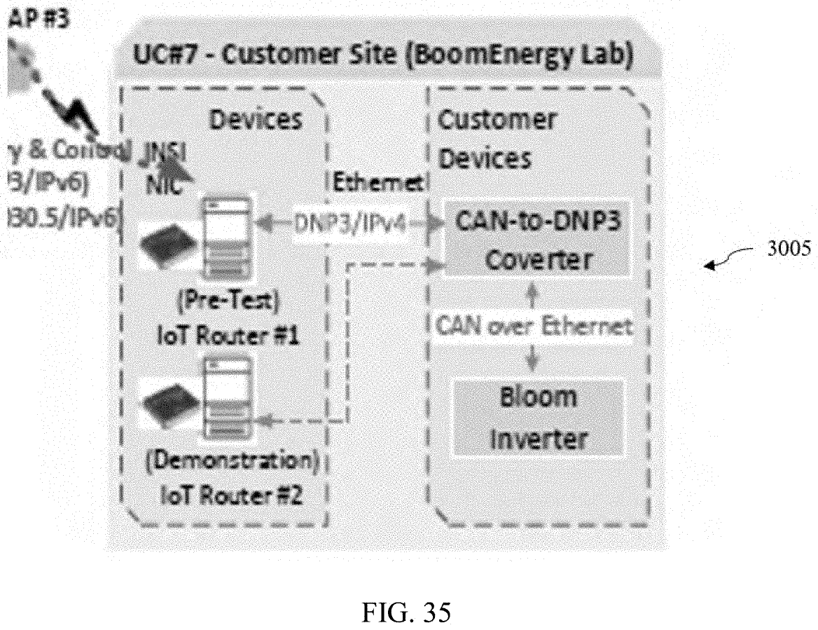

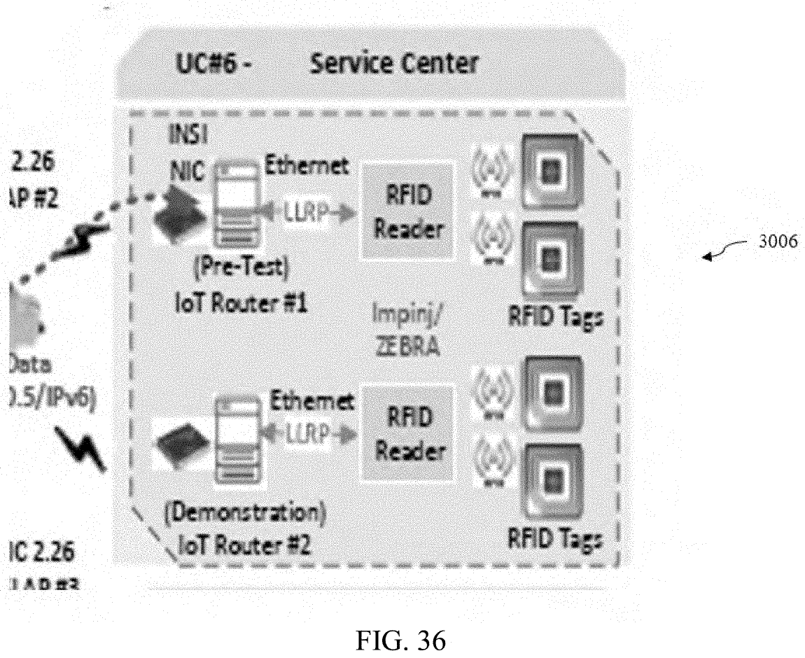

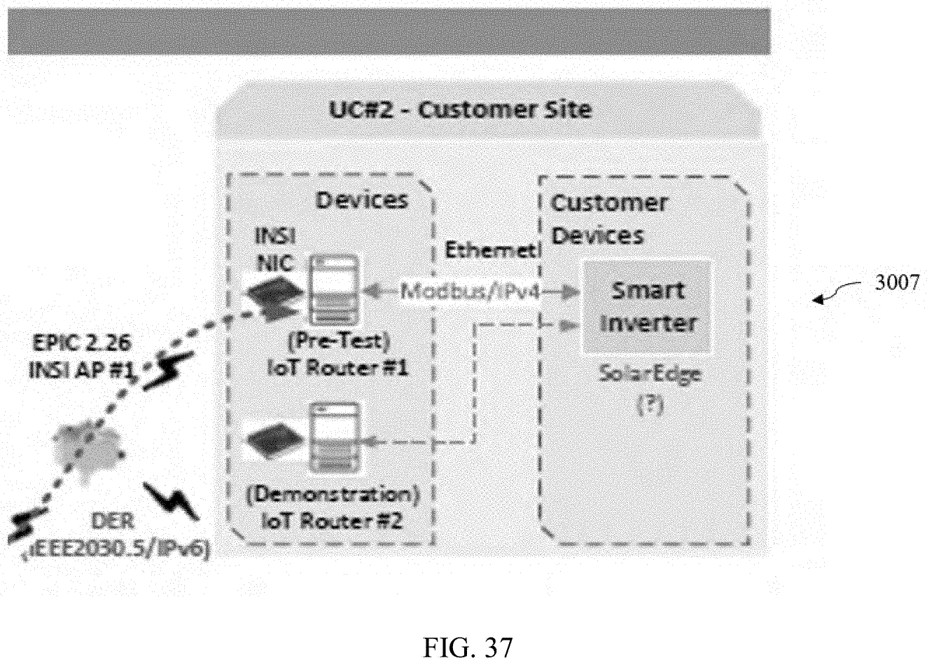

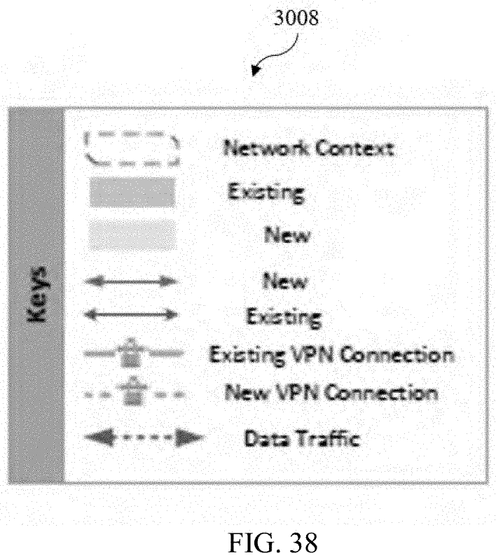

FIG. 30 illustrates a UC2, UC6, and UC7 field test logical architecture diagram 3000 used in conjunction with one or more Use Cases according to some embodiments. In some embodiments, field test logical architecture diagram 3000 sections 3001-3008 are shown enlarged in FIGS. 31-38 for clarity. In some embodiments, one or more field tests included deploying a pre-configured IoT router and/or an Itron Access Point (AP) at the customer location within close proximity to the third-party device under test. In some embodiments, the IoT router and AP was also configured with a network ID that was separate from the primary network.

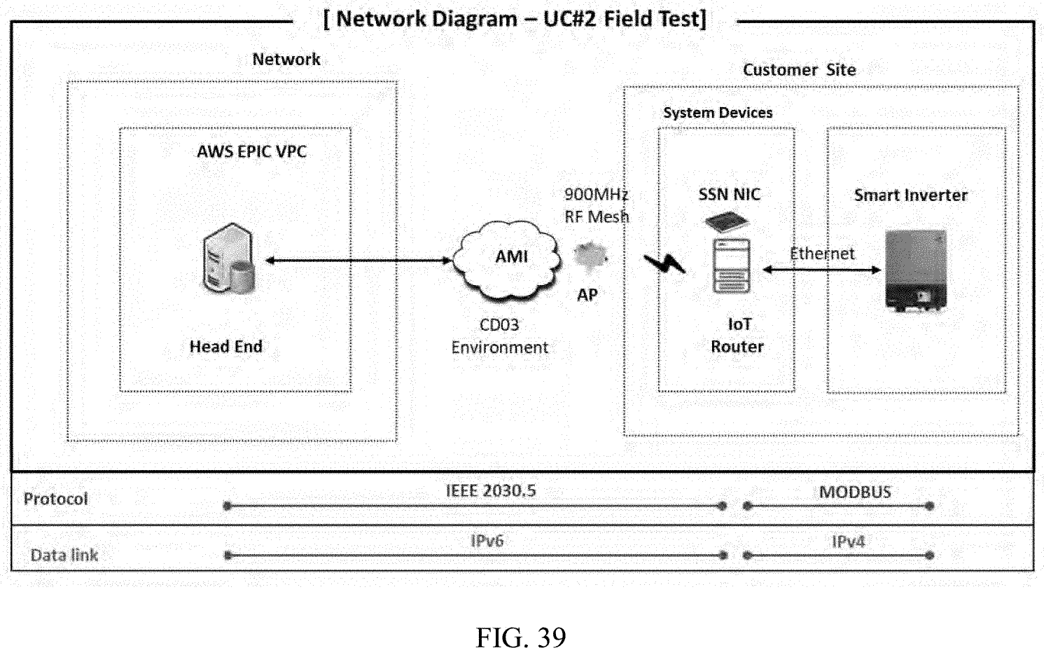

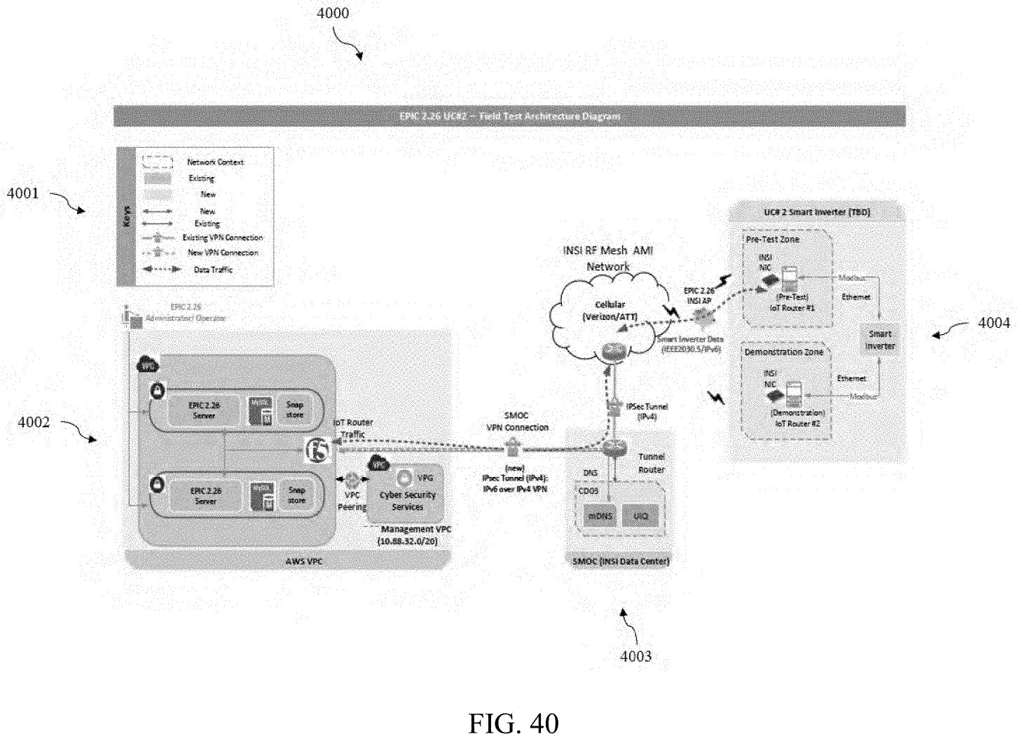

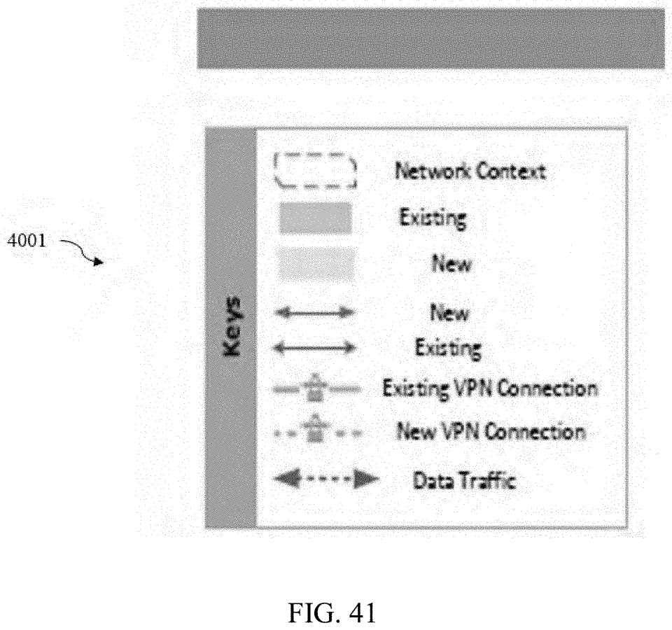

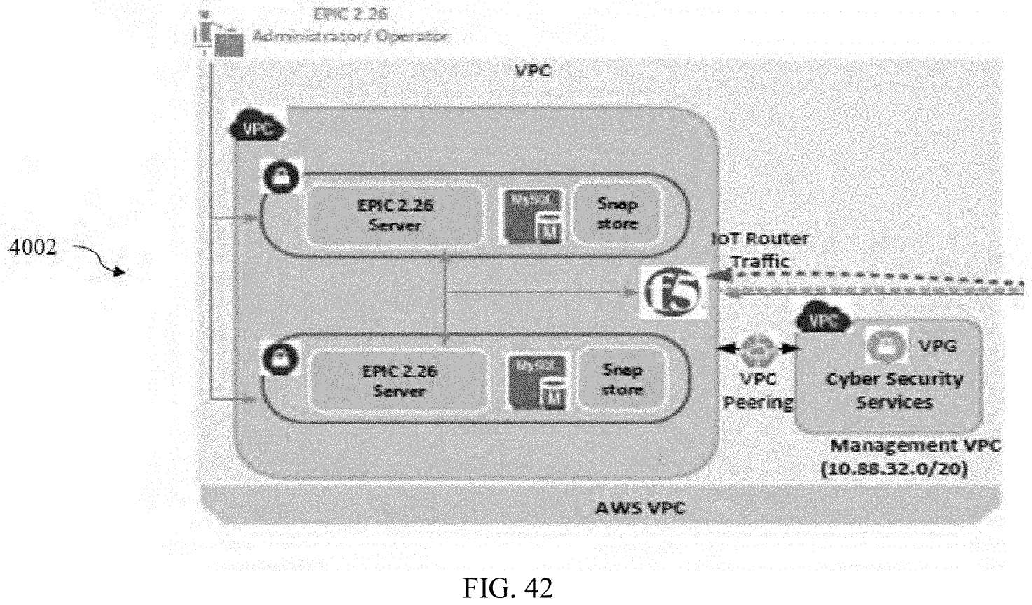

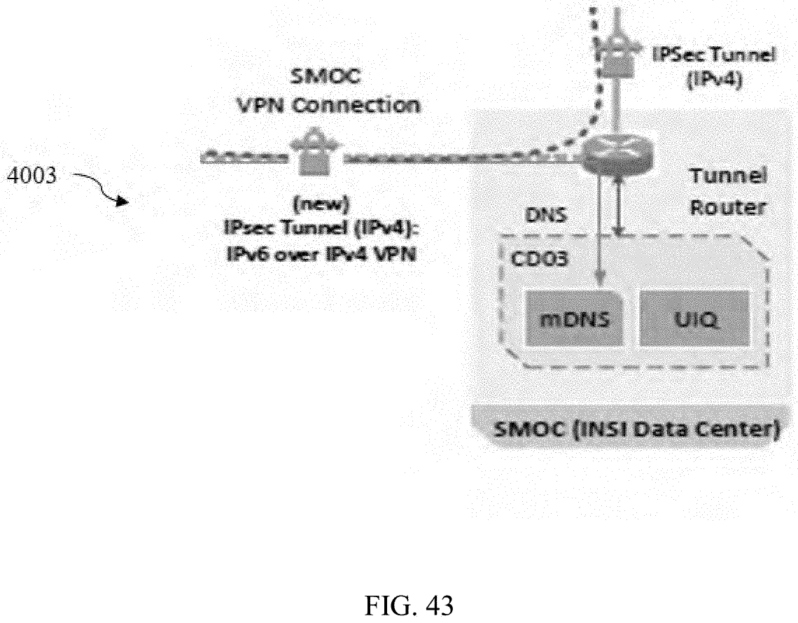

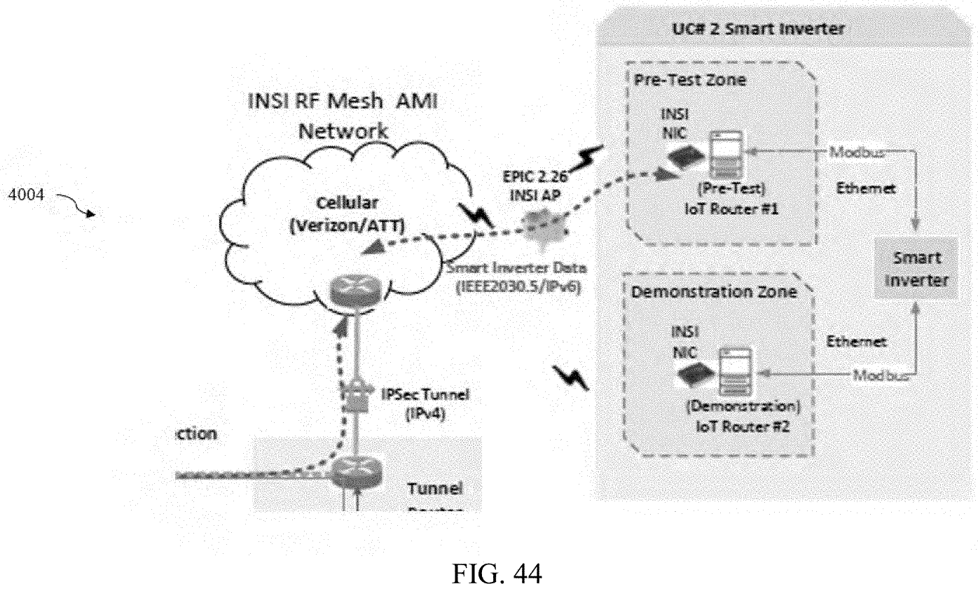

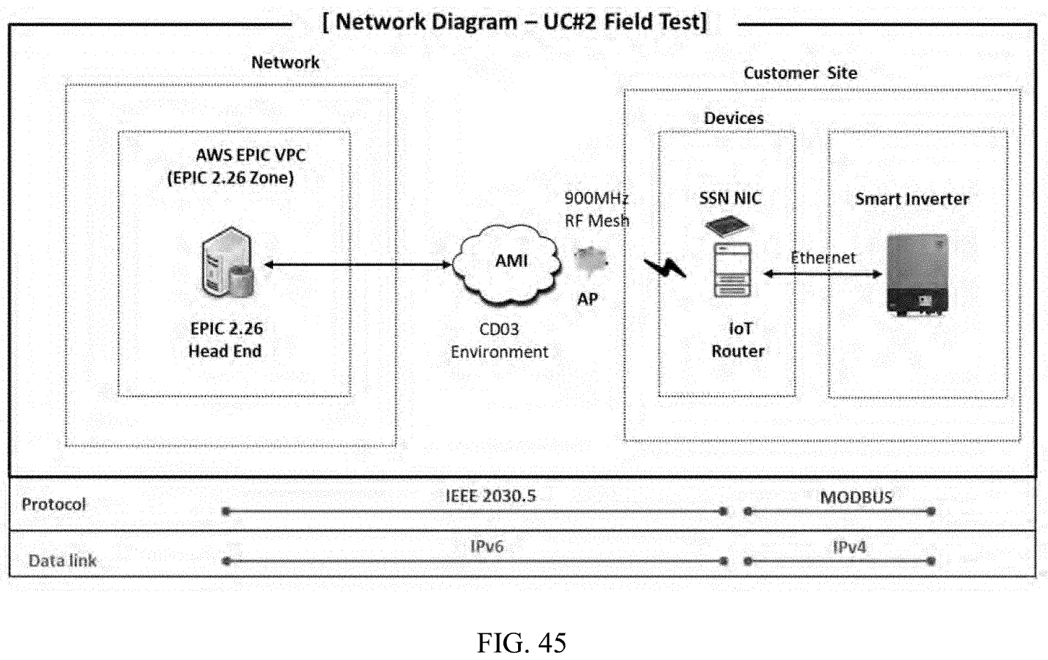

In some embodiments, field testing included Use Case 2: DER Communications. In some embodiments, for Use Case 2 field testing, a customer was chosen that had in their home a compatible Inverter supported by the lab testing. In some embodiments, the customer was provided with a pre-configured IoT router that needed to be connected to the Smart Inverter under test by an Ethernet cable (3 ft. max length) and powered using an AC adapter. In some embodiments, the networking configuration of the Smart Inverter may also have to be changed manually after connecting to the IoT router. FIG. 39 illustrates a UC2 Field Testing Diagram according to some embodiments. FIG. 40 shows a UC2 field test architecture diagram 4000 according to some embodiments. In some embodiments, field test architecture diagram 4000 sections 4001-4004 are shown enlarged in FIGS. 41-44. FIG. 45 illustrates a UC2 field testing diagram according to some embodiments.

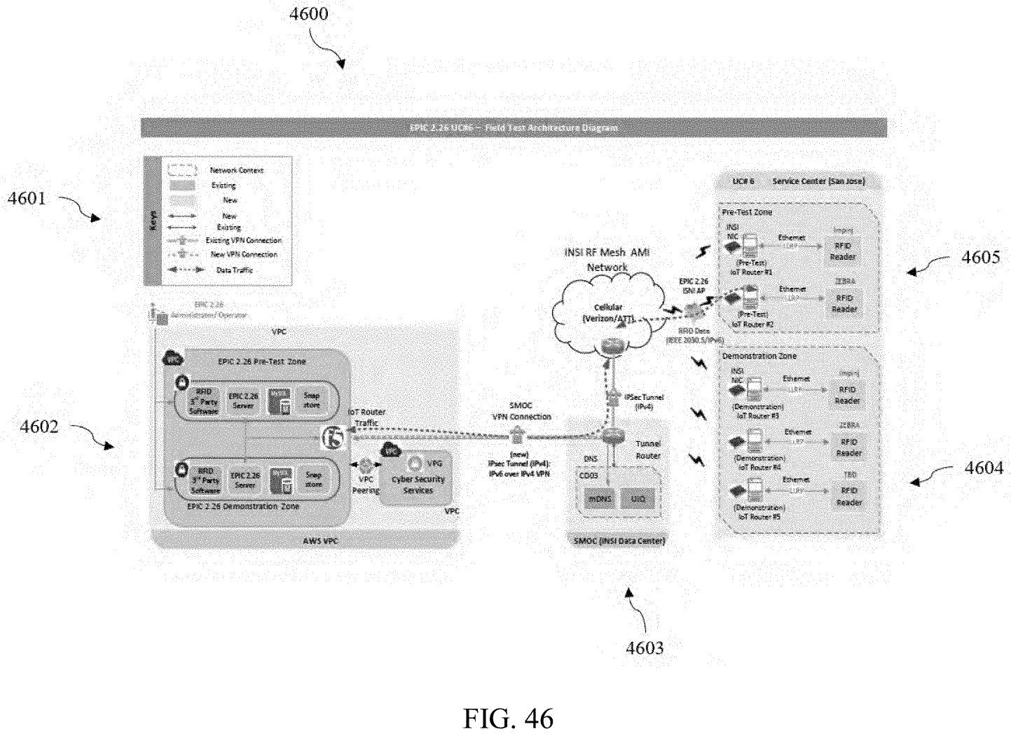

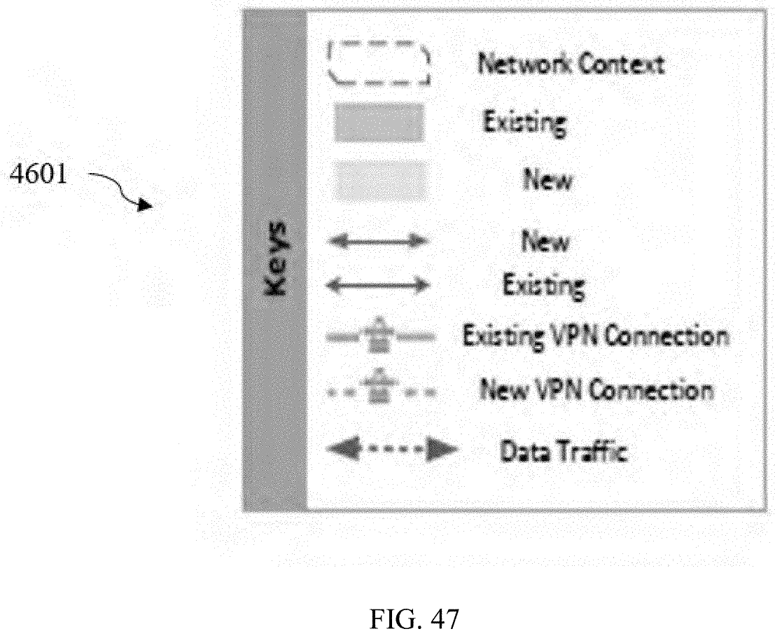

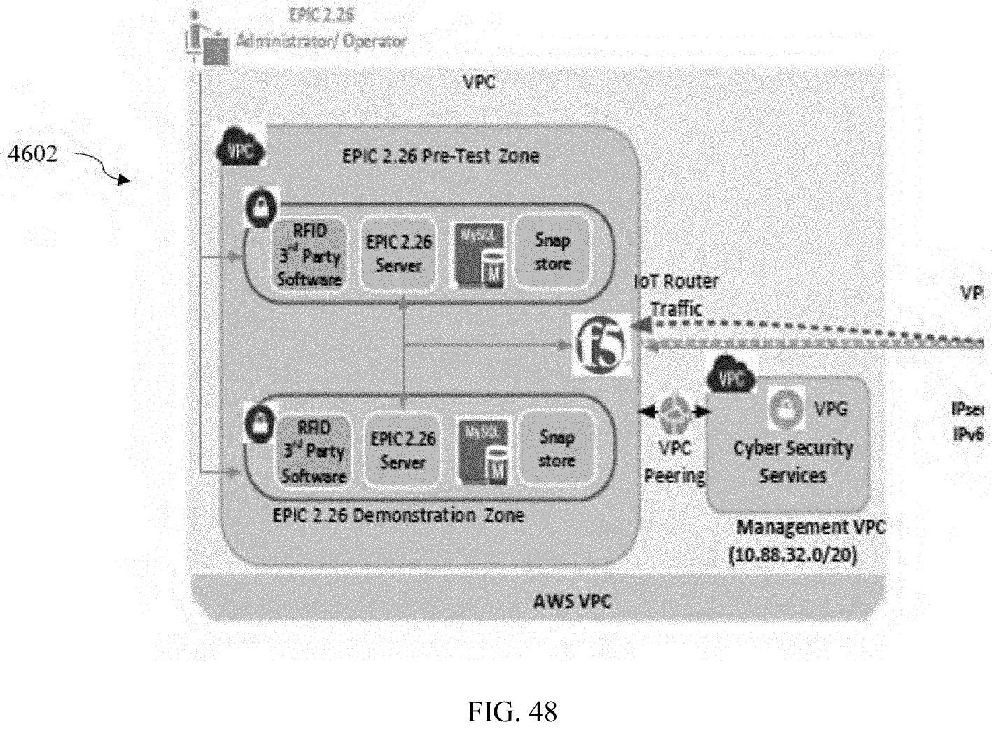

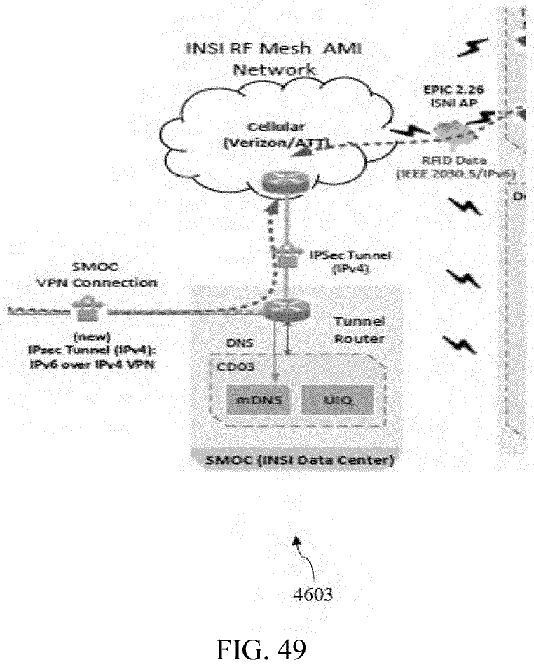

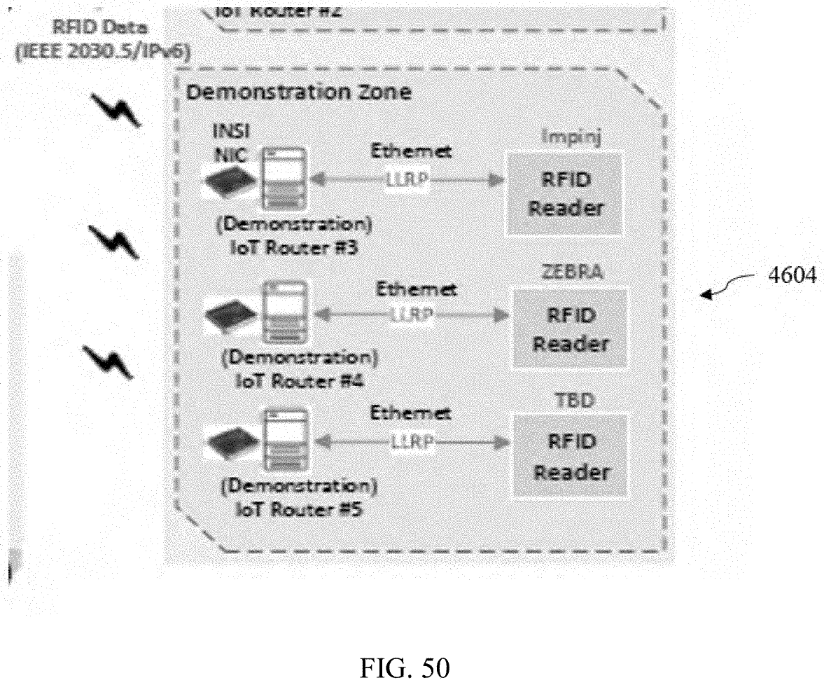

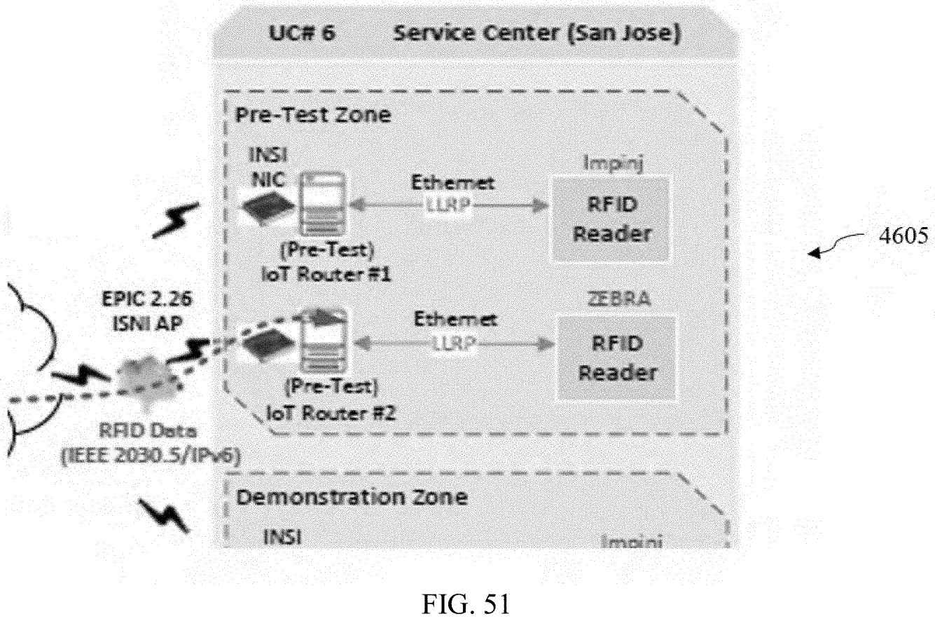

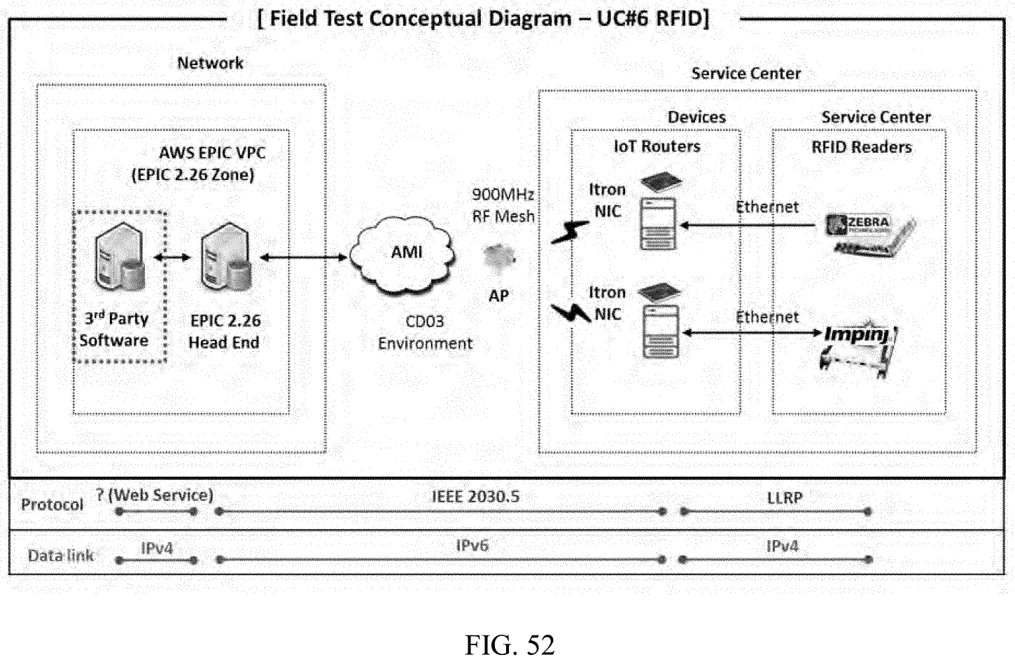

In some embodiments, field testing included Use Case 6: RFID Reader. In some embodiments, for Use Case 6 field testing, two RFID readers of differing vendors (Zebra and Impinj) were used. In some embodiments, each RFID reader was physically connected to their own IoT router and the IoT routers were connected to a new AP on the CD03 AMI network. In some embodiments, basic connectivity tests were performed to validate end-to-end connectivity through the AMI network followed by tests to assess network performance metrics for latency, throughput, and packet loss. FIG. 46 shows a UC6 Field Testing Architecture Diagram according to some embodiments. In some embodiments, field test architecture diagram 4600 sections 4601-4605 are shown enlarged in FIGS. 47-51. FIG. 52 shows a UC6 Field Testing Diagram according to some embodiments.

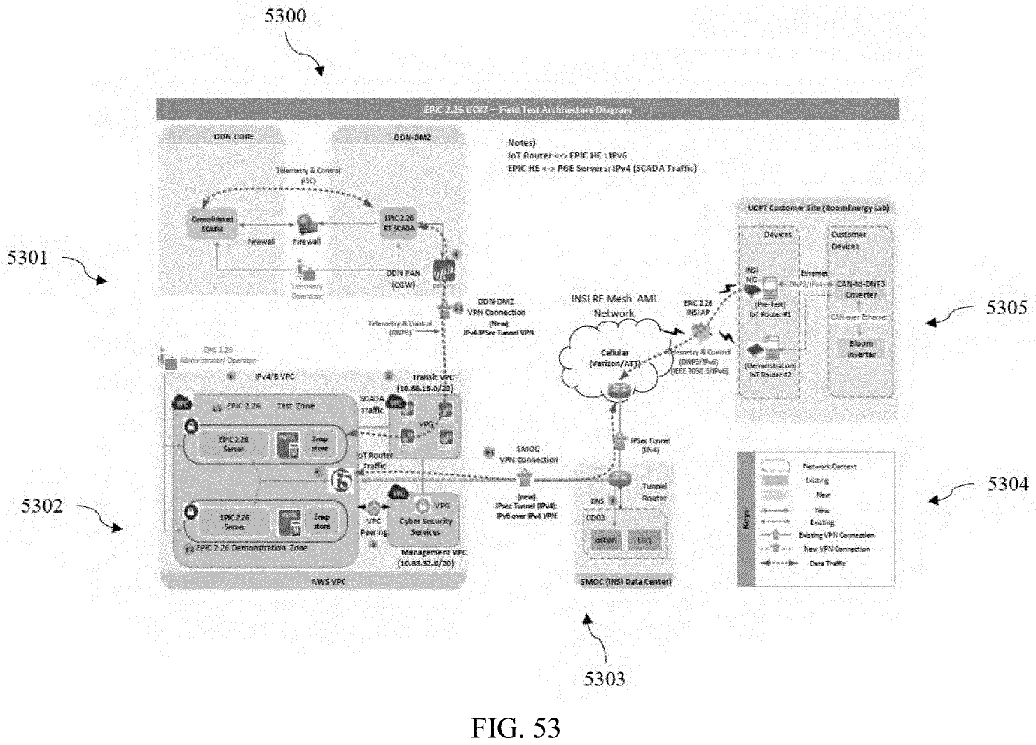

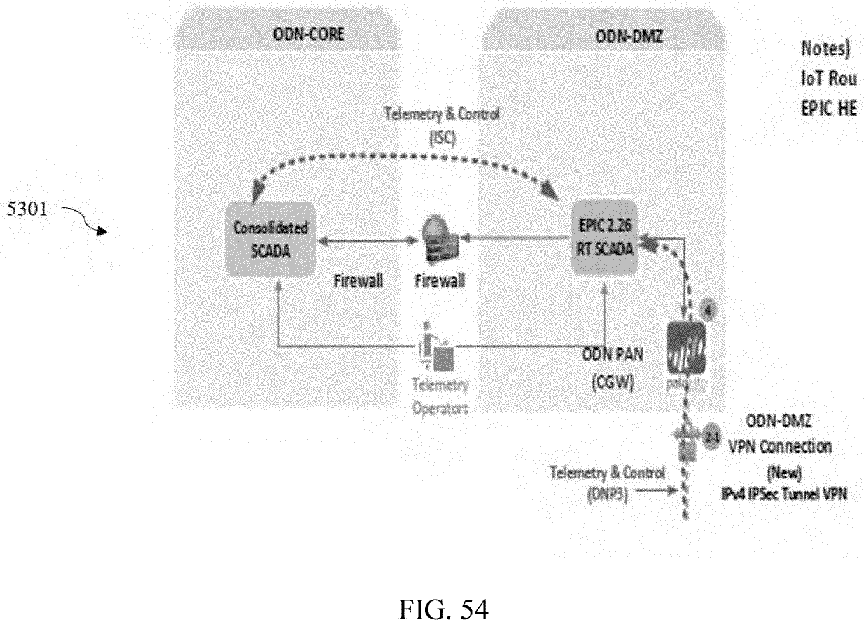

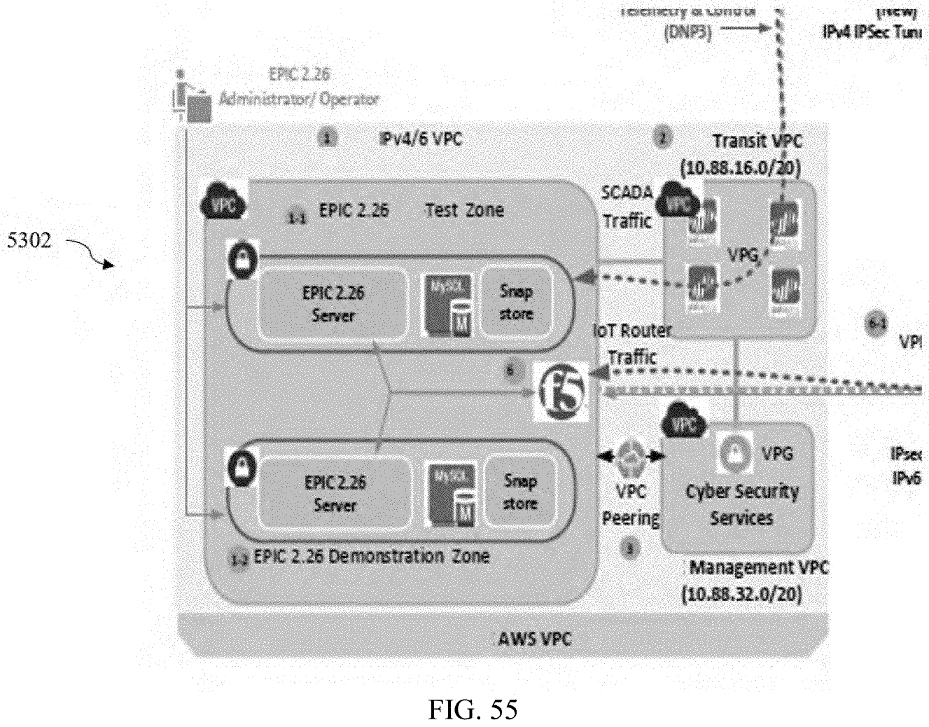

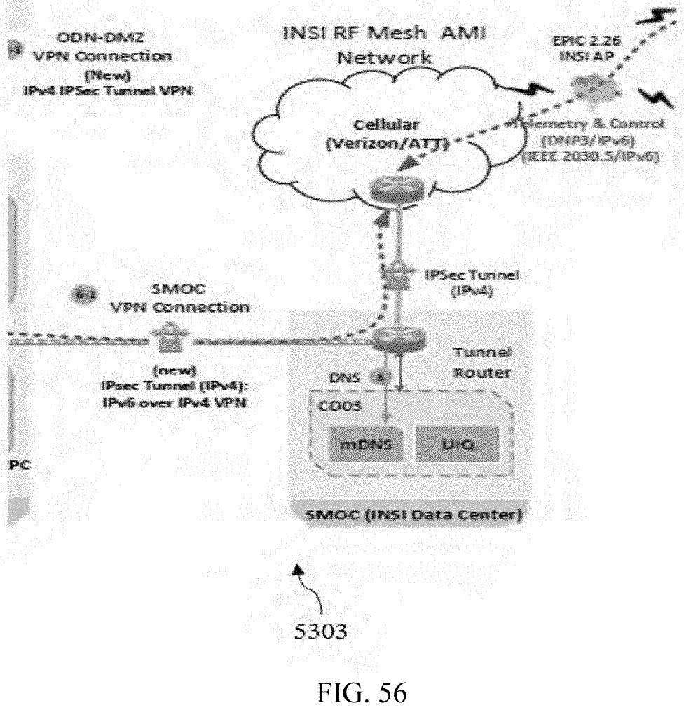

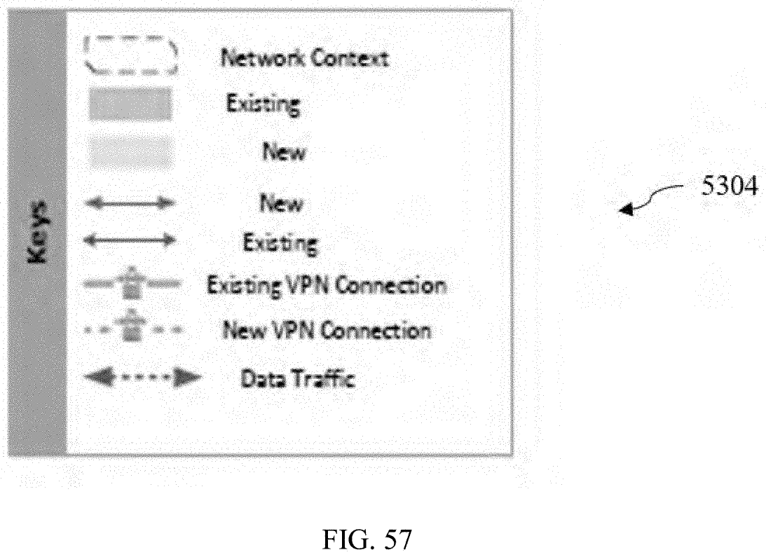

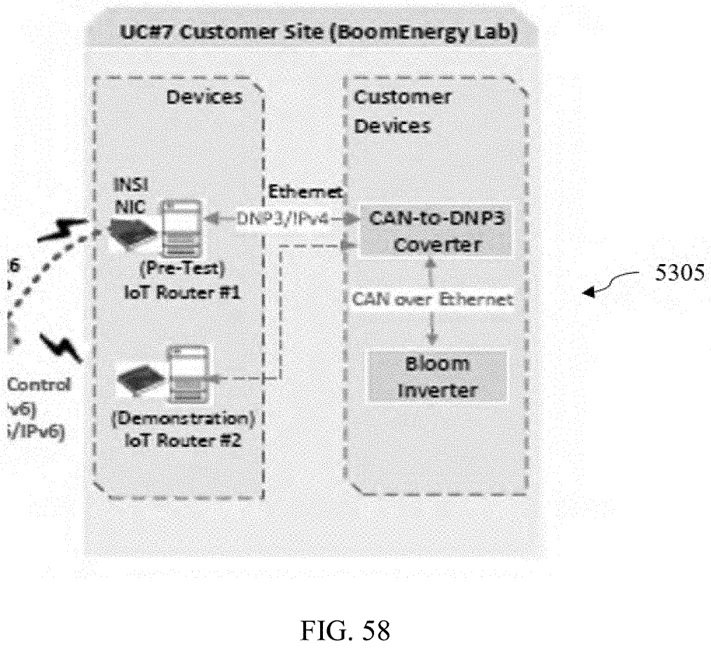

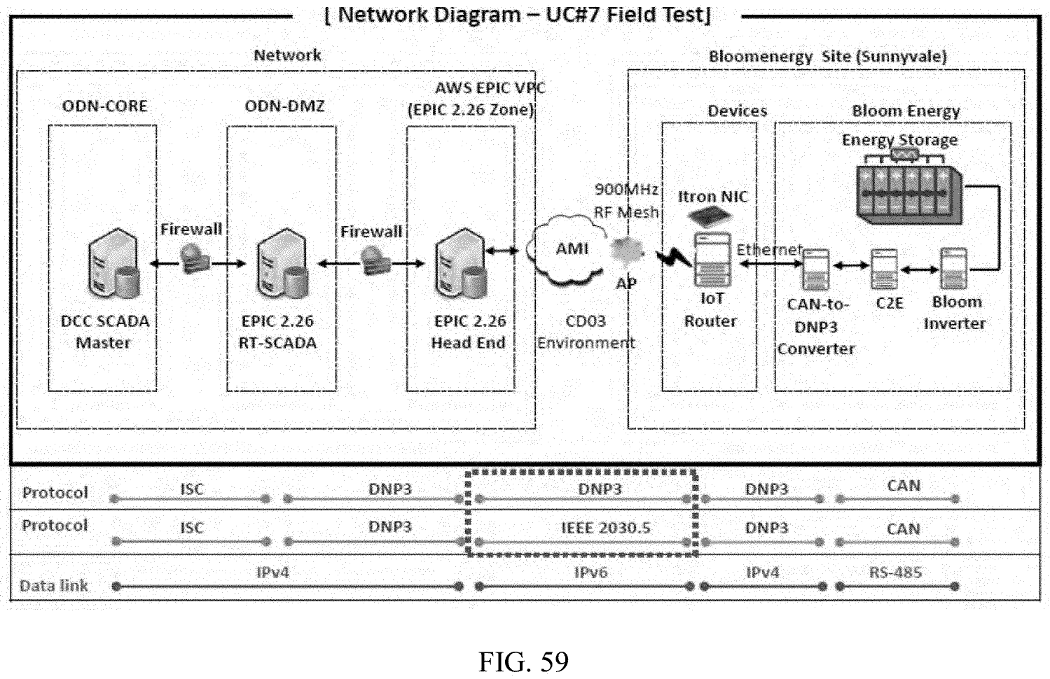

In some embodiments, field testing included Use Case 7: Data Acquisition and Control Telemetry. In some embodiments, for Use Case 7 field testing, a pre-configured Smart Inverter and the hardware to convert a Smart Inverter's CAN protocol to DNP3 were required by the test. In some embodiments, Bloom Energy® was provided with a pre-configured IoT router that needed to be connected to the DNP3 to CAN protocol converter by an Ethernet cable and powered using an AC adapter. In some embodiments, the networking configuration of the DNP3 to CAN converter also had to be changed manually after connecting to the IoT router. In some embodiments, for comparison, the over the air protocol used between the IEEE 2030.5 Server and Client was tested using both DNP3 over a simple HTTP channel as well as DNP3 embedded within IEEE 2030.5 messaging. FIG. 53 is a UC7 field testing architecture diagram 5300 according to some embodiments. In some embodiments, field test architecture diagram 5300 sections 5301-5305 are shown enlarged in FIGS. 54-58. FIG. 59 is a UC7 Field Testing Diagram according to some embodiments.

In some embodiments, the system includes field test deployment requirements. In some embodiments, to support the field tests, the following deployment requirements were included within the network. In some embodiments, the IEEE 2030.5 Server deployed in the head end was hosted on virtual servers within a Virtual Private Cloud (VPC) dedicated to EPIC 2.26 and created in an Amazon Web Services (AWS) environment. Both Development and Test zones reside within the EPIC 2.26 VPC and were connected to the AMI network, a Smart Meter Operations Center (SMOC) Code Drop 03 (CD-03), and the Utility Data Network (UDN) via another “Transit” AWS VPC.

In some embodiments, the system includes virtual hardware. The server instance sizing according to some embodiments are shown in Table 5:

TABLE 5
Field Test Server Requirements

| | Required | | | | Recommended | AWS |
|---|---|---|---|---|---|---|
| Server Function | HDD | | Quantity | CPU | Memory | Equivalent |
| IEEE 2030.5 | 500 | GB | 1 | 2 CPUs/Cores | 4 GB | t2.medium |
| Gateway | | | | | | |
| MySQL Database | 100 | GB | 1 | 2 CPUs/Cores | 4 GB | db.t2.medium |
| Snap Store | 50 | GB | 1 | 1 CPU/Core | 1 GB | t2.micro |
| IEEE 2030.5 | 4 | GB | 1 | 1 Dual Core | 1 GB | N/A |
| Client | | | | CPU@ 1 GHz | | |

In some embodiments, the required 3^{rd} party software applications and version included for each server are shown in Table 6:

TABLE 6
Field Test 3rd Party Software Requirements

| System | Type of Software | Software |
|---|---|---|
| IEEE 2030.5 Gateway | OS | Ubuntu Linux 17.04 |
| Java Runtime Environment | JRE | JRE 1.8.0_151 |
| MySQL Database | DB | MySQL 5.7.20 |
| Snap Store | TBD | TBD |

In some embodiments, the TCP/IP port and protocol information for communication to and from each server used to configure the firewall exception rules are shown in Tables 7-9:

TABLE 7
IEEE 2030.5 Server firewall exception

| | | Source | Destination | |
|---|---|---|---|---|
| Port | Protocol | System | System | Notes |
| 443 | TCP | IEEE | IEEE | HTTPS |
| | | 2030.5 | 2030.5 | |
| | | Client | Gateway | |
| 8080 | TCP | IEEE | IEEE | HTTP, IEEE |
| | | 2030.5 | 2030.5 | 2030.5 Services |
| | | Client | Gateway | |
| 20000 | TCP | RT | IEEE | DNP3 |
| | | SCADA | 2030.5 | |
| | | | Gateway | |

TABLE 8
IEEE 2030.5 Client firewall exception

| | | Source | Destination | |
|---|---|---|---|---|
| Port | Protocol | System | System | Notes |
| 8080 | TCP | IEEE | IEEE | HTTP, IEEE |
| | | 2030.5 | 2030.5 | 2030.5 Services |
| | | Gateway | Client | |

TABLE 9
Database Server firewall exception

| | | Source | Destination | |
|---|---|---|---|---|
| Port | Protocol | System | System | Notes |
| 3306 | TCP | IEEE | Database | MySQL Listener |
| | | 2030.5 | Server | Port |
| | | Gateway | | |

In some embodiments, non-functional requirements for user authentication and authorization on the IEEE 2030.5 Server, integration with an Active Directory using the Lightweight Directory Access (LDAP) protocol is included. In some embodiments, this allows Server users to log in using their existing corporate LAN ID credentials. In some embodiments, to facilitate testing of this functionality during the lab testing phase, internal networks allow LDAP traffic from the TicNet (DMZ) environment to the corporate LDAP server.

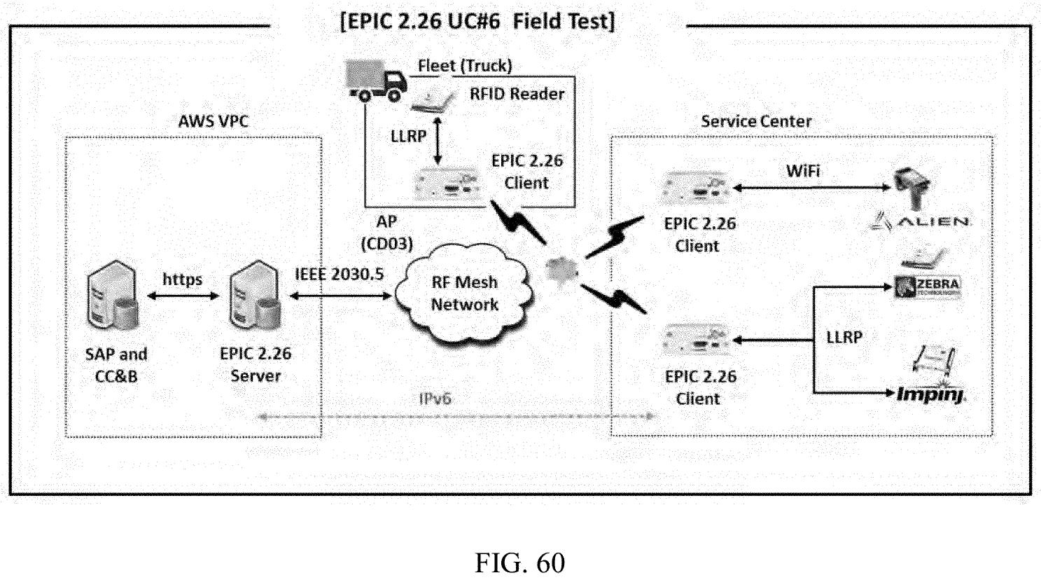

In some embodiments, the system includes Asset Management Interface (AMI) requirements. In some embodiments, the goal of the system is to extend the basic RFID reader functionality with additional functionality, data processing capability, and improved data visualization. In some embodiments, the additional functionality allowed field testing that validated the use of the AMI network and the EPIC 2.26 Server and Client software for the purposes of managing a network of RFID readers across a service area. FIG. 60 is a RFID Field Test Block Diagram according to some embodiments.

In some embodiments, the system includes a data model. In some embodiments, as the initial EPIC 2.26 UC6 development was only focused on collecting raw RFID tag read data from multiple types and vendors of RIFD reader, the scope of these enhancements required additions to the data model to relate the RFID tag reads to physical assets and to track them both geographically and over time.

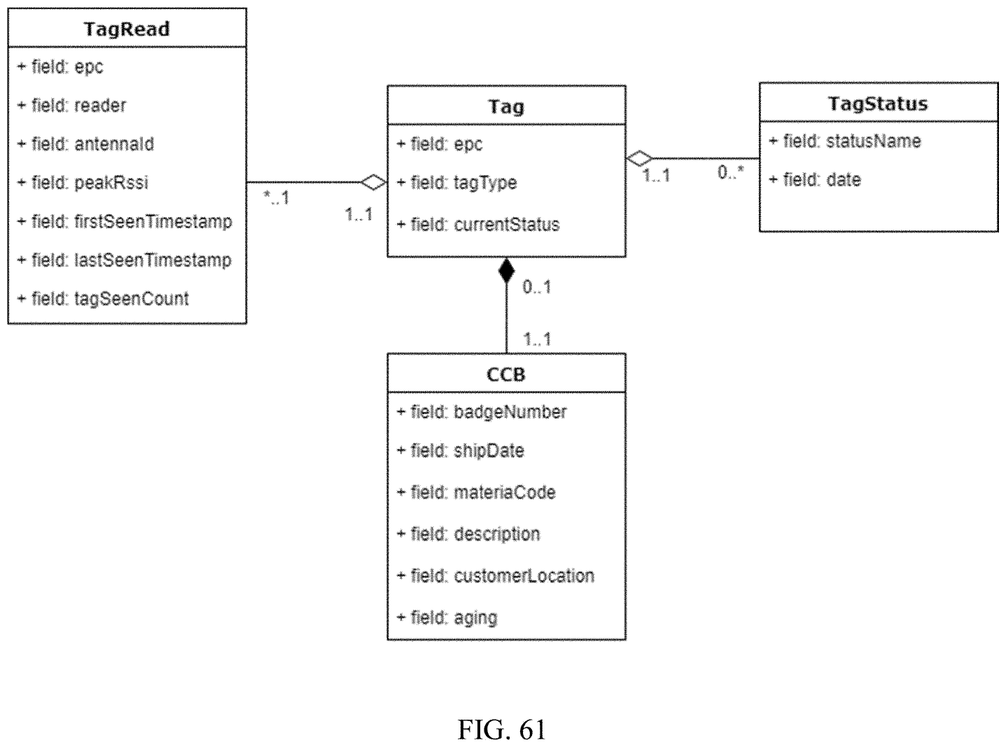

In some embodiments, as new, raw RFID tag read data (i.e., Electronic Product Codes; EPCs) are read into the Server, they are processed to determine if they can be associated to assets that should be tracked. In some embodiments, if an RFID EPC can be correlated to an asset to be tracked, a new instance of “Tag” is created. In some embodiments, during lab and field testing, this is accomplished by a lookup table that can be used to correlate the RFID EPC to an asset's unique identifier (badge #). In some embodiments, the asset unique identifier is used to lookup additional information about the asset (asset type) from another imported external data source (CC&B). In some embodiments, for subsequent tag reads of existing “Tag”s, new TagStatus instances are created and stored to create a history of the Tag's movement throughout the Asset Management system. FIG. 61 shows Tag UML according to some embodiments.

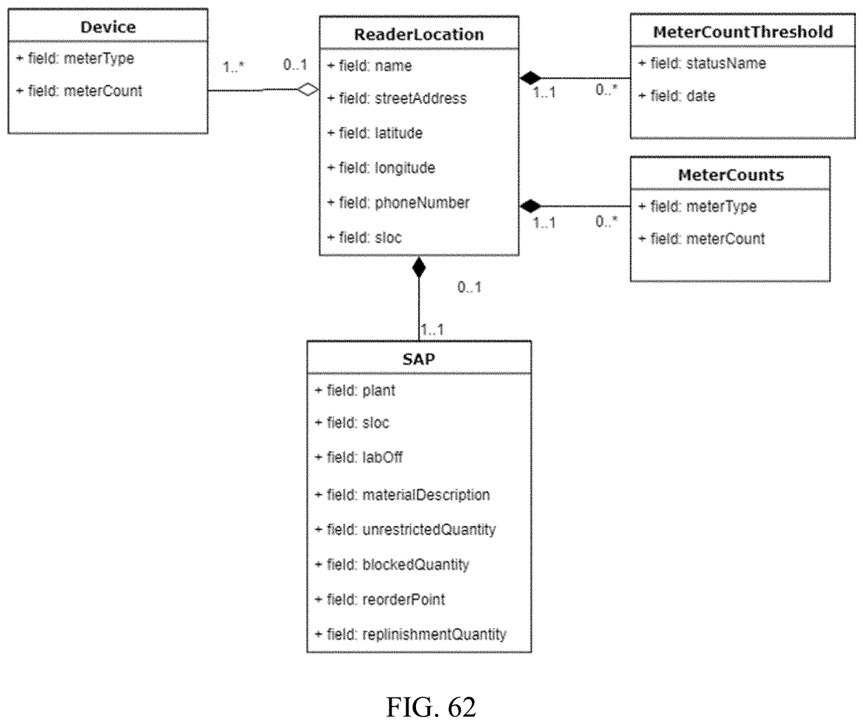

In some embodiments, this data model introduces the concept of RFID reader location, and each location can support one or more RFID readers. In some embodiments, each location has a configurable type with the three main types: Distribution Center (“warehouse”); Service Center (“yard”); Truck. In some embodiments, each location contains configurable parameters for name, internal ID, street address, latitude, and longitude. FIG. 62 depicts Location UML according to some embodiments.

In some embodiments, the system includes software development. In some embodiments, software development includes multiple RFID reader per IoT router support. In some embodiments, to more efficiently manage multiple RFID readers at a single location, both Client and Server are updated and able to send commands and collect data from multiple RFID readers attached to a single IoT router. In some embodiments, IoT router is put into “client” mode which turns its ethernet port into a DHCP client which allows it to talk to all RFID readers on the location's local network. In some embodiments, polling of readers by the Client is configurable per RFID reader. In some embodiments, polling of RFID data by the Server to the Clients collects RFID data for all readers attached to the Client at once (not per RFID reader). In some embodiments, commands issued by the Server is directed to a single RFID reader rather than all readers attached to an IoT router.

In some embodiments, the system includes reader health and status. In some embodiments, to provide more information about the health and status of each RFID reader across the network, additional information is collected by the Client for each individual reader. In some embodiments, for Network connectivity, the Client performs a “ping” to ensure that the RFID reader is reachable on the local network. In some embodiments, the resulting status is pass or fail based on receiving a single successful response out of 5 attempts. In some embodiments, for Reader Operation, the Client performs an LLRP command (GET ROSPEC) to retrieve details of the reader's operation specification. In some embodiments, the status of the reader operation is one of:

Active—Reader operation exists, is enabled, and running.

Inactive—Reader operation exists, is enabled, but not running.

Disabled—Reader operation exists but is not enabled.

Non-existent—No reader operations exist.

In some embodiments, the polling frequency of the Client to the managed readers is configurable through the Router Config file and the RFID reader health information is stored in a Client-side cache. In some embodiments, the Client-side cache is pollable from the Server on-demand and only the most current status for each reader is stored.

In some embodiments, the system includes handheld reader support. In some embodiments, support is added to the system for managing and collecting data from a handheld reader (e.g., the Alien® ALR-H450). In some embodiments, the handheld reader uses an Android® device and does not support LLRP directly, so custom Android software was developed and deployed on the reader. In some embodiments, the Android® software collects the RFID tag read data and transfer it to the EPIC 2.26 Client via a Bluetooth and/or WiFi connection established between the reader and the IoT router.

In some embodiments, the system includes a business intelligence engine. In some embodiments, to be able to translate the RFID tag read data being collected by the platform to usable, business data a Business Intelligence (BI) engine is added. In some embodiments, the BI engine is configured to managing external data and processing the raw RFID tag read data as it enters the system.

In some embodiments, the system includes data import. In some embodiments, at least two external data sources are supported for import into the Server. In some embodiments, one external data source is a Systems Applications and Products (SAP) Export. In some embodiments, the export from the SAP asset management database contains the weekly cycle count information (manual meter counts) as well as the threshold and quantities for reordering of meters. In some embodiments, data is maintained per meter type and per location. In some embodiments, the Server is configured to maintain cycle count data over time (one set of data per week).

In some embodiments, another external data source is a Customer Care & Billing (CC&B) Export. In some embodiments, this data contains meter information from the system database for meters that have been received at a Distribution Center and provide information about the specific meter asset such as meter type, manufacturer, and installation status for meters both installed and not installed, as non-limiting examples. In some embodiments, each new load of the CC&B data overwrites the existing data, and data is not maintained over time. See appendix B for a sample of the CC&B data according to some embodiments.

In some embodiments, the system includes Tag processing. In some embodiments, as new RFID tag read data are read into the system, they are processed to determine details of the underlying asset. In some embodiments, example asset details that are determined from the RFID tag are: Meter vs Pallet; Meter manufacturer & meter type; and Meter/Badge number. See appendix C for an example of EPCs from which all of the above information could be parsed according to some embodiments.

In some embodiments, the system includes asset tracking. In some embodiments, for tag read data that is processed for assets that already exist in the system, the new tag read information is compared to the existing status of the tag. In some embodiments, new tag reads that represent the underlying asset that has “moved” between areas of a single location or between two locations will update the status of the asset and record the new status to the asset's status history.

In some embodiments, the system includes meter count. In some embodiments, for each location, a user-editable script is defined to perform the meter count calculation for that location. In some embodiments, for locations that have RFID tag read data, this meter count data replaces the cycle count data imported from the SAP import sheet.

In some embodiments, the system includes data exporting. In some embodiments, Server interfaces are added for search and export of both asset tracking history and raw tag read data in CSV format.

In some embodiments, the system includes one or more meter data maps. In some embodiments, a Meter Data Map user interface provides information about the quantity of meters at each location and/or geographically within a map-based user interface as a display on a proprietary and/or conventional map (e.g., Google Maps; Waze). In some embodiments, an API works in conjunction with a conventional map to display information about the quantity of meters at each location and/or geographically within a map-based user interface. In some embodiments, different icons on the map will represent each location type and the icons are color-coded (Red/Amber/Green) based on the meter count compared to High and Low as follows:

Green: meter count>=High

Amber: Low<=meter count<High

Red: meter count<Low

In some embodiments, each location supports separate High and Low thresholds per meter type. In some embodiments, the initial default High and Low settings for each location are:

High=reorder point

Low=20% of reorder point

In some embodiments, the map has filters for selecting the location type to display on the map and meter type which adjusts the icon color based on the current meter counts and thresholds. In some embodiments, selecting a specific location on the map will provide additional information (primarily meter count) for that specific location. In some embodiments, this map-based interface is configured for use on mobile devices with regards to size and layout of elements.

In some embodiments, the system includes output APIs. In some embodiments, the EPIC 2.26 Server will be updated to support at least two types of output APIs for exporting RFID data programmatically to external applications as described below:

REST APIs—In some embodiments, a REST API allows external applications to “pull” RFID data from the Server on demand. In some embodiments, two separate APIs are created for exporting tag transaction data based on a location and timeframe and for exporting current asset information by location. In some embodiments, the API will support export of data by XML or JSON.

Kafka API—In some embodiments, a Kafka API will “push” data from the Server to an external Kafka messaging server. In some embodiments, upon completion of the processing of raw tag read data into transactions, all new asset transaction data are pushed to the configured Kafka topic. In some embodiments, Kafka server configuration properties will be added to the EPIC 2.26 Server configuration file.

In some embodiments, the system includes data feed monitoring requirements. In some embodiments, the is Server is configured to allow a user to create thresholds within the system Server (e.g., EPIC 2.26 Server) and apply them against a set of metering data imported into the Server. In some embodiments, after execution, all values identified as not within the selected thresholds are flagged and reported to the user. In some embodiments, this functionality is configured to be expanded to apply to different data sources and trigger different notification processes. In some embodiments, each threshold consists of a set of three components:

property—The specific category of metering data to evaluate.

operator—The comparator to apply (“<”, “=”, “>”, etc.)

value—The threshold value to compare the measured value against.

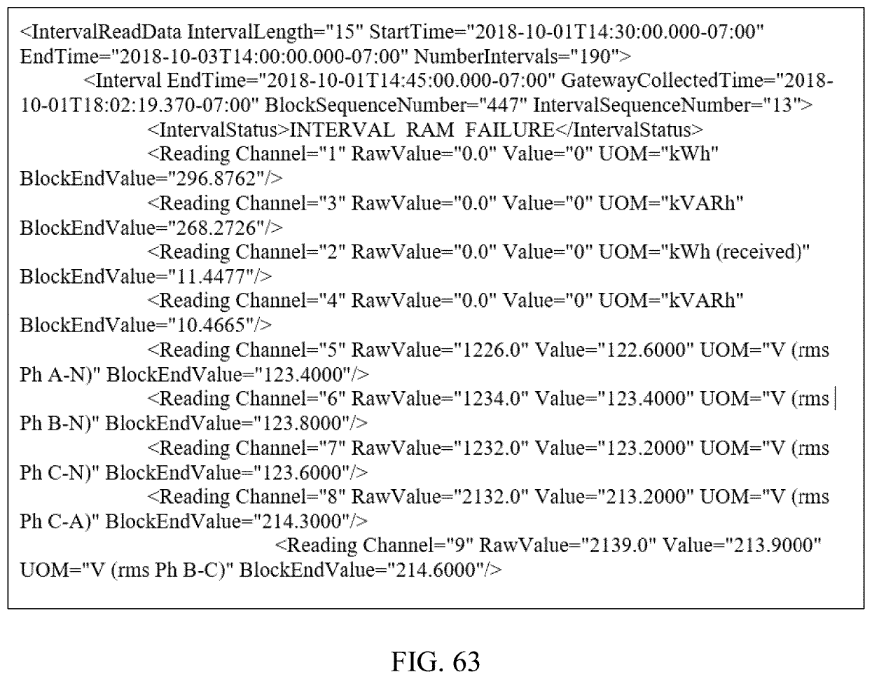

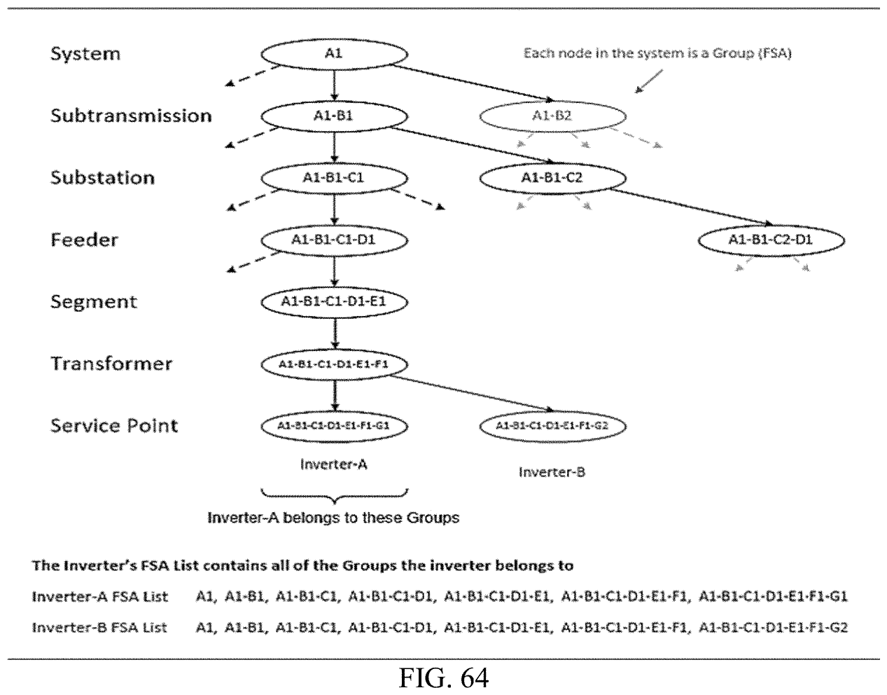

FIG. 63 Illustrates sample XML Metering data according to some embodiments. FIG. 64 shows Server and Client Function Set assignments according to some embodiments. In some embodiments, FIG. 64 shows an example hierarchical FSA structure. In some embodiments, FSAs are essentially labels with no relation to one another. In some embodiments, the Server can easily target a group of SEP devices for DER or DRLC.

In some embodiments, the system includes Server requirements. In some embodiments, Server requirements include security including one or more of security for basic HTTP and user account security; device security using TLS certificates and PIN; and/or Access Control List (ACL) that allows for device-specific privileges. In some embodiments, Server requirements include discovery, where discovery includes the Server managing and communicating the device's capabilities. In some embodiments, Server requirements include one or more background process threads used for routing processes (subscription cleanup, etc.) In some embodiments, Server requirements include Client communication that broker connectivity to Clients via both IEEE 2030.5 and HTTP and support 2030.5 Subscription/Notification to reduce network traffic. In some embodiments, Server requirements include at least one DPN3 API that receives and decodes inbound DNP3 messages to find “Destination Address”. In some embodiments, DNP3 API includes the Server identifying an End Device and IoT Router and forwarding an original message.

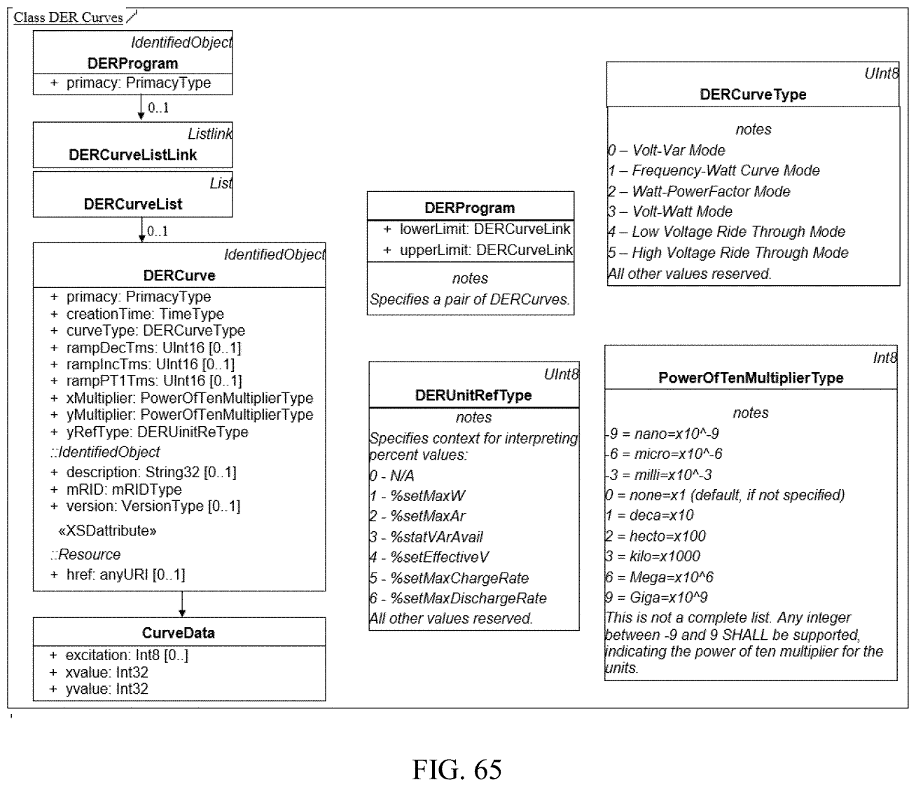

FIG. 65 shows IEEE 2030.5 Data Model UML-DER Curves according to some embodiments. In some embodiments, shown is an example of the UML diagrams from the IEEE 2030.5 specification package. In some embodiments, shown is the relationship between data objects.

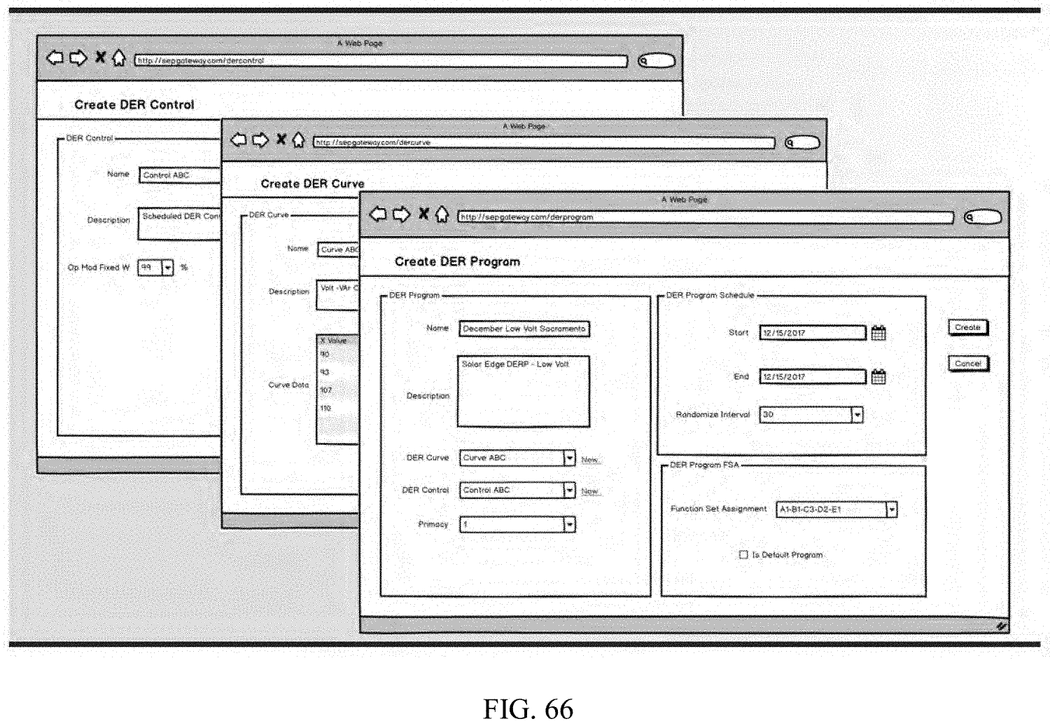

FIG. 66 shows Server GUIs—DER Program according to some embodiments.

In some embodiments, the system includes one or more Client requirements. In some embodiments, Client requirements include security, which includes Spring Security for user accounts and Server communication secured with TLS and device/user authentication. In some embodiments, Client requirements include discovery which includes the Client autonomously registering with the Server, discover available Resources on Server, Subscribe to Notifications, perform time sync, etc., where the Client is designed to support multiple End Devices per IoT router. In some embodiments, Client requirements include at least on background process thread that is used for routine processes (Reading device data, sending device commands, etc.). In some embodiments, Client requirements include Server communication that receives messages from server via both IEEE 2030.5 Notifications and HTTP and supports 2030.5 Subscription/Notification to reduce network traffic. In some embodiments, Client requirements include at least one DPN3 Interface that receives message from server and forward to appropriate End Device.

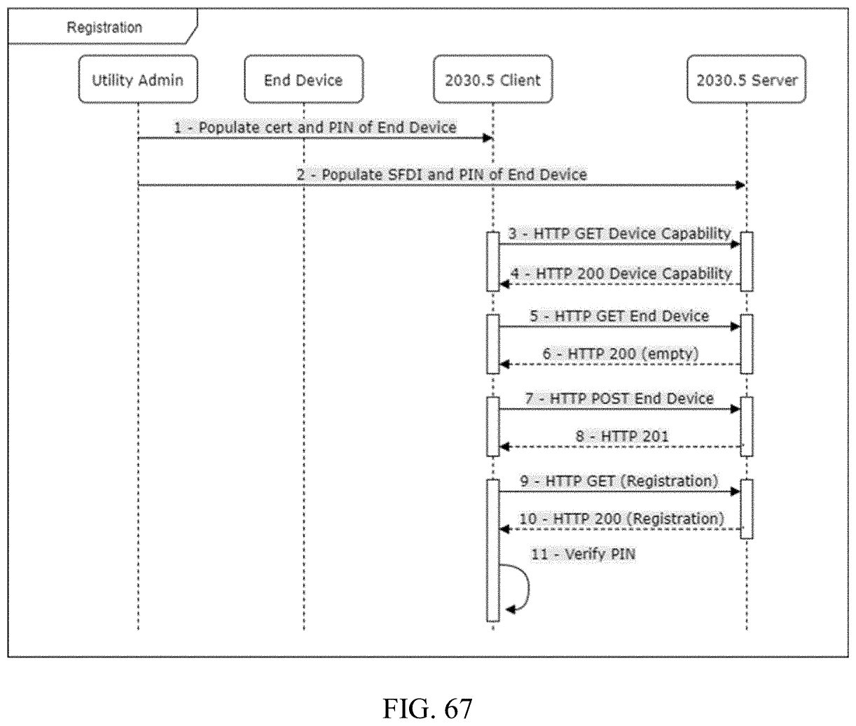

FIG. 67 shows a Registration sequence diagram according to some embodiments.

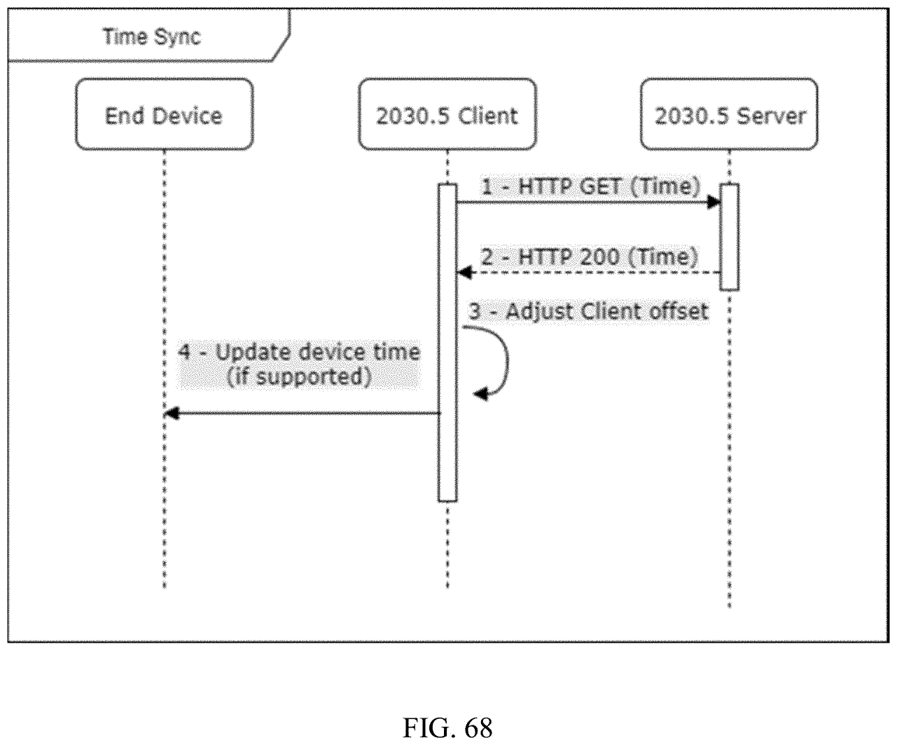

FIG. 68 shows a Time Sync sequence diagram according to some embodiments.

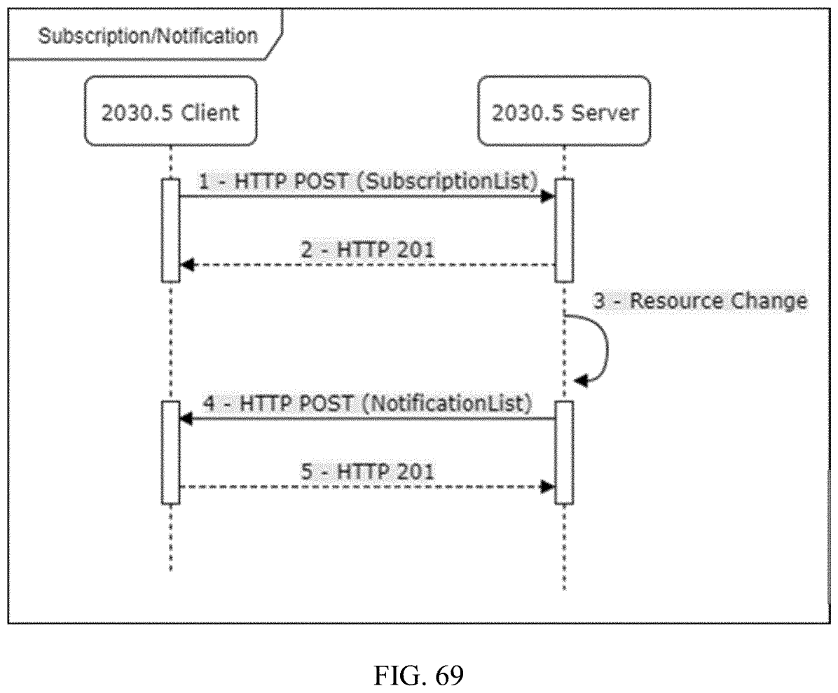

FIG. 69 shows a Subscription/Notification sequence diagram according to some embodiments.

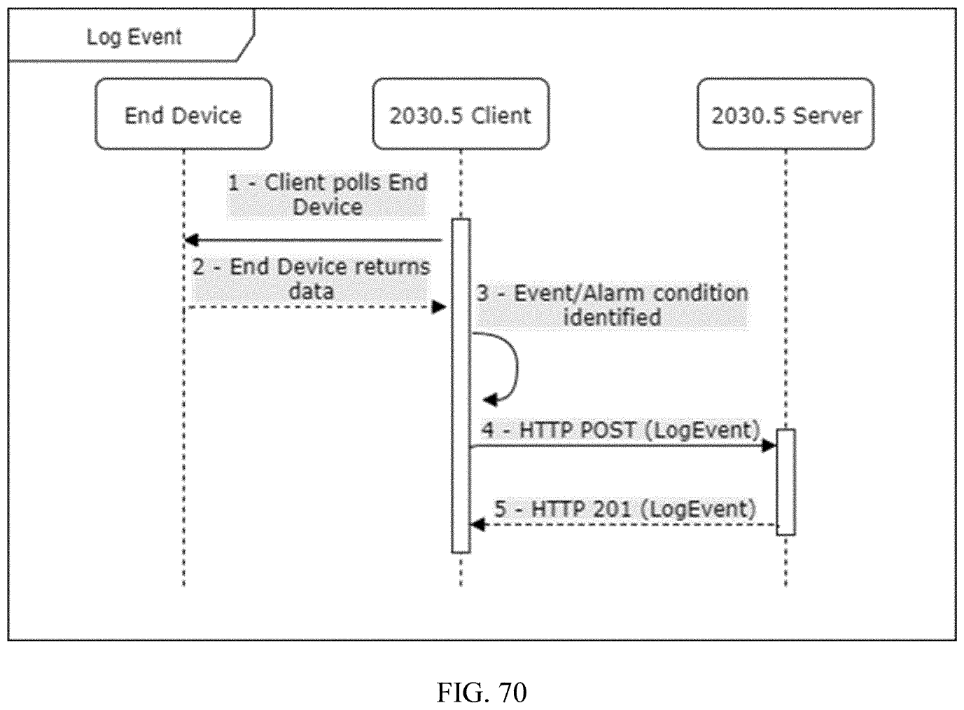

FIG. 70 shows a Log Event sequence diagram according to some embodiments.

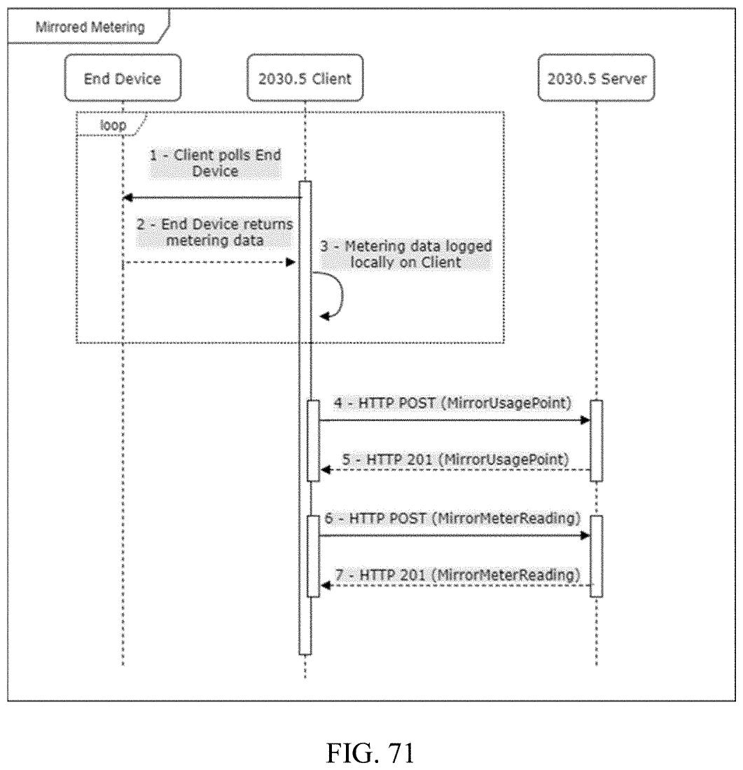

FIG. 71 shows a Mirrored Metering sequence diagram according to some embodiments.

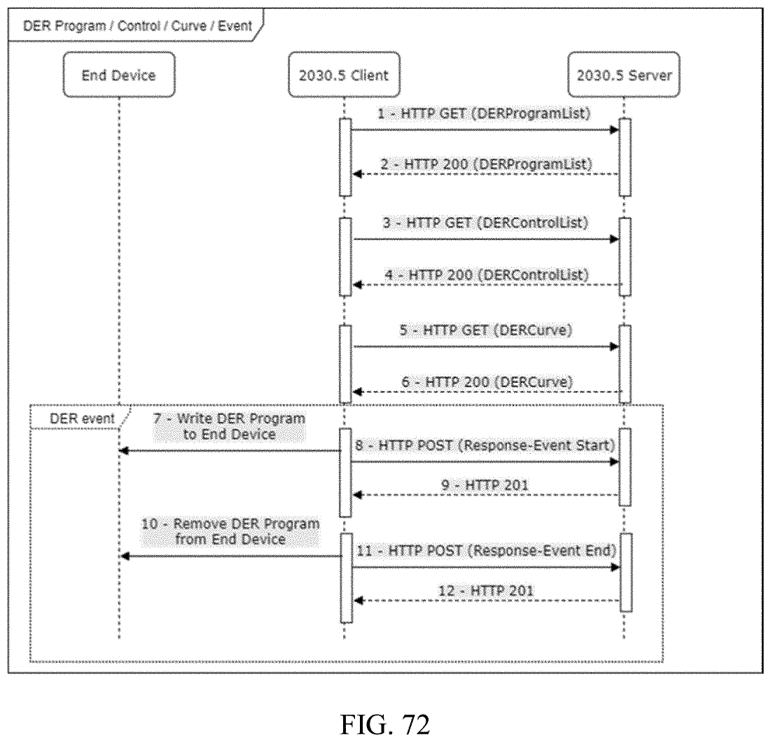

FIG. 72 shows a DER Program sequence diagram according to some embodiments.

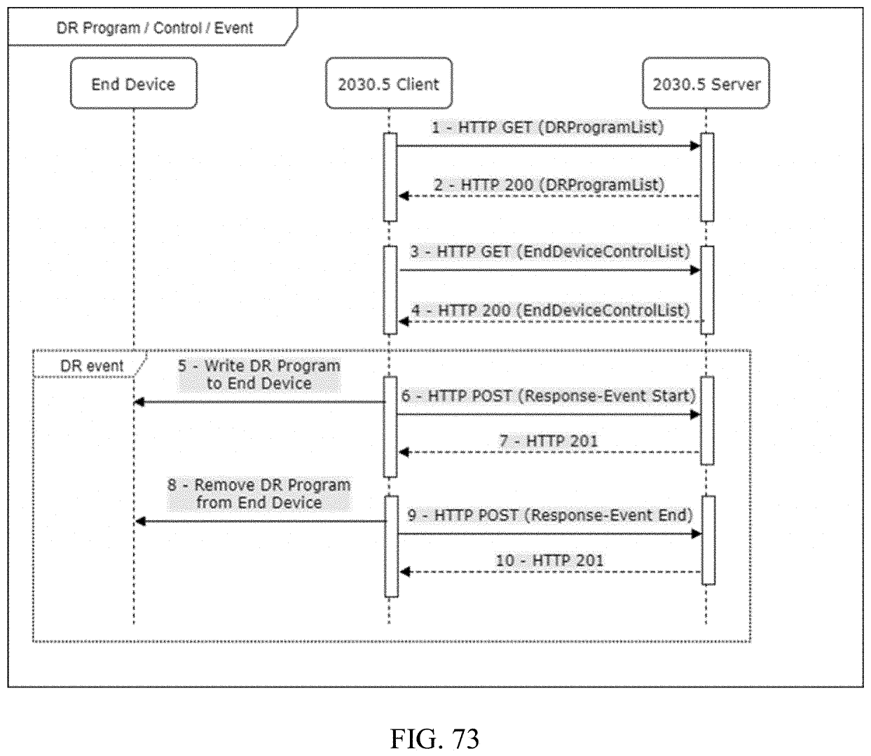

FIG. 73 shows a DRLC Program sequence diagram according to some embodiments.

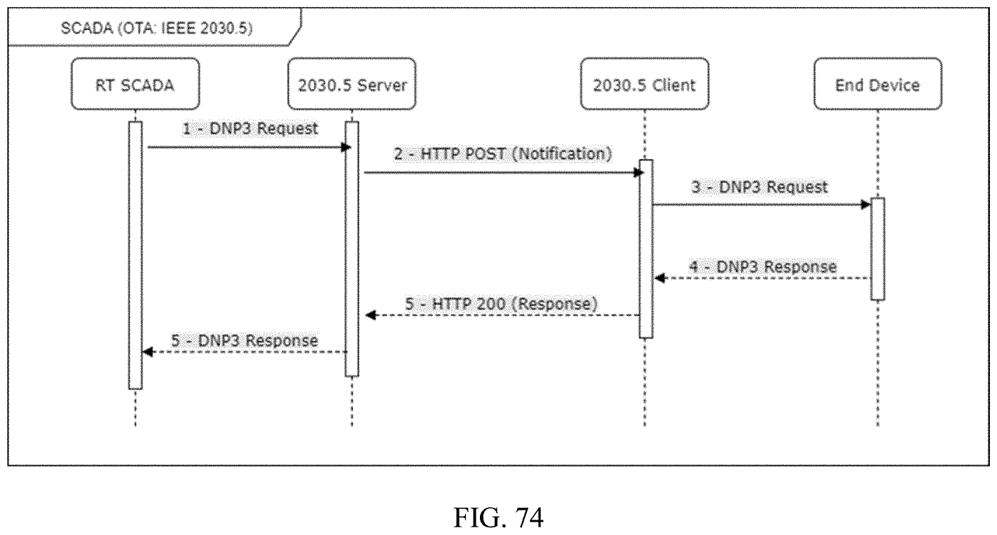

FIG. 74 shows a SCADA OTA 2030.5 sequence diagram according to some embodiments.

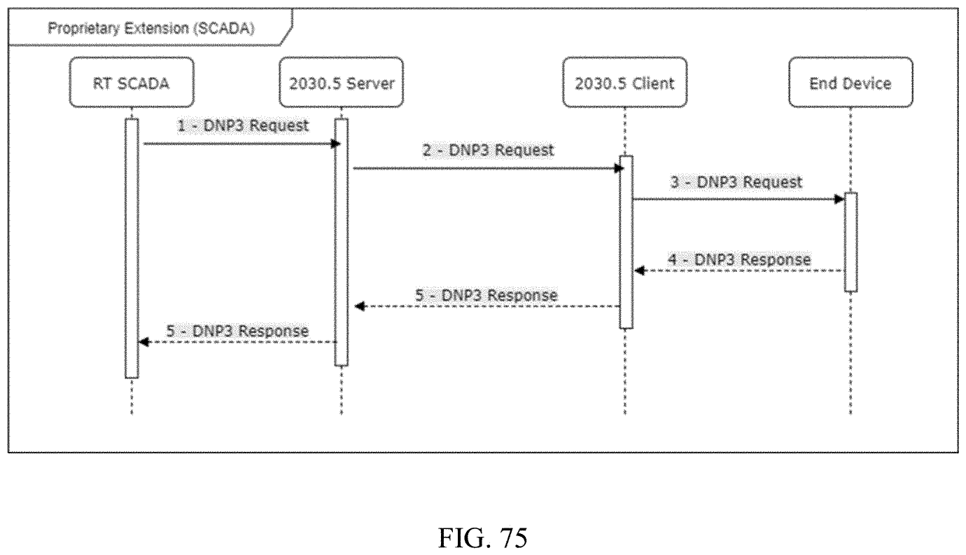

FIG. 75 shows a SCADA OTA HTTP sequence diagram according to some embodiments.

FIG. 76 shows an example of overlapping DER Programs from CSIP for Use Case 2 according to some embodiments.

FIG. 77 shows another example of overlapping DER Programs from CSIP for Use Case 2 according to some embodiments.

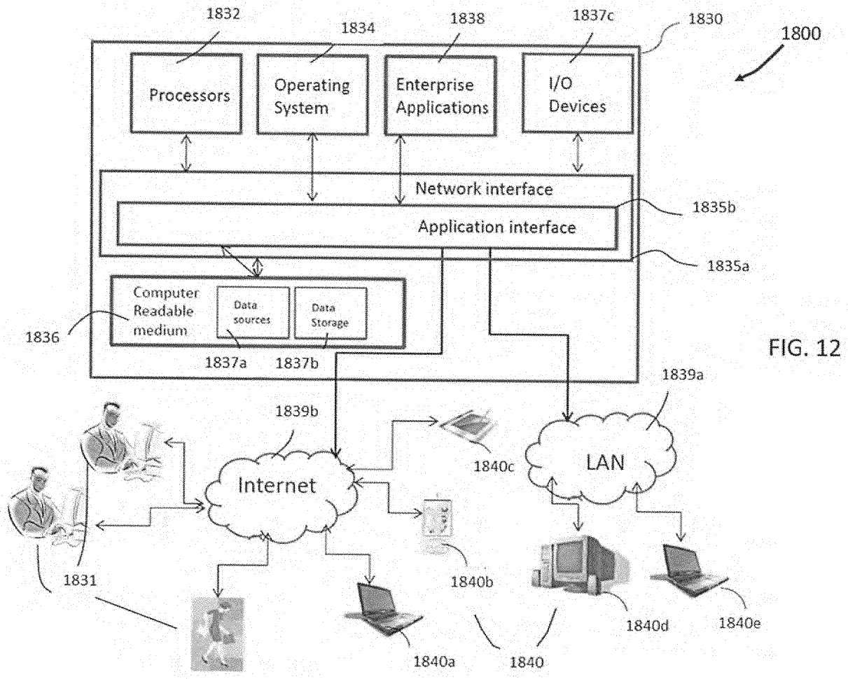

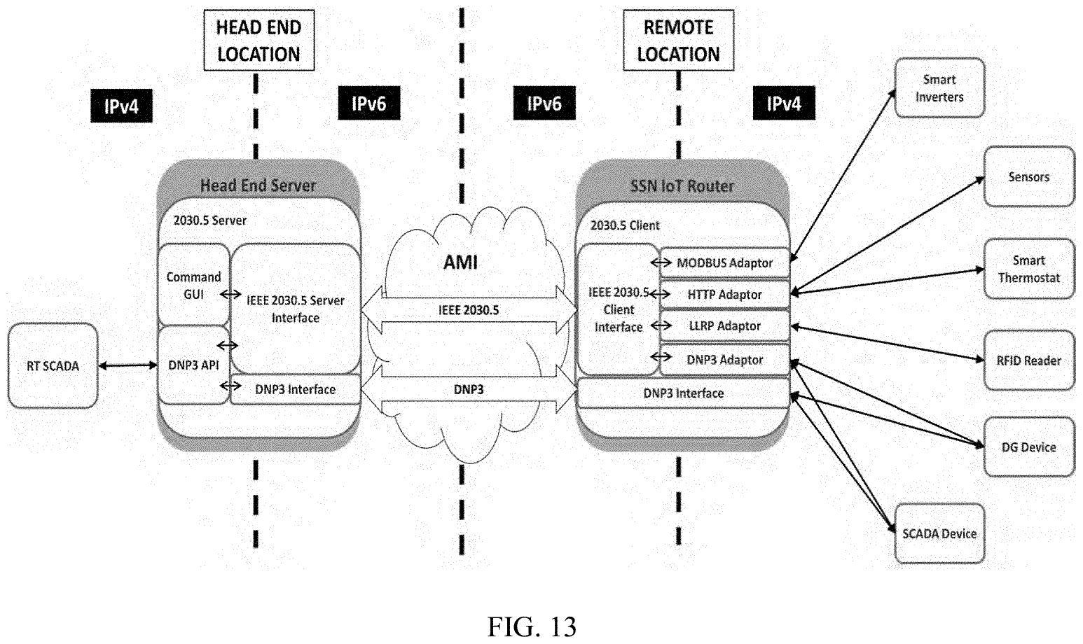

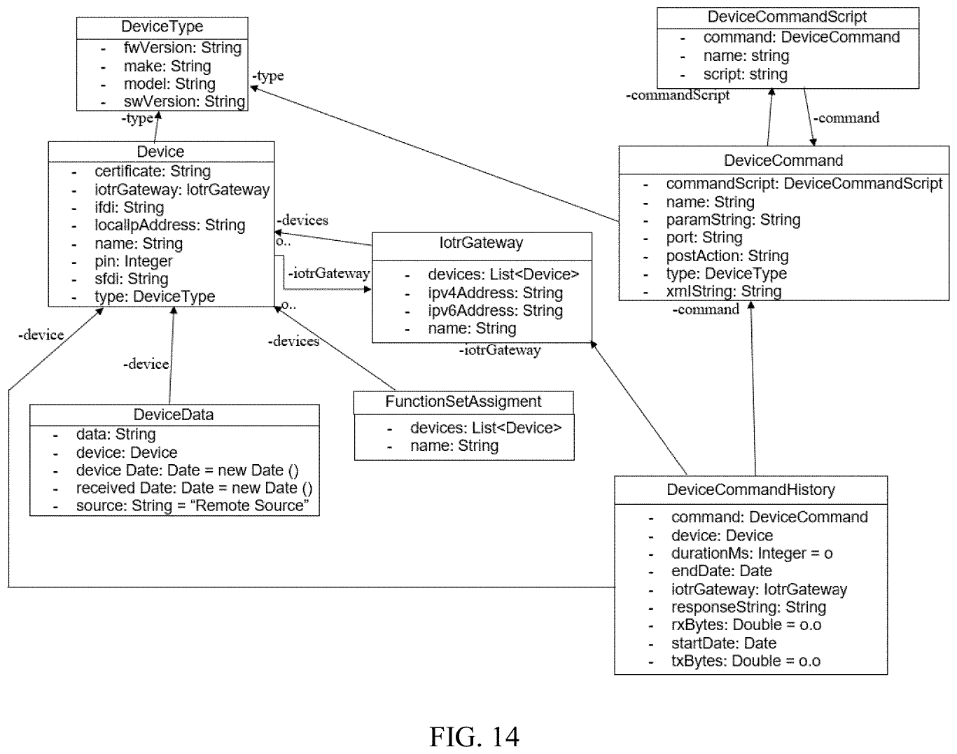

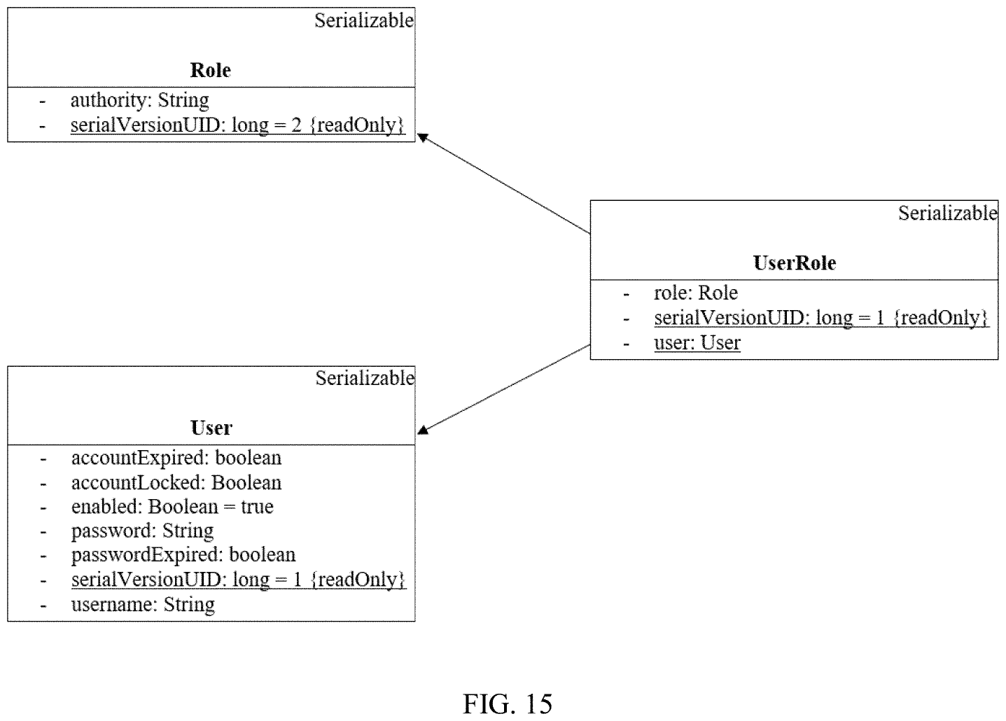

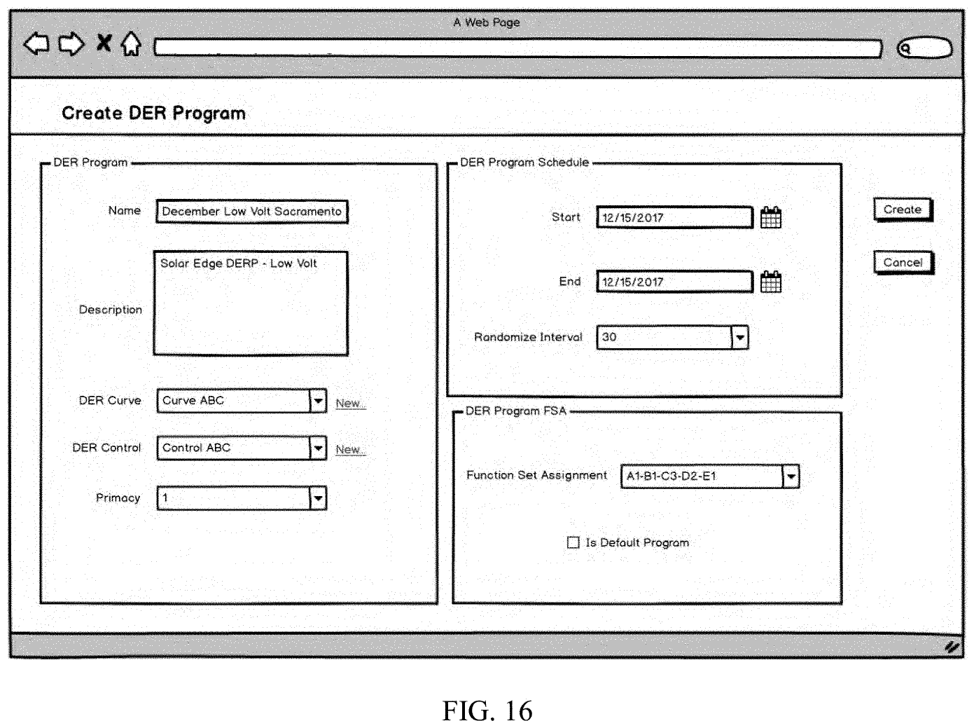

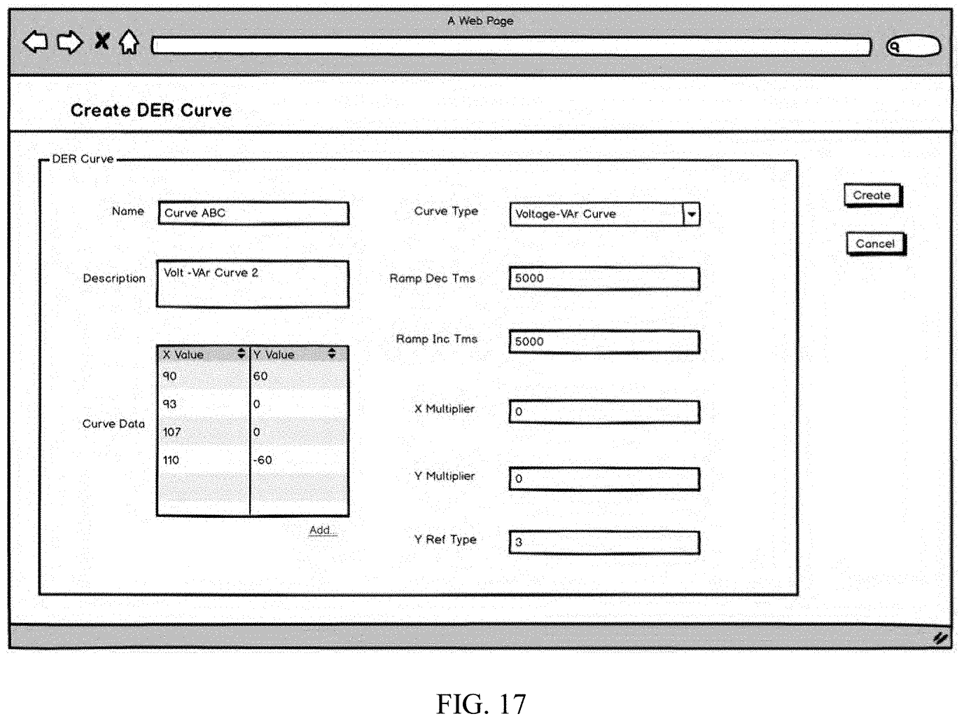

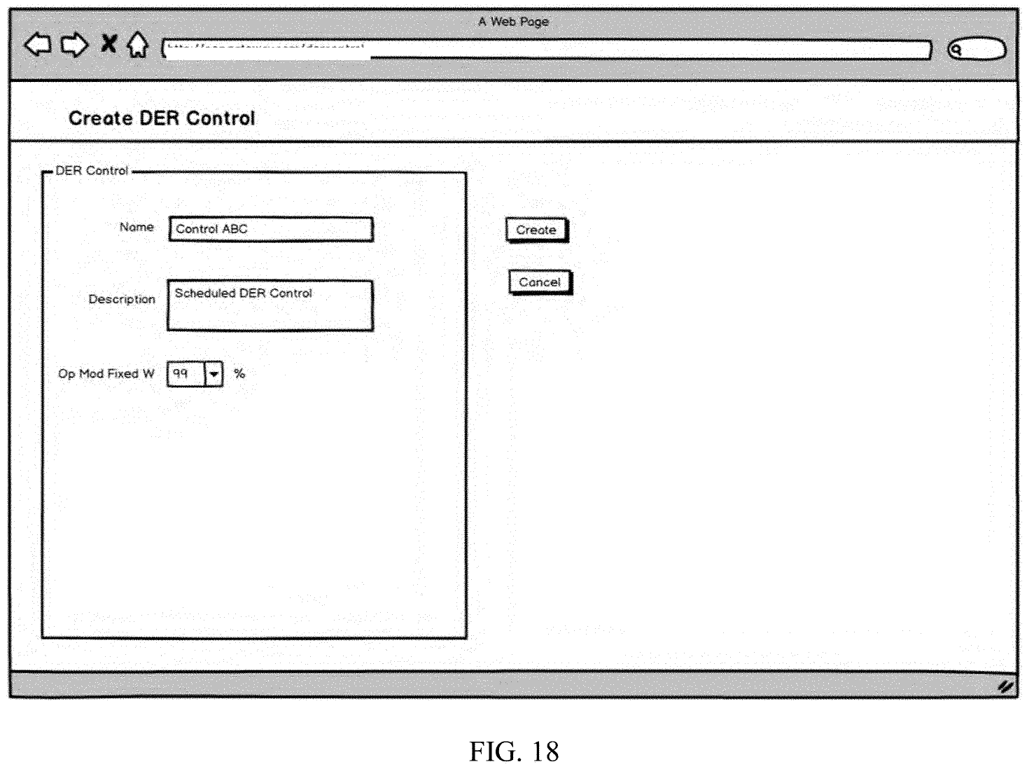

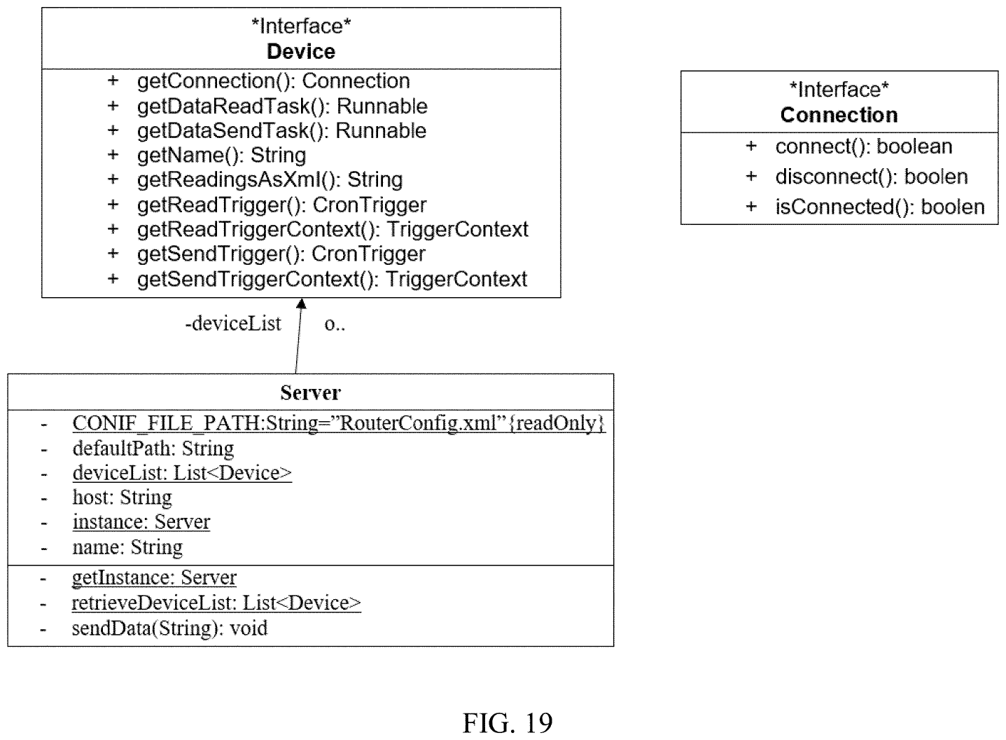

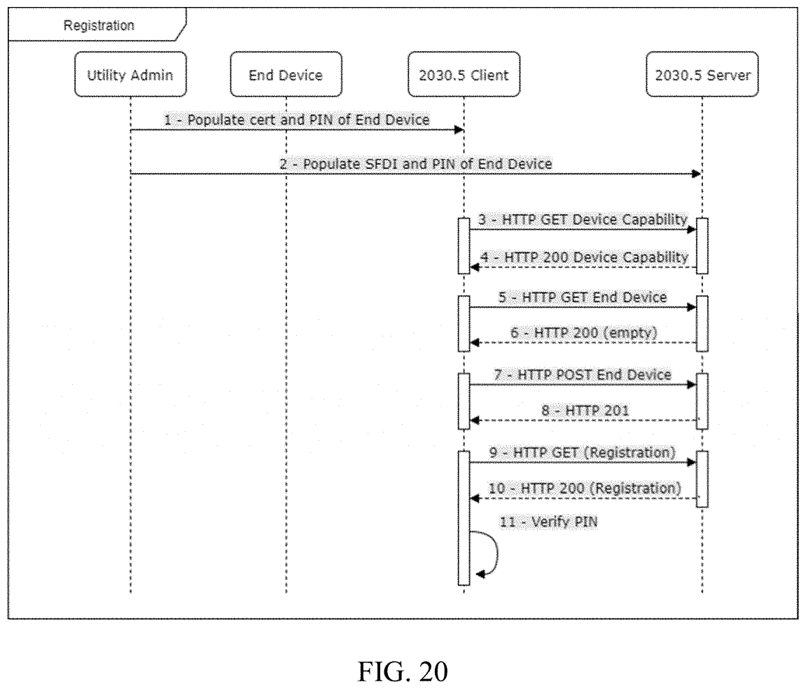

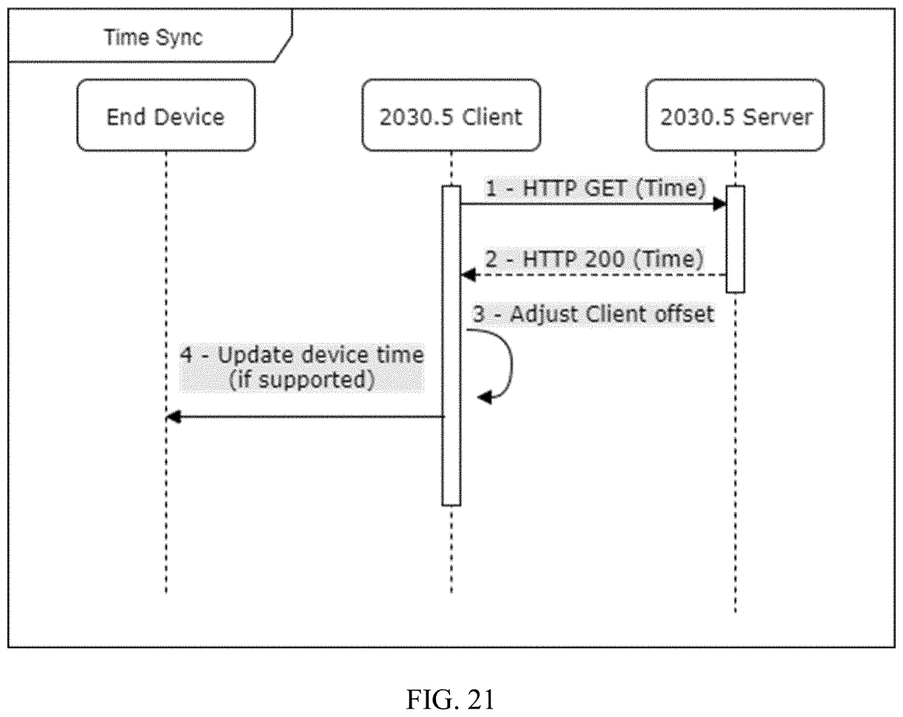

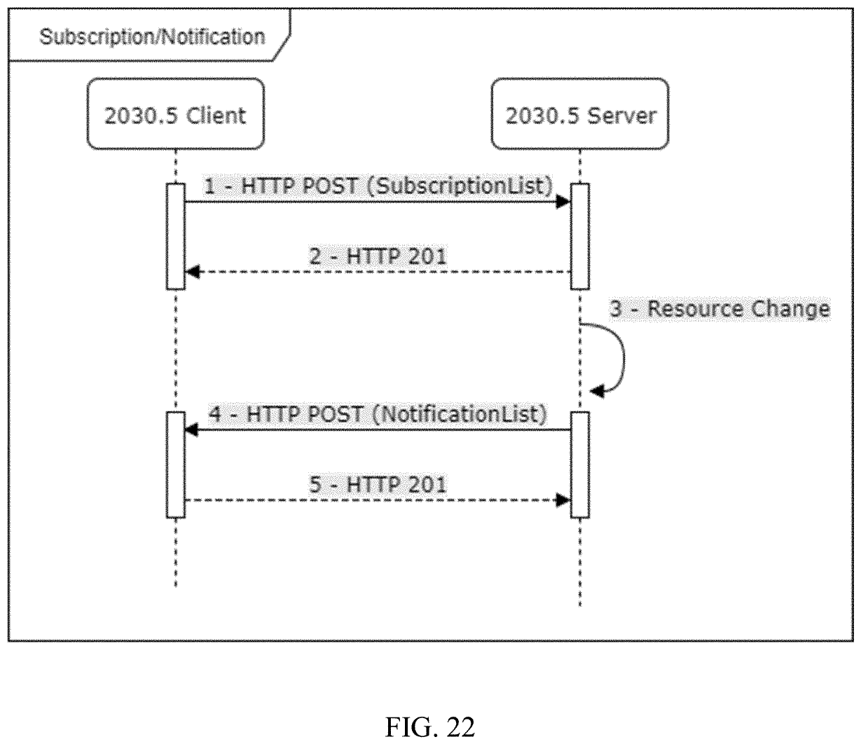

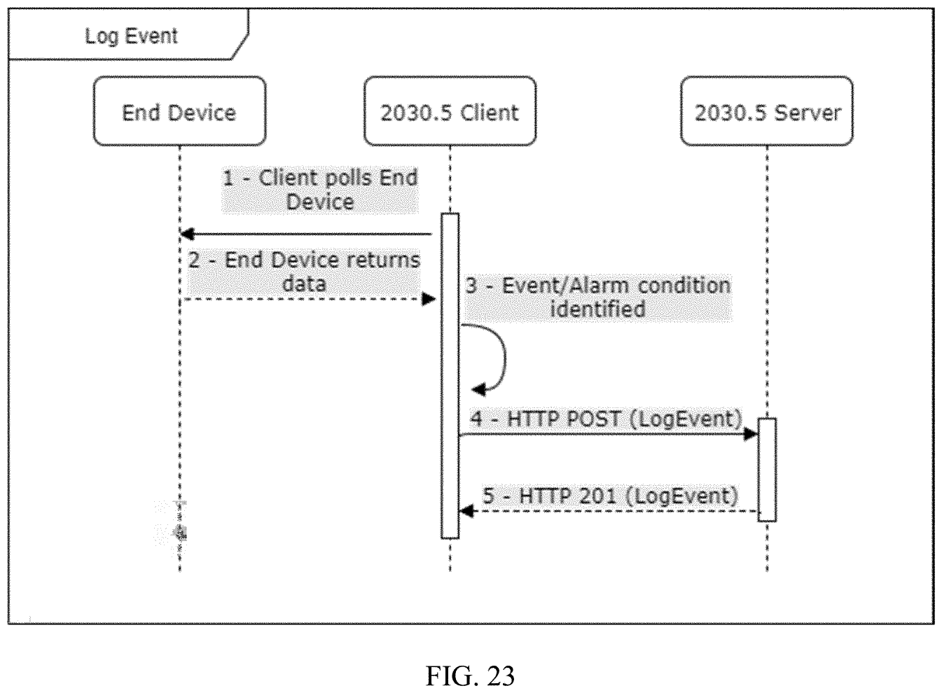

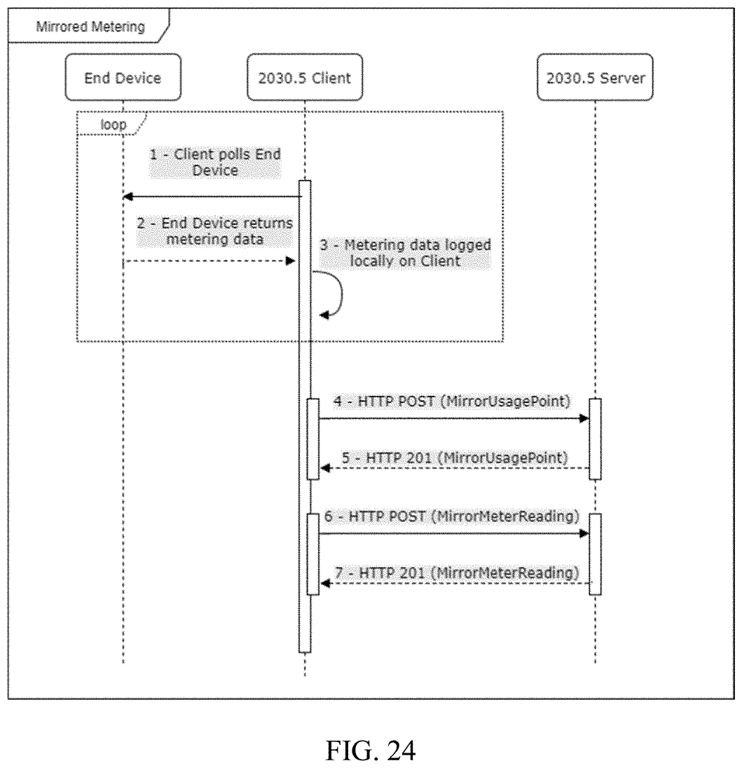

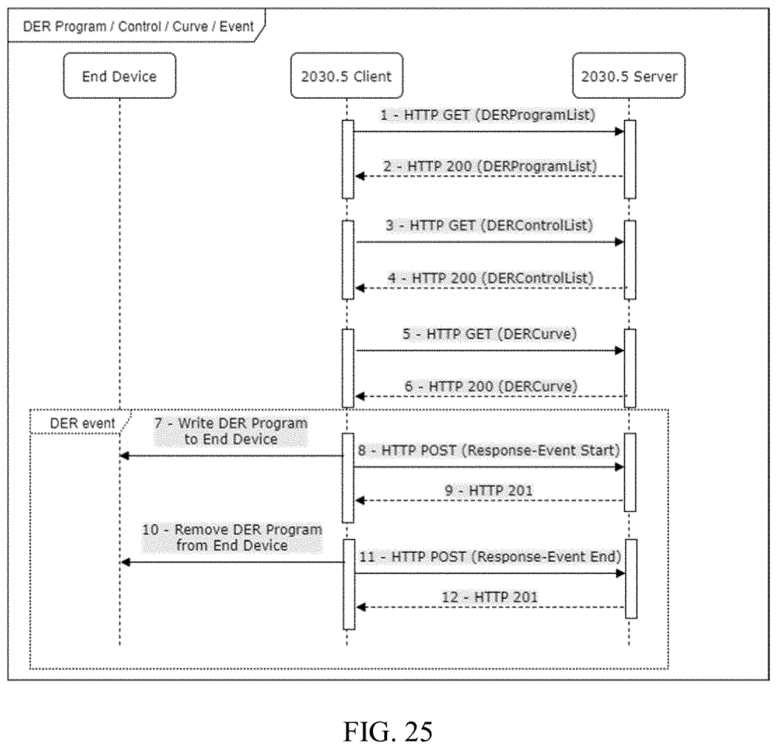

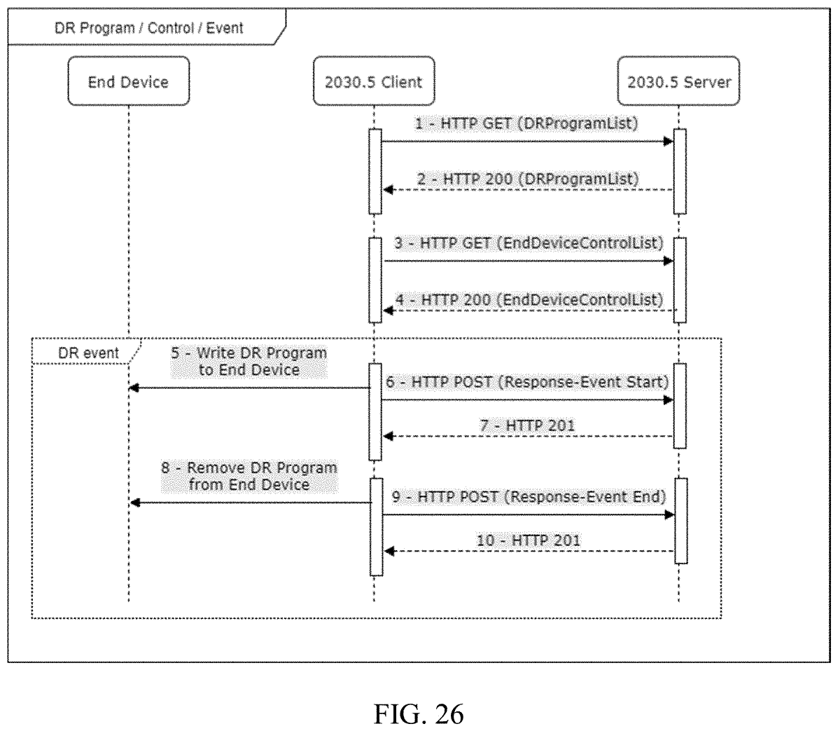

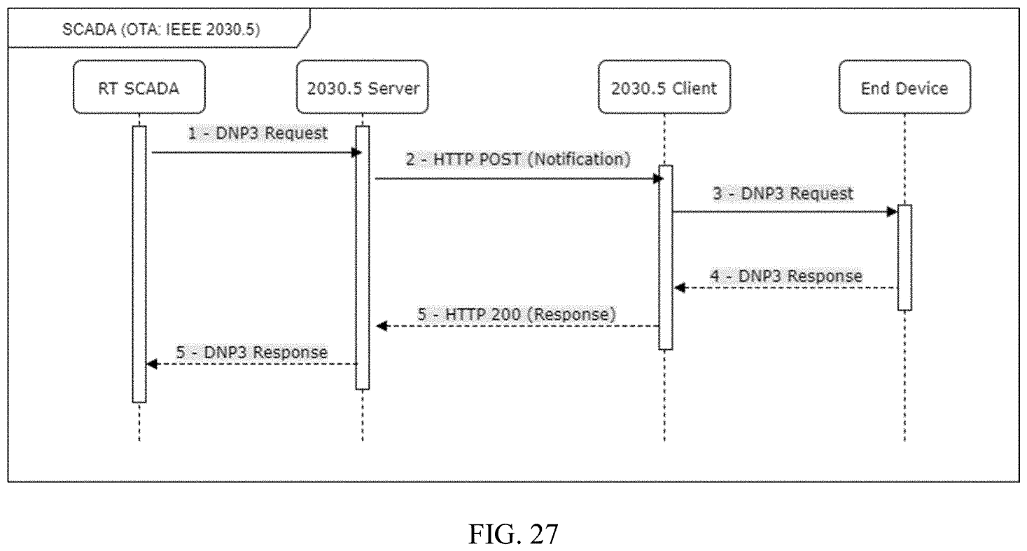

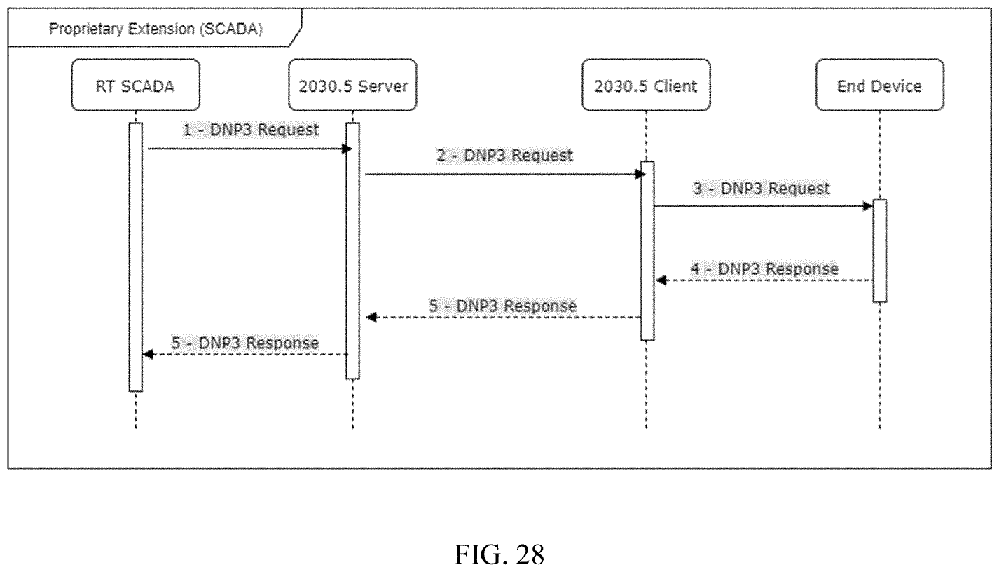

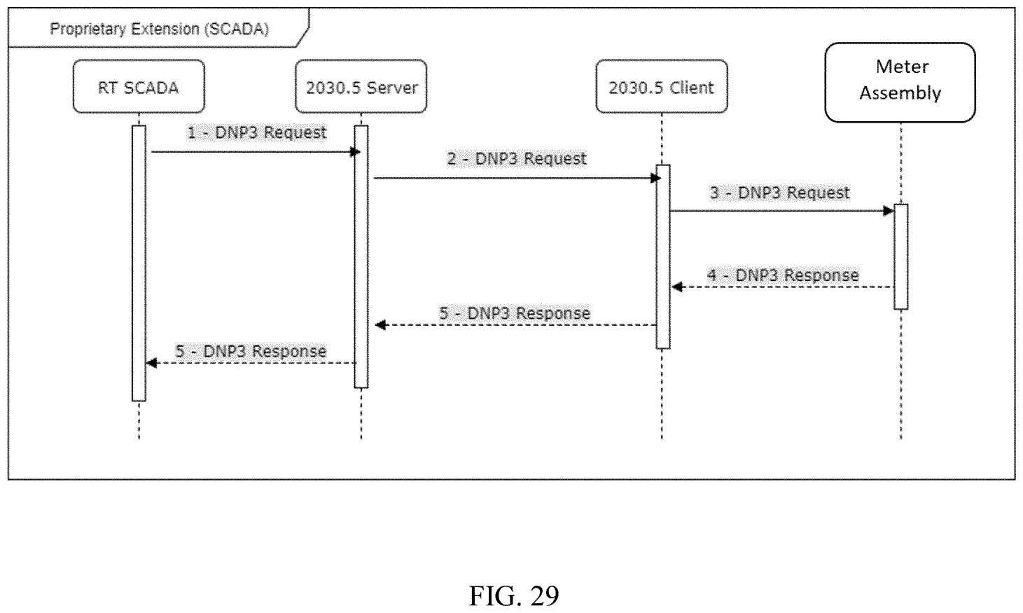

In some embodiments of the system, any of the meters or assemblies described herein uses at least one computing system within a networked metering or power network. For example, FIG. 12 shows an architecture diagram 1800 of a system for operating a smart meter system according to one embodiment of the system. The diagram 1800 shows one example of a system 1830 for performing one or more of the methods of the smart meter system that, as one non-limited example, can operate, read, send data and/or read data from the meter 100. As shown, the system 1830 can include at least one computing device, including one or more processors. Some processors can include processors 1832 residing in one or more conventional server platforms. In some embodiments, the system 1830 can include a network interface 1835a and/or an application interface 1835b coupled to at least one processor 1832 capable of running at least one operating system 1834, and one or more of the software modules 1838 (e.g., such as enterprise applications). In some embodiments, the software modules 1838 can include server-based software platform that can include smart meter system and method 100 software modules suitable for hosting at least one user account and at least one client account, as well as transferring data between one or more accounts.

Some embodiments of the system relate to or include a device or an apparatus for performing these operations of the operating system 1834 and/or the software modules 1838. The apparatus can be specially constructed for the required purpose, such as a special purpose computer. When defined as a special purpose computer, the computer can also perform other processing, program execution or routines that are not part of the special purpose, while still being capable of operating for the special purpose. Alternatively, the operations can be processed by a general purpose computer selectively activated or configured by one or more computer programs stored in the computer memory, cache, or obtained over a network. When data are obtained over a network the data can be processed by other computers on the network, e.g. a cloud of computing resources.

With the above embodiments in mind, it should be understood that the system can employ various computer-implemented operations involving smart meter system and method 100 data stored in computer systems. Moreover, the above-described databases and models throughout the smart meter system and method 100 can store analytical models and other data on computer-readable storage media within the system 1830 and on computer-readable storage media coupled to the system 1830. In addition, the above-described applications of the smart meter system and method 100 system can be stored on computer-readable storage media within the system 1830 and on computer-readable storage media coupled to the system 1830. These operations are those requiring physical manipulation of physical quantities. Usually, though not necessarily, these quantities take the form of electrical, electromagnetic, or magnetic signals, optical or magneto-optical form capable of being stored, transferred, combined, compared and otherwise manipulated.

Some embodiments include the system 1830 comprising at least one computer readable medium 1836 coupled to at least one data storage device 1837b, and/or at least one data source 1837a, and/or at least one input/output device 1837c. In some embodiments, the system embodied by the smart meter system and method 100 can be embodied as computer readable code on a computer readable medium 1836. The computer readable medium 1836 can be any data storage device that can store data, which can thereafter be read by a computer system (such as the system 1830). Examples of the computer readable medium 1836 can include hard drives, network attached storage (NAS), read-only memory, random-access memory, FLASH based memory, CD-ROMs, CD-Rs, CD-RWs, DVDs, magnetic tapes, other optical and non-optical data storage devices, or any other physical or material medium which can be used to tangibly store the desired information or data or instructions and which can be accessed by a computer or processor (including processors 1832).

In some embodiments of the system, the computer readable medium 1836 can also be distributed over a conventional computer network via the network interface 1835a so that the smart meter system and method 100 embodied by the computer readable code can be stored and executed in a distributed fashion. For example, in some embodiments, one or more components of the system 1830 can be tethered to send and/or receive data through a local area network (“LAN”) 1839a. In some embodiments, one or more components of the system 1830 can be tethered to send or receive data through an internet 1839b (e.g., a wireless internet). In some embodiments, at least one software application 1838 running on one or more processors 1832 can be configured to be coupled for communication over a network 1839a, 1839b. In some embodiments, one or more components of the network 1839a, 1839b can include one or more resources for data storage, including any other form of computer readable media beyond the media 1836 for storing information and including any form of computer readable media for communicating information from one electronic device to another electronic device.

In some embodiments, the network 1839a, 1839b can include wide area networks (“WAN”), direct connections (e.g., through a universal serial bus port) or other forms of computer-readable media 1836, or any combination thereof. Further, in some embodiments, one or more components of the network 1839a, 1839b can include a number of client devices which can be personal computers 1840 including for example desktop computers 1840d, laptop computers 1840a, 1840e, digital assistants and/or personal digital assistants (shown as 1840c), cellular phones or mobile phones or smart phones (shown as 1840b), pagers, digital tablets, internet appliances, and other processor-based devices. In general, a client device can be any type of external or internal devices such as a mouse, a CD-ROM, DVD, a keyboard, a display, or other input or output devices 1837c. In some embodiments, various other forms of computer-readable media 1836 can transmit or carry instructions to a computer 1840, including a router, private or public network, or other transmission device or channel, both wired and wireless. The software modules 1838 can be configured to send and receive data from a database (e.g., from a computer readable medium 1836 including data sources 1837a and data storage 1837b that can comprise a database), and data can be received by the software modules 1838 from at least one other source. In some embodiments, at least one of the software modules 1838 can be configured within the system to output data to a user 1831 via at least one smart meter (e.g., to a computer 1840 comprising a smart meter).

In some embodiments, the system 1830 as described above can enable one or more users 1831 to receive, analyze, input, modify, create and send data to and from the system 1830, including to and from one or more enterprise applications 1838 running on the system 1830. Some embodiments include at least one user 1831 coupled to a computer 1840 accessing one or more modules of the smart meter system and method 100 including at least one enterprise applications 1838 via a stationary I/O device 1837c through a LAN 1839a. In some other embodiments, the system 1830 can enable at least one user 1831 (through computer 1840) accessing enterprise applications 1838 via a stationary or mobile I/O device 1837c through an internet 1839a.

The embodiments of the present system can also be defined as a machine that transforms data from one state to another state. The data can represent an article, that can be represented as an electronic signal and electronically manipulate data. The transformed data can, in some cases, be visually depicted on a display, representing the physical object that results from the transformation of data. The transformed data can be saved to storage generally or in particular formats that enable the construction or depiction of a physical and tangible object. In some embodiments, the manipulation can be performed by a processor. In such an example, the processor thus transforms the data from one thing to another. Still further, the methods can be processed by one or more machines or processors that can be connected over a network. Each machine can transform data from one state or thing to another, and can also process data, save data to storage, transmit data over a network, display the result, or communicate the result to another machine. Computer-readable storage media, as used herein, refers to physical or tangible storage (as opposed to signals) and includes without limitation volatile and non-volatile, removable and non-removable storage media implemented in any method or technology for the tangible storage of information such as computer-readable instructions, data structures, program modules or other data.

Although method operations can be described in a specific order, it should be understood that other housekeeping operations can be performed in between operations, or operations can be adjusted so that they occur at slightly different times, or can be distributed in a system which allows the occurrence of the processing operations at various intervals associated with the processing, as long as the processing of the overlay operations are performed in the desired way.

It will be appreciated by those skilled in the art that while the system has been described above in connection with particular embodiments and examples, the system is not necessarily so limited, and that numerous other embodiments, examples, uses, modifications and departures from the embodiments, examples and uses are intended to be encompassed by the description herein.

Acting as Applicant's own lexicographer, Applicant defines the use of and/or, in terms of “A and/or B,” to mean one option could be “A and B” and another option could be “A or B.” Such an interpretation is consistent with ex parte Gross, where the Board established that “and/or” means element A alone, element B alone, or elements A and B together.

Simultaneously as used herein includes lag and or latency times associated with a conventional computer attempting to process multiple types of data at the same time.

### APPENDICES

APPENDIX A
List of non-functional components according to some embodiments.

| | | | | | Gap | |
|---|---|---|---|---|---|---|
| | | | | | (New, | |
| | | | Requirement | | Mod, No | Priority |
| ID | Category | Type | Name | Requirement Description | Change) | (H/M/L) |
| 1.01 | Look and Feel | Delightfulness | Improve user's | In some embodiments, a critical EPIC | | L |
| | | | experience | 2.26 Server and Client component to | | |
| | | | | creating an excellent user experience | | |
| | | | | inside User Application is | | |
| | | | | personalized contents; user | | |
| | | | | configurable. | | |
| | | | | In some embodiments, use | | |
| | | | | animations to make user interface | | |
| | | | | feel more alive. (ex., Change menu, | | |
| | | | | User Error, etc.) | | |
| | | | | In some embodiments, reduce | | |
| | | | | obstacles to minimize pain points and | | |
| | | | | frustrations that users may | | |
| | | | | experience throughout their journey. | | |
| 1.02 | Look and Feel | Simplicity | UI simplicity | In some embodiments, Server and | | H |
| | | | | Client modules are simple to | | |
| | | | | generate EPIC 2.26 use case messages | | |
| | | | | and receive events/responses. | | |
| 1.03 | Look and Feel | Style | GUI based | In some embodiments, use GUI- | | M |
| | | | Simulator & | based message generation and | | |
| | | | Configuration | polling functions | | |
| 2.01 | Usability and | Convenience | Remote | In some embodiments, the system | | H |
| | Human Factors | | configuration | administrator has remote access to | | |
| | | | | the target environment to configure | | |
| | | | | and maintain Server and Client | | |
| | | | | modules. | | |
| 2.02 | Usability and | Documentation | Development | Some embodiments include | | H |
| | Human Factors | | Document lists | High Level Architecture | | |
| | | | | Logical Data Model | | |
| | | | | Application Detailed Design | | |
| | | | | Performance Test | | |
| 2.03 | Usability and | Documentation | online help at | In some embodiments, an On-Line | | L |
| | Human Factors | | application | User Guide is provided inside of | | |
| | | | program | applications | | |
| 2.04 | Usability and | Documentation | User Manual/ | In some embodiments. User Manual | | H |
| | Human Factors | | Administrator | and System Admin Guide are | | |
| | | | Guide | provided. | | |
| 3.01 | Maintainability | Installation | Installation Guide | In some embodiments, to install | | H |
| | and Support | | | Server and Client module on the field | | |
| | | | | test environment (EPIC Server and | | |
| | | | | IoT Routers), 3rd party vendors | | |
| | | | | deliver following items, | | |
| | | | | Installation Guide | | |
| | | | | Installation Software Package | | |
| | | | | Release notes | | |
| 3.02 | Maintainability | Installation | Operating Systems - | In some embodiments, 3rd Party | | H |
| | and Support | | Requirements for | vendors provide detailed required | | |
| | | | EPIC 2.26 Servers | Hardware and Software (including | | |
| | | | | database) specifications for each | | |
| | | | | servers including Web Server, | | |
| | | | | Application Server, and Database | | |
| | | | | Server as below, | | |
| | | | | OS Version - Red Hat Enterprise Linux | | |
| | | | | v6.5 | | |
| | | | | RAM - 32-64 GB VRAM | | |
| | | | | CPU - 16 vCPUs | | |
| | | | | Disk - Utility standard configuration | | |
| | | | | for root, tempfs and other OS | | |
| | | | | volumes. | | |
| 3.03 | Maintainability | Installation | Operating Systems - | In some embodiments, the IoT Router | | H |
| | and Support | | Requirements for | uses the following specifications | | |
| | | | IoT Router | OS Version: Linux Ubuntu Core 16.04 | | |
| | | | | RAM: 1 GB SDRAM | | |
| | | | | CPU: Quad-Core ARM CPU @1 GHz | | |
| | | | | Flash: 4 GB | | |
| 3.04 | Maintainability | Installation | Operation systems - | In some embodiments, Client allows | | M |
| | and Support | | Requirements for | the use standard issued software for | | |
| | | | Client | running the application. In some | | |
| | | | | embodiments, the web client is | | |
| | | | | compatible with IE 10 or above. | | |
| | | | | Currently using IE 11.0 | | |
| 3.05 | Maintainability | Traceability | Results Review for | In some embodiments, Test plans, | | H |
| | and Support | | 3rd party | test scripts, and test results reviews | | |
| | | | applications | verify the following test activities: | | |
| | | | | Configuration | | |
| | | | | End-to-End integration | | |
| | | | | Security | | |
| | | | | Performance | | |
| | | | | Operational Readiness | | |
| | | | | Security/Penetration | | |
| | | | | User Acceptance Test (Internal) | | |
| 3.06 | Usability and | Training | End user training | In some embodiments, training is | | H |
| | Human Factors | | | provided for the following users: Test | | |
| | | | | Engineers, MS&E Engineers, SMOC | | |
| | | | | Operators, DCC SCADA Operators, IT | | |
| | | | | Engineers | | |
| 4.01 | Operational | Auditability | Auditability/ | In some embodiments, any | | M |
| | | | Debugging | configuration changes are logged. | | |
| | | | | In some embodiments, application | | |
| | | | | logs are stored for 15 days. In some | | |
| | | | | embodiments, the logs are used for | | |
| | | | | troubleshooting to tack event | | |
| | | | | messages. In some embodiments, the | | |
| | | | | logs include: | | |
| | | | | API message transaction log | | |
| | | | | Process Exception log | | |
| | | | | Application error log | | |
| | | | | In some embodiments, any | | |
| | | | | application setting changes are | | |
| | | | | audible. | | |
| | | | | In some embodiments, the data | | |
| | | | | coming to upstream and downstream | | |
| | | | | applications are auditable. | | |
| 4.02 | Operational | Reliability | Reliability | In some embodiments, the ability to | | L |
| | | | | remove and add updates without | | |
| | | | | incurring outages supporting the | | |
| | | | | need for 24/7/365 availability. | | |
| 4.03 | Operational | Scalability | Scalability - user | In some embodiments, scalability | | L |
| | | | | increases the number of users. In | | |
| | | | | some embodiments, the system | | |
| | | | | provides methods to extend max | | |
| | | | | number of users of a single system | | |
| | | | | and how to extend it. | | |
| | | | | In some embodiments, the solution | | |
| | | | | shall be able to support at least 50 | | |
| | | | | total users and 30 concurrent logged | | |
| | | | | in users. | | |
| 4.04 | Operational | Scalability | Scalability - | In some embodiments, the solution | | L |
| | | | endpoint device | shall have the scalability to increase | | |
| | | | | number of endpoint devices. In some | | |
| | | | | embodiments, methods extend a max | | |
| | | | | number of endpoint devices of a | | |
| | | | | single system and how to extend it. | | |
| 4.05 | Operational | Scalability | Scalability - data | In some embodiments, the system | | M |
| | | | volume | has the scalability to increase size of | | |
| | | | | data volume. In some embodiments, | | |
| | | | | the maximum size of data volume is | | |
| | | | | extended. | | |
| 4.06 | | Scalability | Scalability - | In some embodiments, operational | | L |
| | | | Operational Data | data shall be retained for 2 years. | | |
| | | | Retention | | | |
| 4.07 | Operational | Stability | Stability - system | In some embodiments, the system | | H |
| | | | performance | has the scalability to increase system | | |
| | | | (QoS) | hardware to keep QoS (response | | |
| | | | | time, data processing time, etc.) due | | |
| | | | | to increasing of endpoint devices, | | |
| | | | | increasing number of data points, | | |
| | | | | and/or increasing input volume of | | |
| | | | | data. | | |
| 4.08 | Operational | Stability | Development/Test | Some embodiments include 2 | | H |
| | | | Environment | separate delivery environments: (1) | | |
| | | | | ATS for Lab Test (2) Integration with | | |
| | | | | SMOC for AMI Field Test. | | |
| | | | | (1) Lab Test Environment (ATS) | | |
| | | | | Development Env: Refer to ATS | | |
| | | | | Requirements | | |
| | | | | Test Environment: Refer to ATS | | |
| | | | | Requirements | | |
| | | | | (2) Field Test - UC#2 and UC#7 | | |
| | | | | Field development (CD03 | | |
| | | | | Network) - In some embodiments. | | |
| | | | | Pilot Developers use this | | |
| | | | | environment to validate | | |
| | | | | functionalities. In some | | |
| | | | | embodiments, users will not have | | |
| | | | | access to this environment. | | |
| | | | | Field Test (SI03 Network) - In | | |
| | | | | some embodiments, testers use this | | |
| | | | | environment to certify changes prior | | |
| | | | | to installation into production. | | |
| 4.09 | Operational | Availability | Service | In some embodiments, percentage of | | L |
| | | | Availability | time the system needs to be available | | |
| | | | | to users is 99.9%. | | |
| | | | | In some embodiments. Systems | | |
| | | | | should be available 18 hours a day 7 | | |
| | | | | days a week. In some embodiments. | | |
| | | | | System maintenance is limited to the | | |
| | | | | hours of 10 p.m. to 4 a.m. | | |
| 4.10 | Operational | Availability | HA (High | In some embodiments, the Solution | | L |
| | | | Availability) | shall be highly available to all the | | |
| | | | | network devices in the UDN | | |
| | | | | environment in Production | | |
| | | | | environment. | | |
| 4.11 | Operational | Availability | DR (Disaster | In some embodiments, the solution | | L |
| | | | Recovery) | shall support automatic site failover | | |
| | | | | in Production environment | | |
| 4.12 | Operational | Availability | Fault Tolerant | In some embodiments, the Solution | | M |
| | | | | shall be critical for providing | | |
| | | | | information for the system's | | |
| | | | | infrastructure. In some | | |
| | | | | embodiments, the Server is resilient | | |
| | | | | to failure and allows for fast | | |
| | | | | recovery. | | |
| 4.13 | Operational | Backup | Software Backup | In some embodiments, incremental | | L |
| | | | | backups of all system data occurs | | |
| | | | | nightly, and a full backup occurs | | |
| | | | | weekly. In some embodiments, the | | |
| | | | | recommended backup time is | | |
| | | | | between 10 p.m. and 3 a.m. | | |
| 4.14 | Operational | Data retention | Data retention | In some embodiments, system data | | L |
| | | | capability | should be retained on-line for 3 years | | |
| | | | | in production environment. In some | | |
| | | | | embodiments, after 3 years work | | |
| | | | | data should be archived to offline | | |
| | | | | storage. | | |
| 5.01 | Performance | Capacity | Capacity | In some embodiments, the system is | | M |
| | | | | able to accommodate all system | | |
| | | | | users. | | |
| 5.02 | Performance | Efficiency | Response time | In some embodiments, there are no | | M |
| | | | | special performance requirements for | | |
| | | | | the system. In some embodiments, a | | |
| | | | | response time of up to 5 seconds for | | |
| | | | | an End-to-End On-Line transaction is | | |
| | | | | acceptable. | | |
| 5.03 | Performance | Efficiency | Performance | In some embodiments, a 3rd Party | | M |
| | | | Criteria for EPIC | vendor provides performance criteria | | |
| | | | Server | and related technical data such as | | |
| | | | applications | number of event messages per | | |
| | | | | second. | | |
| 5.04 | Performance | Efficiency | Performance | In some embodiments, 3rd Party | | M |
| | | | Criteria for loT | vendors provide performance criteria | | |
| | | | Router | and related technical data such as | | |
| | | | Applications | number of IEEE 2030.5 message | | |
| | | | | transactions per second. | | |
| 6.01 | Security | Privacy | Privacy | In some embodiments, the provides | | H |
| | | | | the ability to determine what data in | | |
| | | | | a computer system can be shared | | |
| | | | | with third parties. | | |
| 6.02 | Security | Security | Password | In some embodiments, the system is | — | H |
| | | | management | in compliance with IT-5303S (Utility | | |
| | | | | Standard). | | |
| 6.03 | Security | Security | Access log | In some embodiments, the system | | M |
| | | | | will automatically authenticate and | | |
| | | | | log in users based on their network ID | | |
| | | | | and password. | | |
| 6.04 | Security | Security | LDAP/Active | In some embodiments, if EPIC 2.26 | | H |
| | | | Directory | Servers are at AWS VPC, EPIC Servers | | |
| | | | | are integrated with LDAP/AD system | | |
| | | | | to authenticate and authorize user | | |
| | | | | accounts. | | |

APPENDIX B
Smart Inverter Register Maps according to some embodiments.
Fronius Primo 5.0-1 208-240

| | | | | | | | |
|---|---|---|---|---|---|---|---|
| | | | | Function | | | |
| Start | End | Size | R/W | Codes | Name | Description | Type |

SunSpec 1 - Common

| | | | | | | | |
|---|---|---|---|---|---|---|---|
| 40001 | 40002 | 2 | R | 0x03 | SID | Well-known value. Uniquely identifies this as a | uint32 |
| | | | | | | SunSpec Modbus Map | |
| 40003 | 40003 | 1 | R | 0x03 | ID | Well-known value. Uniquely identifies this as a | uint16 |
| | | | | | | SunSpec Common Model block | |
| 40004 | 40004 | 1 | R | 0x03 | L | Length of Common Model block | uint16 |
| 40005 | 40020 | 16 | R | 0x03 | Mn | Manufacturer | String32 |
| 40021 | 40036 | 16 | R | 0x03 | Md | Device model | String32 |
| 40037 | 40044 | 8 | R | 0x03 | Opt | Options | String16 |
| 40045 | 40052 | 8 | R | 0x03 | Vr | SW version of inverter | String16 |
| 40053 | 40068 | 16 | R | 0x03 | SN | Serial number of the inverter | String32 |
| 40069 | 40069 | 1 | R | 0x03 | DA | Modbus Device Address | uint16 |

SunSpec 11X - Inverter

| | | | | | | | |
|---|---|---|---|---|---|---|---|
| 40070 | 40070 | 1 | R | 0x03 | ID | Uniquely identifies this as a SunSpec Inverter Float | uint16 |
| | | | | | | Modbus Map; 111: single phase, 112: split phase, 113: | |
| | | | | | | three phase | |
| 40071 | 40071 | 1 | R | 0x03 | L | Length of inverter model block | uint16 |
| 40072 | 40073 | 2 | R | 0x03 | A | AC Total Current value | float32 |
| 40074 | 40075 | 2 | R | 0x03 | AphA | AC Phase-A Current value | float32 |
| 40076 | 40077 | 2 | R | 0x03 | AphB | AC Phase-B Current value | float32 |
| 40078 | 40079 | 2 | R | 0x03 | AphC | AC Phase-C Current value | float32 |
| 40080 | 40081 | 2 | R | 0x03 | PPVphAB | AC Voltage Phase-AB value | float32 |
| 40082 | 40083 | 2 | R | 0x03 | PPVphBC | AC Voltage Phase-BC value | float32 |
| 40084 | 40085 | 2 | R | 0x03 | PPVphCA | AC Voltage Phase-CA value | float32 |
| 40086 | 40087 | 2 | R | 0x03 | PhVphA | AC Voltage Phase-A-to-neutral value | float32 |
| 40088 | 40089 | 2 | R | 0x03 | PhVphB | AC Voltage Phase-B-to-neutral value | float32 |
| 40090 | 40091 | 2 | R | 0x03 | PhVphC | AC Voltage Phase-C-to-neutral value | float32 |
| 40092 | 40093 | 2 | R | 0x03 | W | AC Power value | float32 |
| 40094 | 40095 | 2 | R | 0x03 | Hz | AC Frequency value | float32 |
| 40096 | 40097 | 2 | R | 0x03 | VA | Apparent Power | float32 |
| 40098 | 40099 | 2 | R | 0x03 | VAr | Reactive Power | float32 |
| 40100 | 40101 | 2 | R | 0x03 | PF | Power Factor | float32 |
| 40102 | 40103 | 2 | R | 0x03 | WH | AC Lifetime Energy production | float32 |
| 40104 | 40105 | 2 | R | 0x03 | DCA | DC Current value | float32 |
| 40106 | 40107 | 2 | R | 0x03 | DCV | DC Voltage value | float32 |
| 40108 | 40109 | 2 | R | 0x03 | DCW | DC Power value | float32 |
| 40110 | 40111 | 2 | R | 0x03 | TmpCab | Cabinet Temperature | float32 |
| 40112 | 40113 | 2 | R | 0x03 | TmpSnk | Coolant or Heat Sink Temperature | float32 |
| 40114 | 40115 | 2 | R | 0x03 | TmpTrns | Transformer Temperature | float32 |
| 40116 | 40117 | 2 | R | 0x03 | TmpOt | Other Temperature | float32 |
| 40118 | 40118 | 1 | R | 0x03 | St | Operating State | enum16 |
| 40119 | 40119 | 1 | R | 0x03 | StVnd | Vendor Defined Operating State | enum16 |
| 40120 | 40121 | 2 | R | 0x03 | Evt1 | Event Flags (bits 0-31) | uint32 |
| 40122 | 40123 | 2 | R | 0x03 | Evt2 | Event Flags (bits 32-63) | uint32 |
| 40124 | 40125 | 2 | R | 0x03 | EvtVnd1 | Vendor Defined Event Flags (bits 0-31) | uint32 |
| 40126 | 40127 | 2 | R | 0x03 | EvtVnd2 | Vendor Defined Event Flags (bits 32-63) | uint32 |
| 40128 | 40129 | 2 | R | 0x03 | EvtVnd3 | Vendor Defined Event Flags (bits 64-95) | uint32 |
| 40130 | 40131 | 2 | R | 0x03 | EvtVnd4 | Vendor Defined Event Flags (bits 96-127) | uint32 |

SunSpec 120 - Nameplate

| | | | | | | | |
|---|---|---|---|---|---|---|---|
| 40132 | 40132 | 1 | R | 0x03 | ID | A well-known value 120. Uniquely identifies this | uint16 |
| | | | | | | as a SunSpec Nameplate Model | |
| 40133 | 40133 | 1 | R | 0x03 | L | Length of Nameplate Model | uint16 |
| 40134 | 40134 | 1 | R | 0x03 | DERTyp | Type of DER device. Default value is 4 to indicate | enum16 |
| | | | | | | PV device. | |
| 40135 | 40135 | 1 | R | 0x03 | WRtg | Continuous power output capability of the | uint16 |
| | | | | | | inverter. | |
| 40136 | 40136 | 1 | R | 0x03 | WRtg_SF | Scale factor | sunssf |
| 40137 | 40137 | 1 | R | 0x03 | VARtg | Continuous Volt-Ampere capability of the | uint16 |
| | | | | | | inverter. | |
| 40138 | 40138 | 1 | R | 0x03 | VARtg_SF | Scale factor | sunssf |
| 40139 | 40139 | 1 | R | 0x03 | VArRtgQ1 | Continuous VAR capability of the inverter in | int16 |
| | | | | | | quadrant 1. | |
| 40140 | 40140 | 1 | R | 0x03 | VArRtgQ2 | Continuous VAR capability of the inverter in | int16 |
| | | | | | | quadrant 2. | |
| 40141 | 40141 | 1 | R | 0x03 | VArRtgQ3 | Continuous VAR capability of the inverter in | int16 |
| | | | | | | quadrant 3. | |
| 40142 | 40142 | 1 | R | 0x03 | VArRtgQ4 | Continuous VAR capability of the inverter in | int16 |
| | | | | | | quadrant 4. | |
| 40143 | 40143 | 1 | R | 0x03 | VArRtg_SF | Scale factor | sunssf |
| 40144 | 40144 | 1 | R | 0x03 | ARtg | Maximum RMS AC current level capability of the | uint16 |
| | | | | | | inverter. | |
| 40145 | 40145 | 1 | R | 0x03 | ARtg_SF | Scale factor | sunssf |
| 40146 | 40146 | 1 | R | 0x03 | PFRtgQ1 | Minimum power factor capability of the inverter | int16 |
| | | | | | | in quadrant 1. | |
| 40147 | 40147 | 1 | R | 0x03 | PFRtgQ2 | Minimum power factor capability of the inverter | int16 |
| | | | | | | in quadrant 2. | |
| 40148 | 40148 | 1 | R | 0x03 | PFRtgQ3 | Minimum power factor capability of the inverter | int16 |
| | | | | | | in quadrant 3. | |
| 40149 | 40149 | 1 | R | 0x03 | PFRtgQ4 | Minimum power factor capability of the inverter | int16 |
| | | | | | | in quadrant 4. | |
| 40150 | 40150 | 1 | R | 0x03 | PFRtg_SF | Scale factor | sunssf |
| 40151 | 40151 | 1 | R | 0x03 | WHRtg | Nominal energy rating of storage device. | uint16 |
| 40152 | 40152 | 1 | R | 0x03 | WHRtg_SF | Scale factor | sunssf |
| 40153 | 40153 | 1 | R | 0x03 | AhrRtg | The useable capacity of the battery. Maximum | uint16 |
| | | | | | | charge minus minimum charge from a technology | |
| | | | | | | capability perspective (Amp-hour capacity rating). | |
| 40154 | 40154 | 1 | R | 0x03 | AhrRtg_SF | Scale factor for amp-hour rating. | sunssf |
| 40155 | 40155 | 1 | R | 0x03 | MaxChaRte | Maximum rate of energy transfer into the storage | uint16 |
| | | | | | | device. | |
| 40156 | 40156 | 1 | R | 0x03 | MaxChaRte_SF | Scale factor | sunssf |
| 40157 | 40157 | 1 | R | 0x03 | MaxDisChaRte | Maximum rate of energy transfer out of the | uint16 |
| | | | | | | storage device. | |
| 40158 | 40158 | 1 | R | 0x03 | MaxDisChaRte_SF | Scale factor | sunssf |
| 40159 | 40159 | 1 | R | 0x03 | Pad | Pad register | |

SunSpec 121 - Basic

| | | | | | | | |
|---|---|---|---|---|---|---|---|
| 40160 | 40160 | 1 | R | 0x03 | ID | A well-known value 121. Uniquely identifies this as a | uint16 |
| | | | | | | SunSpec Basic Settings Model | |
| 40161 | 40161 | 1 | R | 0x03 | L | Length of Basic Settings Model | uint16 |
| 40162 | 40162 | 1 | RW | 0x03 | WMax | Setting for maximum power output. Default to | uint16 |
| | | | | | | I_WRtg. | |
| 40163 | 40163 | 1 | RW | 0x03 | VRef | Voltage at the PCC. | uint16 |
| | | | | 0x06 | | | |
| | | | | 0x10 | | | |
| 40164 | 40164 | 1 | RW | 0x03 | VRefOfs | Offset from PCC to inverter. | int16 |
| | | | | 0x06 | | | |
| | | | | 0x10 | | | |
| 40165 | 40165 | 1 | RW | 0x03 | VMax | Setpoint for maximum voltage. | uint16 |
| | | | | 0x06 | | | |
| | | | | 0x10 | | | |
| 40166 | 40166 | 1 | RW | 0x03 | VMin | Setpoint for minimum voltage. | uint16 |
| | | | | 0x06 | | | |
| | | | | 0x10 | | | |
| 40167 | 40167 | 1 | RW | 0x03 | VAMax | Setpoint for maximum apparent power. Default to | uint16 |
| | | | | | | I_VARtg. | |
| 40168 | 40168 | 1 | R | 0x03 | VARMaxQ1 | Setting for maximum reactive power in quadrant 1. | int16 |
| | | | | | | Default to VArRtgQ1. | |
| 40169 | 40169 | 1 | R | 0x03 | VARMaxQ2 | Setting for maximum reactive power in quadrant 2. | int16 |
| | | | | | | Default to VArRtgQ2. | |
| 40170 | 40170 | 1 | R | 0x03 | VARMaxQ3 | Setting for maximum reactive power in quadrant 3 | int16 |
| | | | | | | Default to VArRtgQ3. | |
| 40171 | 40171 | 1 | R | 0x03 | VARMaxQ4 | Setting for maximum reactive power in quadrant 4 | int16 |
| | | | | | | Default to VArRtgQ4. | |
| 40172 | 40172 | 1 | R | 0x03 | WGra | Default ramp rate of change of active power due to | uint16 |
| | | | | | | command or internal action. | |
| 40173 | 40173 | 1 | R | 0x03 | PFMinQ1 | Setpoint for minimum power factor value in quadrant | int16 |
| | | | | | | 1. Default to PFRtgQ1. | |
| 40174 | 40174 | 1 | R | 0x03 | PFMinQ2 | Setpoint for minimum power factor value in quadrant | int16 |
| | | | | | | 2. Default to PFRtgQ2. | |
| 40175 | 40175 | 1 | R | 0x03 | PFMinQ3 | Setpoint for minimum power factor value in quadrant | int16 |
| | | | | | | 3. Default to PFRtgQ3. | |
| 40176 | 40176 | 1 | R | 0x03 | PFMinQ4 | Setpoint for minimum power factor value in quadrant | int16 |
| | | | | | | 4. Default to PFRtgQ4. | |
| 40177 | 40177 | 1 | R | 0x03 | VArAct | VAR action on change between charging and | enum16 |
| | | | | | | discharging: 1 = switch 2 = maintain VAR | |
| | | | | | | characterization. | |
| 40178 | 40178 | 1 | R | 0x03 | ClcTotVA | Calculation method for total apparent power. 1 = vector | enum16 |
| | | | | | | 2 = arithmetic. | |
| 40179 | 40179 | 1 | R | 0x03 | MaxRmpRte | Setpoint for maximum ramp rate as percentage of | uint16 |
| | | | | | | nominal maximum ramp rate. This setting will limit | |
| | | | | | | the rate that watts delivery to the grid can increase or | |
| | | | | | | decrease in response to intermittent PV generation. | |
| 40180 | 40180 | 1 | R | 0x03 | ECPNomHz | Setpoint for nominal frequency at the ECP. | uint16 |
| 40181 | 40181 | 1 | R | 0x03 | ConnPh | Identity of connected phase for single phase inverters. | enum16 |
| | | | | | | A = 1 B = 2 C = 3. | |
| 40182 | 40182 | 1 | R | 0x03 | WMax_SF | Scale factor for maximum power output. | sunssf |
| 40183 | 40183 | 1 | R | 0x03 | VRef_SF | Scale factor for voltage at the PCC. | sunssf |
| 40184 | 40184 | 1 | R | 0x03 | VRefOfs_SF | Scale factor for offset voltage. | sunssf |
| 40185 | 40185 | 1 | R | 0x03 | VMinMax_SF | Scale factor for min/max voltages. | sunssf |
| 40186 | 40186 | 1 | R | 0x03 | VAMax_SF | Scale factor for voltage at the PCC. | sunssf |
| 40187 | 40187 | 1 | R | 0x03 | VARMax_SF | Scale factor for reactive power. | sunssf |
| 40188 | 40188 | 1 | R | 0x03 | WGra_SF | Scale factor for default ramp rate. | sunssf |
| 40189 | 40189 | 1 | R | 0x03 | PFMin_SF | Scale factor for minimum power factor. | sunssf |
| 40190 | 40190 | 1 | R | 0x03 | MaxRmpRte_SF | Scale factor for maximum ramp percentage. | sunssf |
| 40191 | 40191 | 1 | R | 0x03 | ECPNomHz_SF | Scale factor for nominal frequency. | sunssf |

SunSpec 122 - Extended

| | | | | | | | |
|---|---|---|---|---|---|---|---|
| 40192 | 40192 | 1 | R | 0x03 | ID | A well-known value 122. Uniquely identifies this as a | uint16 |
| | | | | | | SunSpec Measurements_Status Model | |
| 40193 | 40193 | 1 | R | 0x03 | L | Length of Measurements_Status Model | uint16 |
| 40194 | 40194 | 1 | R | 0x03 | PVConn | PV inverter present/available status. Enumerated value. | bitfield16 |
| 40195 | 40195 | 1 | R | 0x03 | StorConn | Storage inverter present/available status. Enumerated | bitfield16 |
| | | | | | | value. | |
| 40196 | 40196 | 1 | R | 0x03 | ECPConn | ECP connection status: disconnected = 0 connected = 1. | bitfield16 |
| 40197 | 40200 | 4 | R | 0x03 | ActWh | AC lifetime active (real) energy output. | acc64 |
| 40201 | 40204 | 4 | R | 0x03 | ActVAh | AC lifetime apparent energy output. | acc64 |
| 40205 | 40208 | 4 | R | 0x03 | ActVArhQ1 | AC lifetime reactive energy output in quadrant 1. | acc64 |
| 40209 | 40212 | 4 | R | 0x03 | ActVArhQ2 | AC lifetime reactive energy output in quadrant 2. | acc64 |
| 40213 | 40216 | 4 | R | 0x03 | ActVArhQ3 | AC lifetime negative energy output in quadrant 3. | acc64 |
| 40217 | 40220 | 4 | R | 0x03 | ActVArhQ4 | AC lifetime reactive energy output in quadrant 4. | acc64 |
| 40221 | 40221 | 1 | R | 0x03 | VArAval | Amount of VARs available without impacting watts | int16 |
| | | | | | | output. | |
| 40222 | 40222 | 1 | R | 0x03 | VArAval_SF | Scale factor for available VARs. | sunssf |
| 40223 | 40223 | 1 | R | 0x03 | WAval | Amount of Watts available. | uint16 |
| 40224 | 40224 | 1 | R | 0x03 | WAval_SF | Scale factor for available Watts. | sunssf |
| 40225 | 40226 | 2 | R | 0x03 | StSetLimMsk | Bit Mask indicating setpoint limit(s) reached. Bits are | bitfield32 |
| | | | | | | persistent and must be cleared by the controller. | |
| 40227 | 40228 | 2 | R | 0x03 | StActCtl | Bit Mask indicating which inverter controls are | bitfield32 |
| | | | | | | currently active. | |
| 40229 | 40232 | 4 | R | 0x03 | TmSrc | Source of time synchronization. | String8 |
| 40233 | 40234 | 2 | R | 0x03 | Tms | Seconds since 01-01-2000 00:00 UTC | uint32 |
| 40235 | 40235 | 1 | R | 0x03 | RtSt | Bit Mask indicating which voltage ride through modes | bitfield16 |
| | | | | | | are currently active. | |
| 40236 | 40236 | 1 | R | 0x03 | Ris | Isolation resistance | uint16 |
| 40237 | 40237 | 1 | R | 0x03 | Ris_SF | Scale factor for Isolation resistance | int16 |

SunSpec 123 - Immediate Control

| | | | | | | | |
|---|---|---|---|---|---|---|---|
| 40238 | 40238 | 1 | R | 0x03 | ID | A well-known value 123. Uniquely identifies this as a | uint16 |
| | | | | | | SunSpec Immediate Controls Model | |
| 40239 | 40239 | 1 | R | 0x03 | L | Length of Immediate Controls Model | uint16 |
| 40240 | 40240 | 1 | RW | 0x03 | Conn_WinTms | Time window for connect/disconnect. | uint16 |
| | | | | 0x06 | | | |
| | | | | 0x10 | | | |
| 40241 | 40241 | 1 | RW | 0x03 | Conn_RvrtTms | Timeout period for connect/disconnect. | uint16 |
| | | | | 0x06 | | | |
| | | | | 0x10 | | | |
| 40242 | 40242 | 1 | RW | 0x03 | Conn | Enumerated valued. Connection control. | bitfield16 |
| | | | | 0x06 | | | |
| | | | | 0x10 | | | |
| 40243 | 40243 | 1 | RW | 0x03 | WMaxLimPct | Set power output to specified level. | uint16 |
| | | | | 0x06 | | | |
| | | | | 0x10 | | | |
| 40244 | 40244 | 1 | RW | 0x03 | WMaxLimPct_WinTms | Time window for power limit change. | uint16 |
| | | | | 0x06 | | | |
| | | | | 0x10 | | | |
| 40245 | 40245 | 1 | RW | 0x03 | WMaxLimPct_ RvrtTms | Timeout period for power limit. | uint16 |
| | | | | 0x06 | | | |
| | | | | 0x10 | | | |
| 40246 | 40246 | 1 | R | 0x03 | WMaxLimPct_ RmpTms | Ramp time for moving from current setpoint to new | uint16 |
| | | | | | | setpoint. | |
| 40247 | 40247 | 1 | RW | 0x03 | WMaxLim_Ena | Enumerated valued. Throttle enable/disable control. | enum16 |
| | | | | 0x06 | | | |
| | | | | 0x10 | | | |
| 40248 | 40248 | 1 | RW | 0x03 | OutPFSet | Set power factor to specific value - cosine of angle. | int16 |
| | | | | 0x06 | | | |
| | | | | 0x10 | | | |
| 40249 | 40249 | 1 | RW | 0x03 | OutPFSet_WinTms | Time window for power factor change. | uint16 |
| | | | | 0x06 | | | |
| | | | | 0x10 | | | |
| 40250 | 40250 | 1 | RW | 0x03 | OutPFSet_RvrtTms | Timeout period for power factor. | uint16 |
| | | | | 0x06 | | | |
| | | | | 0x10 | | | |
| 40251 | 40251 | 1 | RW | 0x03 | OutPFSet_RmpTms | Ramp time for moving from current setpoint to new | uint16 |
| | | | | 0x06 | | setpoint. | |
| | | | | 0x10 | | | |
| 40252 | 40252 | 1 | RW | 0x03 | OutPFSet_Ena | Enumerated valued. Fixed power factor enable/disable | enum16 |
| | | | | 0x06 | | control. | |
| | | | | 0x10 | | | |
| 40253 | 40253 | 1 | R | 0x03 | VArWMaxPct | Reactive power in percent of I_WMax. | int16 |
| 40254 | 40254 | 1 | RW | 0x03 | VArMaxPct | Reactive power in percent of I_VArMax. | int16 |
| | | | | 0x06 | | | |
| | | | | 0x10 | | | |
| 40255 | 40255 | 1 | R | 0x03 | VArAvalPct | Reactive power in percent of I_VArAval. | int16 |
| 40256 | 40256 | 1 | RW | 0x03 | VArPct_WinTms | Time window for VAR limit change. | uint16 |
| | | | | 0x06 | | | |
| | | | | 0x10 | | | |
| 40257 | 40257 | 1 | RW | 0x03 | VArPct_RvrtTms | Timeout period for VAR limit. | uint16 |
| | | | | 0x06 | | | |
| | | | | 0x10 | | | |
| 40258 | 40258 | 1 | RW | 0x03 | VArPct_RmpTms | Ramp time for moving from current setpoint to new | uint16 |
| | | | | 0x06 | | setpoint. | |
| | | | | 0x10 | | | |
| 40259 | 40259 | 1 | R | 0x03 | VArPct_Mod | Enumerated value. VAR limit mode. | enum16 |
| 40260 | 40260 | 1 | RW | 0x03 | VArPct_Ena | Enumerated valued. Fixed VAR enable/disable | enum16 |
| | | | | 0x06 | | control. | |
| | | | | 0x10 | | | |
| 40261 | 40261 | 1 | R | 0x03 | WMaxLimPct_SF | Scale factor for power output percent. | sunssf |
| 40262 | 40262 | 1 | R | 0x03 | OutPFSet_SF | Scale factor for power factor. | sunssf |
| 40263 | 40263 | 1 | R | 0x03 | VArPct_SF | Scale factor for reactive power. | sunssf |

SunSpec 160 - MultiMPPT

| | | | | | | | |
|---|---|---|---|---|---|---|---|
| 40264 | 40264 | 1 | R | 0x03 | ID | A well-known value 160. Uniquely identifies this as a | unit16 |
| | | | | | | SunSpec Multiple MPPT Inverter Extension Model | |
| | | | | | | Mode | |
| 40265 | 40265 | 1 | R | 0x03 | L | Length of Multiple MPPT Inverter Extension Model | uint16 |
| 40266 | 40266 | 1 | R | 0x03 | DCA_SF | Current Scale Factor | sunssf |
| 40267 | 40267 | 1 | R | 0x03 | DCV_SF | Voltage Scale Factor | sunssf |
| 40268 | 40268 | 1 | R | 0x03 | DCW_SF | Power Scale Factor | sunssf |
| 40269 | 40269 | 1 | R | 0x03 | DCWH_SF | Energy Scale Factor | sunssf |
| 40270 | 40271 | 2 | R | 0x03 | Evt | Global Events | bitfield32 |
| 40272 | 40272 | 1 | R | 0x03 | N | Number of Modules | uint16 |
| 40273 | 40273 | 1 | R | 0x03 | TmsPer | Timestamp Period | uint16 |
| 40274 | 40274 | 1 | R | 0x03 | 1_ID | Input ID | uint16 |
| 40275 | 40282 | 8 | R | 0x03 | 1_IDStr | Input ID Sting | String16 |
| 40283 | 40283 | 1 | R | 0x03 | 1_DCA | DC Current | uint16 |
| 40284 | 40284 | 1 | R | 0x03 | 1_DCV | DC Voltage | uint16 |
| 40285 | 40285 | 1 | R | 0x03 | 1_DCW | DC Power | uint16 |
| 40286 | 40287 | 2 | R | 0x03 | 1_DCWH | Lifetime Energy | acc32 |
| 40288 | 40289 | 2 | R | 0x03 | 1_Tms | Timestamp | uint32 |
| 40290 | 40290 | 1 | R | 0x03 | 1_Tmp | Temperature | int16 |
| 40291 | 40291 | 1 | R | 0x03 | 1_DCSt | Operating State | enum16 |
| 40292 | 40293 | 2 | R | 0x03 | 1_DCEvt | Module Events | bitfield32 |
| 40294 | 40294 | 1 | R | 0x03 | 2_ID | Input ID | uint16 |
| 40295 | 40302 | 8 | R | 0x03 | 2_IDStr | Input ID Sting | String16 |
| 40303 | 40303 | 1 | R | 0x03 | 2_DCA | DC Current | uint16 |
| 40304 | 40304 | 1 | R | 0x03 | 2_DCV | DC Voltage | uint16 |
| 40305 | 40305 | 1 | R | 0x03 | 2_DCW | DC Power | uint16 |
| 40306 | 40307 | 2 | R | 0x03 | 2_DCWH | Lifetime Energy | acc32 |
| 40308 | 40309 | 2 | R | 0x03 | 2_Tms | Timestamp | uint32 |
| 40310 | 40310 | 1 | R | 0x03 | 2_Tmp | Temperature | int16 |
| 40311 | 40311 | 1 | R | 0x03 | 2_DCSt | Operating State | enum16 |
| 40312 | 40313 | 2 | R | 0x03 | 2_DCEvt | Module Events | bitfield32 |

SunSpec 124 - Basic Storage

| | | | | | | | |
|---|---|---|---|---|---|---|---|
| 40314 | 40314 | 1 | R | 0x03 | ID | A well-known value 124. Uniquely identifies this as a | uint16 |
| | | | | | | SunSpec Basic Storage Controls Model | |
| 40315 | 40315 | 1 | R | 0x03 | L | Length of Basic Storage Controls | uint16 |
| 40316 | 40316 | 1 | R | 0x03 | WchaMax | Setpoint for maximum charge. | uint16 |
| | | | | | | Additional Fronius description: | |
| | | | | | | Reference Value for maximum Charge and Discharge. | |
| | | | | | | Multiply this value by InWRte to define maximum charging | |
| | | | | | | and OutWRte to define maximum discharging. Every rate | |
| | | | | | | between these two limits is allowed. Note that InWRte and | |
| | | | | | | OutWRte can be negative to define ranges for charging and | |
| | | | | | | discharging only. | |
| 40317 | 40317 | 1 | R | 0x03 | WchaGra | Setpoint for maximum charging rate. Default is MaxChaRte. | uint16 |
| 40318 | 40318 | 1 | R | 0x03 | WdisChaGra | Setpoint for maximum discharge rate. Default is | uint16 |
| | | | | | | MaxDisChaRte. | |
| 40319 | 40319 | 1 | RW | 0x03 | StorCtl_Mod | Activate hold/discharge/charge storage control mode. Bitfield | bitfield16 |
| | | | | 0x06 | | value. | |
| | | | | 0x10 | | Additional Fronius description: | |
| | | | | | | Active hold/discharge/charge storage control mode. Set the | |
| | | | | | | charge field to enable charging and the discharge field to | |
| | | | | | | enable discharging. Bitfield value. | |
| 40320 | 40320 | 1 | R | 0x03 | VAChaMax | Setpoint for maximum charging VA. | uint16 |
| 40321 | 40321 | 1 | RW | 0x03 | MinRsvPct | Setpoint for minimum reserve for storage as a percentage of | uint16 |
| | | | | 0x06 | | the nominal maximum storage. | |
| | | | | 0x10 | | | |
| 40322 | 40322 | 1 | R | 0x03 | ChaState | Currently available energy as a percent of the capacity rating. | uint16 |
| 40323 | 40323 | 1 | R | 0x03 | StorAval | State of charge (ChaState) minus storage reserve (MinRsvPct) | uint16 |
| | | | | | | times capacity rating (AhrRtg). | |
| 40324 | 40324 | 1 | R | 0x03 | InBatV | Internal battery voltage. | uint16 |
| 40325 | 40325 | 1 | R | 0x03 | ChaSt | Charge status of storage device. Enumerated value. | enum16 |
| 40326 | 40326 | 1 | RW | 0x03 | OutWRte | Percent of max discharge rate. | int16 |
| | | | | 0x06 | | Additional Fronius description: | |
| | | | | 0x10 | | Defines maximum Discharge rate. If not used than the default | |
| | | | | | | is 100 and wChaMax defines max. Discharge rate. See | |
| | | | | | | wChaMax for details. | |
| 40327 | 40327 | 1 | RW | 0x03 | InWRte | Percent of max charging rate. | int16 |
| | | | | 0x06 | | Additional Fronius description: | |
| | | | | 0x10 | | Defines maximum Charge rate. If not used than the default is | |
| | | | | | | 100 and wChaMax defines max. Charge rate. See wChaMax | |
| | | | | | | for details. | |
| 40328 | 40328 | 1 | R | 0x03 | InOutWRte_WinTms | Time window for charge/discharge rate change. | uint16 |
| 40329 | 40329 | 1 | R | 0x03 | InOutWRte_RvrtTms | Timeout period for charge/discharge rate. | uint16 |
| 40330 | 40330 | 1 | R | 0x03 | InOutWRte_RmpTms | Ramp time for moving from current setpoint to new setpoint. | uint16 |
| 40331 | 40331 | 1 | RW | 0x03 | ChaGriSet | Setpoint to enable/disable charging from grid | enum16 |
| | | | | 0x06 | | | |
| | | | | 0x10 | | | |
| 40332 | 40332 | 1 | R | 0x03 | WchaMax_SF | Scale factor for maximum charge. | sunssf |
| 40333 | 40333 | 1 | R | 0x03 | WchaDisChaGra_SF | Scale factor for maximum charge and discharge rate. | sunssf |
| 40334 | 40334 | 1 | R | 0x03 | VAChaMax_SF | Scale factor for maximum charging VA. | sunssf |
| 40335 | 40335 | 1 | R | 0x03 | MinRsvPct_SF | Scale factor for minimum reserve percentage. | sunssf |
| 40336 | 40336 | 1 | R | 0x03 | ChaState_SF | Scale factor for available energy percent. | sunssf |
| 40337 | 40337 | 1 | R | 0x03 | StorAval_SF | Scale factor for state of charge. | sunssf |
| 40338 | 40338 | 1 | R | 0x03 | InBatV_SF | Scale factor for battery voltage. | sunssf |
| 40339 | 40339 | 1 | R | 0x03 | InOutWRte_SF | Scale factor for percent charge/discharge rate. | sunssf |

SolarEdge SE5000A
SunSpec - Common

| Address | Size | Name | Type | Description |
|---|---|---|---|---|
| 40001 | 2 | C_SunSpec_ID | uint32 | Value = “SunS” |
| | | | | (0x53756e53). Uniquely |
| | | | | identifies this |
| | | | | as a SunSpec Modbus Map |
| 40003 | 1 | C_SunSpec_DID | uint16 | Value = 0x0001. |
| | | | | Uniquely identifies |
| | | | | this as a SunSpec |
| | | | | Common Model Block |
| 40004 | 1 | C_SunSpec_Length | uint16 | 65 = Length of block |
| | | | | in 16-bit registers |
| 40005 | 16 | C_Manufacturer | String(32) | Value Registered with |
| | | | | SunSpec = “SolarEdge” |
| 40021 | 16 | C_Model | String(32) | SolarEdge |
| | | | | Specific Value |
| 40045 | 8 | C_Version | String(16) | SolarEdge |
| | | | | Specific Value |
| 40053 | 16 | C_SerialNumber | String(32) | SolarEdge |
| | | | | Unique Value |
| 40069 | 1 | C_DeviceAddress | uint16 | Modbus Unit |
| | | | | ID |

SunSpec - Inverter

| Address | Size | Name | Type | Units | Description |
|---|---|---|---|---|---|
| 40070 | 1 | C_SunSpec_DID | uint16 | | 101 = single phase |
| | | | | | 102 = split phase₁ |
| | | | | | 103 = three phase |
| 40071 | 1 | C_SunSpec_Length | uint16 | Registers | 50 = Length of |
| | | | | | model block |
| 40072 | 1 | I_AC_Current | uint16 | Amps | AC Total |
| | | | | | Current value |
| 40073 | 1 | I_AC_CurrentA | uint16 | Amps | AC Phase A |
| | | | | | Current value |
| 40074 | 1 | I_AC_CurrentB | uint16 | Amps | AC Phase B |
| | | | | | Current value |
| 40075 | 1 | I_AC_CurrentC | uint16 | Amps | AC Phase C |
| | | | | | Current value |
| 40076 | 1 | I_AC_Current_SF | int16 | | AC Current |
| | | | | | scale factor |
| 40077 | 1 | I_AC_VoltageAB | uint16 | Volts | AC Voltage |
| | | | | | Phase AB value |
| 40078 | 1 | I_AC_VoltageBC | uint16 | Volts | AC Voltage |
| | | | | | Phase BC |
| | | | | | value |
| 40079 | 1 | I_AC_VoltageCA | uint16 | Volts | AC Voltage |
| | | | | | Phase CA |
| | | | | | value |
| 40080 | 1 | I_AC_VoltageAN 2 | uint16 | Volts | AC Voltage |
| | | | | | Phase A to N |
| | | | | | value |
| 40081 | 1 | I_AC_VoltageBN 1 | uint16 | Volts | AC Voltage |
| | | | | | Phase B to N |
| | | | | | value |
| 40082 | 1 | I_AC_VoltageCN 1 | uint16 | Volts | AC Voltage |
| | | | | | Phase C to N |
| | | | | | value |
| 40083 | 1 | I_AC_Voltage_SF | int16 | | AC Voltage |
| | | | | | scale factor |
| 40084 | 1 | I_AC_Power | int16 | Watts | AC Power |
| | | | | | value |
| 40085 | 1 | I_AC_Power_SF | int16 | | AC Power scale |
| | | | | | factor |
| 40086 | 1 | I_AC_Frequency | uint16 | Hertz | AC Frequency |
| | | | | | value |
| 40087 | 1 | I_AC_Frequency_SF | int16 | | Scale factor |
| 40088 | 1 | I_AC_VA | int16 | VA | Apparent |
| | | | | | Power |
| 40089 | 1 | I_AC_VA_SF | int16 | | Scale factor |
| 40090 | 1 | I_AC_VAR | int16 | VAR | Reactive Power |
| 40091 | 1 | I_AC_VAR_SF | int16 | | Scale factor |
| 40092 | 1 | I_AC_PF | int16 | % | Power Factor |
| 40093 | 1 | I_AC_PF_SF | int16 | | Scale factor |
| 40094 | 2 | I_AC_Energy_WH | acc32 | WattHours | AC Lifetime |
| | | | | | Energy |
| | | | | | production |
| 40096 | 1 | I_AC_Energy_WH_SF | uint16 | | Scale factor |
| 40097 | 1 | I_DC_Current | uint16 | Amps | DC Current |
| | | | | | value |
| 40098 | 1 | I_DC_Current_SF | int16 | | Scale factor |
| 40099 | 1 | I_DC_Voltage | uint16 | Volts | DC Voltage |
| | | | | | value |
| 40100 | 1 | I_DC_Voltage_SF | int16 | | Scale factor |
| 40101 | 1 | I_DC_Power | int16 | Watts | DC Power |
| | | | | | value |
| 40102 | 1 | I_DC_Power_SF | int16 | | Scale factor |
| 40104 | 1 | I_Temp_Sink | int16 | Degrees | Heat Sink |
| | | | | C. | Temperature |
| 40107 | 1 | I_Temp_SF | int16 | | Scale factor |
| 40108 | 1 | I_Status | uint16 | | Operating State |
| 40109 | 1 | I_Status_Vendor | uint16 | | Vendor-defined operating state |
| | | | | | and error codes. The errors |
| | | | | | displayed here are similar |
| | | | | | to the ones displayed on the |
| | | | | | inverter LCD screen. For error |
| | | | | | description, meaning and |
| | | | | | troubleshooting, refer to the |
| | | | | | SolarEdge Installation Guide. |

| | | | | | | |
|---|---|---|---|---|---|---|
| | | Read/ | | | | |
| Address | Size | Write | Name | Type | Value Range | Units |

Power Control Data and Control Registers

| | | | | | | |
|---|---|---|---|---|---|---|
| F000 | 1 | R | RRCR State | Uint16 | 0-15 | N/A |
| F001 | 1 | R/W | Active Power Limit | Uint16 | 0-100 | % |
| F002 | 2 | R/W | CosPhi | Float32 | −1.0-1.0 | N/A |
| F100 | 1 | R/W | Commit Power Control | Int16 | N/A | |
| | | | Settings | | | |
| F101 | 1 | R/W | Restore Power Control | Int16 | N/A | |
| | | | Default Settings | | | |
| F102 | 2 | R/W | PwrFrqDeratingConfig | Int32 | 0-4 | N/A |
| F104 | 2 | R/W | ReactivePwrConfig | Int32 | 0-4 | N/A |
| F106 | 2 | R/W | ReactPwrIterTime | Uint32 | 0-MAX_UINT32 | ms |
| F108 | 2 | R/W | ActivePwrGrad | Int32 | 0, 1 | N/A |
| F10A | 2 | R/W | FixedCosPhiPhase | Float32 | −1.0-1.0 | N/A |
| F10C | 2 | R/W | Fixed ReactPwr | Float32 | 0-MAX FLOAT | VAR |
| F10E | 2 | R/W | ReactCosPhiVsPX[0] | Float32 | 0-100 | P/Pmax % |
| F110 | 2 | R/W | ReactCosPhiVsPX[1] | Float32 | 0-100 | P/Pmax % |
| F112 | 2 | R/W | ReactCosPhiVsPX[2] | Float32 | 0-100 | P/Pmax % |
| F114 | 2 | R/W | ReactCosPhiVsPX[3] | Float32 | 0-100 | P/Pmax % |
| F116 | 2 | R/W | ReactCosPhiVsPX[4] | Float32 | 0-100 | P/Pmax % |
| F118 | 2 | R/W | ReactCosPhiVsPX[5] | Float32 | 0-100 | P/Pmax % |
| F11A | 2 | R/W | ReactCosPhiVsPY[0] | Float32 | −1.0-1.0 | N/A |
| F11C | 2 | R/W | ReactCosPhiVsPY[1] | Float32 | −1.0-1.0 | N/A |
| F11E | 2 | R/W | ReactCosPhiVsPY[2] | Float32 | −1.0-1.0 | N/A |
| F120 | 2 | R/W | ReactCosPhiVsPY[3] | Float32 | −1.0-1.0 | N/A |
| F122 | 2 | R/W | ReactCosPhiVsPY[4] | Float32 | −1.0-1.0 | N/A |
| F124 | 2 | R/W | ReactCosPhiVsPY[5] | Float32 | −1.0-1.0 | N/A |
| F126 | 2 | R/W | ReactQVsVgX[0] | Float32 | 0-200 | V/Vnom % |
| F128 | 2 | R/W | ReactQVsVgX[1] | Float32 | 0-200 | V/Vnom % |
| F12A | 2 | R/W | ReactQVsVgX[2] | Float32 | 0-200 | V/Vnom % |
| F12C | 2 | R/W | ReactQVsVgX[3] | Float32 | 0-200 | V/Vnom % |
| F12E | 2 | R/W | ReactQVsVgX[4] | Float32 | 0-200 | V/Vnom % |
| F130 | 2 | R/W | ReactQVsVgX[5] | Float32 | 0-200 | V/Vnom % |
| F132 | 2 | R/W | ReactQVsVgY[0] | Float32 | −100-100 | Q/Pmax % |
| F134 | 2 | R/W | ReactQVsVgY[1] | Float32 | −100-100 | Q/Pmax % |
| F136 | 2 | R/W | ReactQVsVgY[2] | Float32 | −100-100 | Q/Pmax % |
| F138 | 2 | R/W | ReactQVsVgY[3] | Float32 | −100-100 | Q/Pmax % |
| F13A | 2 | R/W | ReactQVsVgY[4] | Float32 | −100-100 | Q/Pmax % |
| F13C | 2 | R/W | ReactQVsVgY[5] | Float32 | −100-100 | Q/Pmax % |
| F13E | 2 | R/W | FRT_KFactor | Float32 | 0-16 | N/A |
| F140 | 2 | R/W | PowerReduce | Float32 | 0-100 | % |
| F142 | 2 | R/W | Advanced PwrControlEn | Int32 | 0-1 | N/A |
| F144 | 2 | R/W | FrtEn | Int32 | 0-1 | N/A |
| F146 | 2 | R/W | MaxWakeupFreq | Float32 | 0-100 | Hz |
| F148 | 2 | R/W | MinWakeupFreq | Float32 | 0-100 | Hz |
| F14A | 2 | R/W | MaxWakeupVg | Float32 | 0-500 | V |
| F14C | 2 | R/W | MinWakeupVg | Float32 | 0-500 | V |
| F14E | 2 | R/W | Vnom | Float32 | 0-500 | V |
| F150 | 2 | R | Inom | Float32 | 0-100 | A |
| F152 | 2 | R/W | PwrVsFreqX[0] | Float32 | 0-100 | Hz |
| F154 | 2 | R/W | PwrVsFreqX[1] | Float32 | 0-100 | Hz |
| F156 | 2 | R/W | PwrVsFreqY[0] | Float32 | 0-100 | % |
| F158 | 2 | R/W | PwrVsFreqY[1] | Float32 | 0-100 | % |
| F15A | 2 | R/W | ResetFreq | Float32 | 0-100 | Hz |
| F15C | 2 | R/W | MaxFreq | Float32 | 0-100 | Hz |
| F15E | 2 | R/W | ReactQVsPX[0] | Float32 | 0-100 | P/Pmax % |
| F160 | 2 | R/W | ReactQVsPX[1] | Float32 | 0-100 | P/Pmax % |
| F162 | 2 | R/W | ReactQVsPX[2] | Float32 | 0-100 | P/Pmax % |
| F164 | 2 | R/W | ReactQVsPX[3] | Float32 | 0-100 | P/Pmax % |
| F166 | 2 | R/W | ReactQVsPX[4] | Float32 | 0-100 | P/Pmax % |
| F168 | 2 | R/W | ReactQVsPX[5] | Float32 | 0-100 | P/Pmax % |
| F16A | 2 | R/W | ReactQVsPY[0] | Float32 | 0-100 | Q/Pmax % |
| F16C | 2 | R/W | ReactQVsPY[1] | Float32 | 0-100 | Q/Pmax % |
| F16E | 2 | R/W | ReactQVsPY[2] | Float32 | 0-100 | Q/Pmax % |
| F170 | 2 | R/W | ReactQVsPY[3] | Float32 | 0-100 | Q/Pmax % |
| F172 | 2 | R/W | ReactQVsPY[4] | Float32 | 0-100 | Q/Pmax % |
| F174 | 2 | R/W | ReactQVsPY[5] | Float32 | 0-100 | Q/Pmax % |
| F176 | 2 | R/W | PwrFrqDeratingResetTime | Uint32 | 0-MAX_UINT32 | ms |
| F178 | 2 | R/W | PwrFrqDeratingGradTime | Uint32 | 0-MAX_UINT32 | ms |
| F17A | 2 | R/W | ReactCosPhiVsPVgLockInMax | Float32 | 0-2 | V/Vnom |
| F17C | 2 | R/W | ReactCosPhiVsPVgLockInMin | Float32 | 0-2 | V/Vnom |
| F17E | 2 | R/W | ReactCosPhiVsPVgLockOutMax | Float32 | 0-2 | V/Vnom |
| F180 | 2 | R/W | ReactCosPhiVsPVgLockOutMin | Float32 | 0-2 | V/Vnom |
| F182 | 2 | R/W | ReactQVsVgPLockInMax | Float32 | 0-2 | P/Pmax |
| F184 | 2 | R/W | ReactQVsVgPLockInMin | Float32 | 0-2 | P/Pmax |
| F186 | 2 | R/W | ReactQVsVgPLockOutMax | Float32 | 0-2 | P/Pmax |
| F188 | 2 | R/W | ReactQVsVgPLockOutMin | Float32 | 0-2 | P/Pmax |
| F18A | 2 | R/W | ReactQVsVgType | Uint32 | 0-1 | N/A |
| F18C | 2 | R/W | PwrSoftStartTime | Uint32 | 0-MAX_UINT32 | ms |
| F18E | 2 | R/W | MaxCurrent | Float32 | 0-256 | A |
| F190 | 2 | R/W | PwrVsVgX[0] | Float32 | 0-2 | V/Vnom |
| F192 | 2 | R/W | PwrVsVgX[1] | Float32 | 0-2 | V/Vnom |
| F194 | 2 | R/W | PwrVsVgX[2] | Float32 | 0-2 | V/Vnom |
| F196 | 2 | R/W | PwrVsVgX[3] | Float32 | 0-2 | V/Vnom |
| F198 | 2 | R/W | PwrVsVgX[4] | Float32 | 0-2 | V/Vnom |
| F19A | 2 | R/W | PwrVsVgX[5] | Float32 | 0-2 | V/Vnom |
| F19C | 2 | R/W | PwrVsVgY[0] | Float32 | 0-1 | P/Pmax |
| F19E | 2 | R/W | PwrVsVgY[1] | Float32 | 0-1 | P/Pmax |
| F1A0 | 2 | R/W | PwrVsVgY[2] | Float32 | 0-1 | P/Pmax |
| F1A2 | 2 | R/W | PwrVsVgY[3] | Float32 | 0-1 | P/Pmax |
| F1A4 | 2 | R/W | PwrVsVgY[4] | Float32 | 0-1 | P/Pmax |
| F1A6 | 2 | R/W | PwrVsVgY[5] | Float32 | 0-1 | P/Pmax |
| F1A8 | 2 | R/W | DisconnectAtZeroPwrLim | Float32 | 0-1 | N/A |

Enhanced Dynamic Power Control Registers

| | | | | | | |
|---|---|---|---|---|---|---|
| F300 | 1 | R/W | Enable Dynamic Power | Uint16 | 0-1 | N/A |
| | | | Control | | | |
| F301 | 1 | R | Reserved | Uint16 | — | — |
| F302 | 2 | R | Reserved | Float32 | — | — |
| F304 | 2 | R | Max Active Power | Float32 | Inverter rating | W |
| F306 | 2 | R | Max Reactive Power | Float32 | Inverter rating | VAR |
| F308 | 1 | R/W | Active/Reactive | Uint16 | 0-1 | 0-1 |
| | | | Preference | | | |
| F309 | 1 | R/W | CosPhi/Q Preference | Uint16 | 0-1 | 0-1 |
| F30A | 2 | R/W | Reserved | Float32 | — | — |
| F30C | 2 | R/W | Active Power Limit | Float32 | 0-Max Active Power | W |
| F30E | 2 | R/W | Reactive Power Limit | Float32 | 0-Max Reactive Power | VAR |
| F310 | 2 | R/W | Command Timeout | Uint32 | 0-MAX_UINT32 | Sec |
| F312 | 2 | R/W | Fall-back Active Power | Float32 | 0-100 | % |
| | | | Limit | | | |
| F314 | 2 | R/W | Fall-back Reactive | Float32 | 0-100 | % |
| | | | Power Limit | | | |
| F316 | 2 | R/W | Fall-back CosPhi | Float32 | 0.85 | N/A |
| | | | (Cosine of the Phi | | | |
| | | | angle) | | | |
| F318 | 2 | R/W | Active Power Ramp-up | Float32 | 0-100 | %/min |
| | | | Rate | | | |
| F31A | 2 | R/W | Active Power Ramp- | Float32 | 0-100 | %/min |
| | | | down Rate | | | |
| F31C | 2 | R/W | Reactive Power Ramp- | Float32 | 0-100 | %/min |
| | | | up Rate | | | |
| F31E | 2 | R/W | Reactive Power Ramp- | Float32 | 0-100 | %/min |
| | | | down Rate | | | |
| F320 | 2 | R/W | Phi Change Rate | Float32 | 0-pi | rad/min |
| F322 | 2 | R/W | Dynamic Active Power | Float32 | 0-100 | % |
| | | | Limit | | | |
| F324 | 2 | R/W | Dynamic Reactive | Float32 | 0-100 | % |
| | | | Power Ref | | | |
| F326 | 2 | R/W | Dynamic CosPhi Ref | Float32 | 0-pi | N/A |

APPENDIX C
SCADA DNP Point Maps according to some embodiments.
Cooper Form 6 Line Recloser
BINARY INPUT TABLE

| Index | Class | Name |
|---|---|---|
| 0 | 1 | WB(#12)(Dynamic Closed Status) |
| 1 | 1 | WB(#13)(Dynamic Open Status) |
| 2 | 1 | Control is Locked Out |
| 3 | 1 | Any Control or System Alarm |
| 4 | 1 | Above Min. Trip |
| 5 | 1 | Supervisory Off |
| 6 | 1 | Non-Reclosing |
| 7 | 1 | Ground Trip Blocked |
| 8 | 1 | SEF Blocked |
| 9 | 1 | CLPU Blocked |
| 10 | 1 | Normal Profile Selected |
| 11 | 1 | Alt Profile 1 Selected |
| 12 | 1 | Switch Mode Active |
| 13 | 1 | Trip TCC2 Only Mode |
| 14 | 1 | Hot Line Tag |
| 15 | 1 | A-Phase Bus Voltage Present |
| 16 | 1 | B-Phase Bus Voltage Present |
| 17 | 1 | C-Phase Bus Voltage Present |
| 18 | 1 | Reverse Power Flow |
| 19 | 1 | WB(#11)(Bat Test Finished) |
| 20 | 1 | No AC Power (pole only) |
| 21 | 1 | Battery Alarm |
| 22 | 1 | ci8: NA |
| 23 | 1 | ci9: NA |
| 24 | 1 | ci10: NA |
| 25 | 1 | ci11: NA |
| 26 | 1 | co1: Comms Pwr ON |
| 27 | 1 | co2: Spare |
| 28 | 1 | co3: GEN TT |
| 29 | 1 | co4: GEN TT Comms |
| 30 | 1 | ss1: 52a |
| 31 | 1 | co5: NA |
| 32 | 1 | co6: NA |
| 33 | 1 | co7: NA |
| 34 | 1 | co8: NA |
| 35 | 1 | Open Int. is Timing |
| 36 | 1 | Sectionalizer Trip |
| 37 | 1 | Sectionalizer Cut-Out |
| 38 | 1 | Sectionalizer Cut-In |
| 39 | 1 | Reclose Retry: Enabled |
| 40 | 1 | A Phase Fault |
| 41 | 1 | B Phase Fault |
| 42 | 1 | C Phase Fault |
| 43 | 1 | Gnd Fault |
| 44 | 1 | SGF Fault |
| 45 | 1 | ci1: Remote Trip - Lockout |
| 46 | 1 | ci2: Comm Problem |
| 47 | 1 | ci3: External RB |
| 48 | 1 | ci4: NA |
| 49 | 1 | ci5: NA |
| 50 | 1 | ci6: NA |
| 51 | 1 | ci7: NA |
| 52 | 1 | Ground Overcurrent Alarm |
| 53 | 1 | Phase Overcurrent Alarm |
| 54 | 1 | NegSeq Overcurrent Alarm |
| 55 | 1 | WB_HLT_LockON |
| 56 | 1 | Comm_HLT_LockON |
| 57 | 1 | Local_HLT_LockON |
| 58 | 1 | CCI: Control Circuit Interrupted |
| 59 | 1 | Control OK |
| 60 | 1 | Frequency Trip |
| 61 | 1 | Voltage Trip |
| 62 | 1 | Sync-Check is Enabled |
| 63 | 1 | Block of Close is Active |
| 64 | 1 | WB(#02)(Instantaneous Lockout) |
| 65 | 1 | Pole Failure (NV) |
| 66 | 1 | Failure to Trip (NV) |
| 67 | 1 | Failure to Close (NV) |
| 68 | 1 | Self-Clear Alarm (NV) |
| 69 | 1 | Underfrequency Alarm |
| 70 | 1 | Overfrequency Alarm |
| 71 | 1 | Undervoltage Alarm |
| 72 | 1 | Overvoltage Alarm |
| 73 | 1 | Power Factor Alarm |
| 74 | 1 | Loss of Sensing (V) |
| 75 | 1 | DemandAlarm(\|P\|: 3phase) |
| 76 | 1 | DemandAlarm(\|Q\|: 3phase) |
| 77 | 1 | Control Power OK |
| 78 | 1 | WB(#10)(Gen TT Cut-In) |
| 79 | 1 | Alt Profile 3 Selected |
| 80 | 1 | X-Phase Voltage Present |
| 81 | 1 | Y-Phase Voltage Present |
| 82 | 1 | Z-Phase Voltage Present |
| 83 | 1 | Recloser is NOVA |
| 84 | 1 | LS: Cut-In Permitted |
| 85 | 1 | TCC1 Cut-In |

BINARY OUTPUT TABLE

| Index | Name |
|---|---|
| 0 | Close Mechanism |
| 1 | Trip Mechanism |
| 2 | SGF Cut-In |
| 3 | SGF Cut-Out |
| 4 | CLPU Cut-IN |
| 5 | CLPU Cut-Out |
| 6 | reserved-6 |
| 7 | reserved-7 |
| 8 | Profile: Normal |
| 9 | AP1 Deselec |
| 10 | AP2 Deselect |
| 11 | Profile: Alt1 |
| 12 | Profile: Alt2 |
| 13 | TCC1 Cut-In |
| 14 | TCC1 Cut-Out |
| 15 | Reset Targets |
| 16 | Reset Demand |
| 17 | Reset Alarms |
| 18 | Test Battery |
| 19 | HLT Cut-In |
| 20 | HLT Cut-Out |
| 21 | RCLR Retry Cut-In |
| 22 | RCLR Retry Cut-Out |
| 23 | Trip Recloser |
| 24 | Sync Check Cut-In |
| 25 | Sync CheckCut-Out |
| 26 | Alt#3 (Future) |
| 27 | RB Cut-Out |
| 28 | GRD Trip Cut-Out |
| 29 | GRD TRip Cut-In |
| 30 | RCLR RLY Cut-Out |
| 31 | RCLR RLY Cut-In |
| 32 | GEN TT Cut-In |
| 33 | GEN TT Cut-Out |
| 34 | Sect Cut-In |
| 35 | Sect Cut-Out |
| 36 | Reset Tar Cntrs |
| 37 | reserved-37 |
| 38 | reserved-38 |

COUNTER TABLE

| Index | Class | Deadband | Name |
|---|---|---|---|
| 0 | 1 | 10000 | Gnd Trip Counter |
| 1 | 1 | 10000 | A Trip Counter |
| 2 | 1 | 10000 | B Trip Counter |
| 3 | 1 | 10000 | C Trip Counter |
| 4 | 1 | 10000 | Trip Counter |
| 5 | 1 | 10000 | SEF Trip Counter |
| 6 | 1 | 10000 | Fault Type |
| 7 | 1 | 10000 | Proview REV |
| 8 | 1 | 10000 | Sect. Count |
| 9 | 1 | 10000 | NOVA, WE TYPE |

ANALOG INPUT TABLE

| | | | High | Low | Scale | |
|---|---|---|---|---|---|---|
| Index | Class | Deadband | threshold | threshold | Factor | Name |
| 0 | 2 | 10000 | 10000 | 10 | 1 | 90% FullScale |
| 1 | 2 | 10000 | 10000 | 10 | 1 | 0% FullScale |
| 2 | 2 | 10000 | 10000 | 10 | 10 | IA: mag (Apri) |
| 3 | 2 | 10000 | 10000 | 10 | 10 | IB: mag (Apri) |
| 4 | 2 | 10000 | 10000 | 10 | 10 | IC: mag (Apri) |
| 5 | 2 | 10000 | 10000 | 10 | 10 | 3I0: mag (Apri) |
| 6 | 2 | 10000 | 10000 | 10 | 10 | Va/Va-c (120 Vbase) |
| 7 | 2 | 10000 | 10000 | 10 | 10 | Vb/Vb-a (120 Vbase) |
| 8 | 2 | 10000 | 10000 | 10 | 10 | Vc/Vc-b (120 Vbase) |
| 9 | 2 | 10000 | 10000 | 10 | 1 | P: Phase A (kW pri) |
| 10 | 2 | 10000 | 10000 | 10 | 1 | P: Phase B (kW pri) |
| 11 | 2 | 10000 | 10000 | 10 | 1 | P: Phase C (kW pri) |
| 12 | 2 | 10000 | 10000 | 10 | 1 | P: 3phase (kW pri) |
| 13 | 2 | 10000 | 10000 | 10 | 1 | Q: Phase A (kvar pri) |
| 14 | 2 | 10000 | 10000 | 10 | 1 | Q: Phase B (kvar pri) |
| 15 | 2 | 10000 | 10000 | 10 | 1 | Q: Phase C (kvar pri) |
| 16 | 2 | 10000 | 10000 | 10 | 1 | Q: 3phase (kvar pri) |
| 17 | 2 | 10000 | 10000 | 10 | 1000 | pf: 3phase |
| 18 | 2 | 10000 | 10000 | 10 | 100 | Phase Freq (Hz) |
| 19 | 2 | 10000 | 10000 | 10 | 10 | Demand(IA: pri) |
| 20 | 2 | 10000 | 10000 | 10 | 10 | Demand(IB: pri) |
| 21 | 2 | 10000 | 10000 | 10 | 10 | Demand(IC: pri) |
| 22 | 2 | 10000 | 10000 | 10 | 10 | Demand(Ig: pri) |
| 23 | 2 | 10000 | 10000 | 10 | 100 | Battery Voltage |
| 24 | 2 | 10000 | 10000 | 10 | 1000 | Battery Current |
| 25 | 2 | 10000 | 10000 | 10 | 10 | Fault Location (mi/km) |
| 26 | 2 | 10000 | 10000 | 10 | 10 | Fault Duration (cyc) |
| 27 | 2 | 10000 | 10000 | 10 | 1 | Fault A Phase Amps (pri) |
| 28 | 2 | 10000 | 10000 | 10 | 1 | Fault B Phase Amps (pri) |
| 29 | 2 | 10000 | 10000 | 10 | 1 | Fault C Phase Amps (pri) |
| 30 | 2 | 10000 | 10000 | 10 | 1 | Fault Max Amps (pri) |
| 31 | 2 | 10000 | 10000 | 10 | 1 | Max(3I0: mag (Apri)) |
| 32 | 2 | 10000 | 10000 | 10 | 10 | Vx/Vx-y (120 Vbase) × 10 |
| 33 | 2 | 10000 | 10000 | 10 | 10 | Vy/Vy-z (120 Vbase) × 10 |
| 34 | 2 | 10000 | 10000 | 10 | 10 | Vz/Vz-x (120 Vbase) × 10 |
| 35 | 2 | 10000 | 10000 | 10 | 1 | PHS MTT: Norm |
| 36 | 2 | 10000 | 10000 | 10 | 1 | GND MTT: Norm |
| 37 | 2 | 10000 | 10000 | 10 | 1 | SGF MTT: Norm |
| 38 | 2 | 10000 | 10000 | 10 | 1 | PHS MTT: Alt1 |
| 39 | 2 | 10000 | 10000 | 10 | 1 | GND MTT: Alt1 |
| 40 | 2 | 10000 | 10000 | 10 | 1 | SGF MTT: Alt1 |
| 41 | 2 | 10000 | 10000 | 10 | 1 | PHS MTT: Alt2 |
| 42 | 2 | 10000 | 10000 | 10 | 1 | GND MTT: Alt2 |
| 43 | 2 | 10000 | 10000 | 10 | 1 | SGF MTT: Alt2 |

S&C Intellicap Plus Cap Bank Controller

| Point ID | Point Mapping Status - Description | |
|---|---|---|
| 0 | Cap Bank Closed | Class 1 |
| 1 | Cap Bank Open | Class 1 |
| 2 | Auto Manual Operation | Class 1 |
| 3 | SCADA Remote Local | Class 1 |
| 4 | Alarm Summary | Class 1 |
| 5 | SCADA Override Enabled | No Event |
| 6 | Over Voltage | No Event |
| 7 | Under Voltage | No Event |
| 8 | Emergency Voltage Override | No Event |
| 9 | Reclose Block | No Event |
| 10 | Maximum Daily Cycles | No Event |
| 11 | Load Fuse Blown | No Event |
| 12 | Temperature Sensor Error | No Event |
| 13 | Temperature System | No Event |
| 14 | Incorrect Voltage Range | No Event |
| 15 | Low Voltage Switching Delta | No Event |
| 16 | Neutral Sensor Option | No Event |
| 17 | Neutral Sensor Configuration | No Event |
| 18 | Neutral Sensor Lockout | No Event |
| 19 | Continuous Neutral Sensor | No Event |
| 20 | Zero Neutral Sensor | No Event |
| 21 | VAR Option | No Event |
| 22 | Current Direction | No Event |
| 23 | Low Switching VAR Delta | No Event |
| 24 | Neutral Sensor Alarming | No Event |
| 25 | Neutral Sensor Data Logging | No Event |
| 26 | Neutral Sensor Location | No Event |
| 27 | Automatic Calculation Enabled | No Event |

| | | | | Percent | Fixed |
|---|---|---|---|---|---|
| Point ID | Point Mapping Analog Input - Description | Event Class | Scaling | Deadband | Deadband |
| 0 | Voltage Reference Standard 90 | No Event | 1 | NA | NA |
| 1 | Voltage Reference Standard 0 | No Event | 1 | NA | NA |
| 2 | Control Strategy | Class 1 | 1 | NA | NA |
| 3 | Temperature Fahrenheit | No Event | 1 | NA | NA |
| 4 | Secondary Voltage | No Event | 1 | NA | NA |
| 5 | Primary Voltage | No Event | 1 | NA | NA |
| 6 | SCADA Override Remaining Time | No Event | 1 | NA | NA |
| 7 | Neutral Fundamental RMS | No Event | 1 | NA | NA |
| 8 | Single Phase Line Current | No Event | 1 | NA | NA |
| 9 | Phase Angle | No Event | 1 | NA | NA |
| 10 | Three-phase kVARs | No Event | 1 | NA | NA |
| 11 | Three-phase kVA | No Event | 1 | NA | NA |
| 12 | Three-phase kW | No Event | 1 | NA | NA |
| 13 | Voltage Total Harmonic | No Event | 1 | NA | NA |
| 14 | Voltage Third Harmonic | No Event | 1 | NA | NA |
| 15 | Voltage Fifth Harmonic | No Event | 1 | NA | NA |
| 16 | Voltage Seventh Harmonic | No Event | 1 | NA | NA |
| 17 | Current Total Harmonic | No Event | 1 | NA | NA |
| 18 | Current Third Harmonic | No Event | 1 | NA | NA |
| 19 | Current Fifth Harmonic | No Event | 1 | NA | NA |
| 20 | Current Seventh Harmonic | No Event | 1 | NA | NA |
| 21 | Neutral Total Harmonic | No Event | 1 | NA | NA |
| 22 | Neutral Third Harmonic | No Event | 1 | NA | NA |
| 23 | Neutral Fifth Harmonic | No Event | 1 | NA | NA |
| 24 | Neutral Seventh Harmonic | No Event | 1 | NA | NA |
| 25 | Voltage Delta | No Event | 1 | NA | NA |
| 26 | Neutral Total RMS | No Event | 1 | NA | NA |
| 27 | kVAR Delta | No Event | 1 | NA | NA |
| 28 | Last Switch Operation Reason | No Event | 1 | NA | ManualOperation |
| 29 | Voltage Ninth Harmonic | No Event | 1 | NA | NA |
| 30 | Current Ninth Harmonic | No Event | 1 | NA | NA |
| 31 | Neutral Ninth Harmonic | No Event | 1 | NA | NA |
| 32 | Three Phase Bank Size | No Event | 1 | NA | NA |
| 33 | Extended Voltage Sampling Average Value | No Event | 1 | NA | NA |

| Point ID | Point Mapping Control Points - Description | Object Type |
|---|---|---|
| 0 | Open/Close Switch | Breaker |
| 1 | Enable/Disable Automatic Operation | Breaker |
| 2 | Enable/Disable Scada Override | Breaker |
| 3 | Reset Neutral Lockout | N/A |
| 4 | Enable/Disable Application Layer Confirmations | Breaker |
| 5 | Reset All Alarms | Warnings and Errors |
| 6 | Inhibit Automatic Operation For SCADA Timer | N/A |
| 7 | Enable/Disable Automatic Bank Voltage Change Calculation | Breaker |

| | Point Mapping Analog Output Points - |
|---|---|
| Point ID | Description |
| 0 | Application Layer Confirm Retry Time |
| 1 | Application Confirm Retry Count |
| 2 | Control Point Select Time |
| 3 | Scada Override Timer |
| 4 | High Voltage Scada Override Value |
| 5 | Low Voltage Scada Override Value |
| 6 | Max Auto Cycles Per Day |
| 7 | Extended Voltage Sampling Average Period |

| | Point Mapping Counters - | | Percent | Fixed |
|---|---|---|---|---|
| Point ID | Description | Event Class | Deadband | Deadband |
| 0 | Total Cycles Since Installation | No Event | NA | NA |
| 1 | Total Cycles This Year | No Event | NA | NA |
| 2 | Daily Automatic Operations | No Event | NA | NA |

S&C 5802 Underground Switch Controller
BINARY INPUT TABLE

| Index | Status Input | Description - DNP |
|---|---|---|
| 0 | sw 1 position b | Switch 1 Open contact status. This bit is set if the switch |
| | | (circuit) is open. |
| 1 | sw 1 position | Switch 1 Closed contact status. This bit is set if the switch |
| | | (circuit) is closed. |
| 2 | vacuum fault interrupter 1 position | Vacuum Fault Interrupter 1 Closed contact status. This bit is |
| | | set if the first Vacuum Fault Interrupter is closed (if |
| | | applicable). |
| 3 | sw 2 position b | Switch 2 Open contact status. This bit is set if the switch |
| | | (circuit) is open. |
| 4 | sw 2 position | Switch 2 Closed contact status. This bit is set if the switch |
| | | (circuit) is closed. |
| 5 | vacuum fault interrupter 2 position | Vacuum Fault Interrupter 2 Closed contact status. This bit is |
| | | set if the first Vacuum Fault Interrupter is closed (if |
| | | applicable). |
| 6 | sectionalizer mode | Automatic operation enable. This bit is set if automatic |
| | | control functions have been enabled via either the faceplate |
| | | switches or SCADA control command. |
| 7 | scada | REMOTE/LOCAL faceplate switch position. This bit is set |
| | | when the switch is in REMOTE |
| 8 | fi tgt | Overcurrent fault detected, Switch 1 or Switch 2. This bit is |
| | | set if the fault detection circuitry has detected a line fault |
| | | condition which has not been reset by the SCADA operator. |
| | | For the normally closed switch, line fault conditions clear |
| | | automatically once 3-phase line voltage has been sensed, |
| | | the switch is closed, and 45 minutes have elapsed or the |
| | | faceplate REMOTE/LOCAL switch is toggled. For the |
| | | normally open switch, you can toggle the |
| | | REMOTE/LOCAL switch to clear the condition while the |
| | | line switch is open or closed. |
| | | Note: NEED TO TEST - EITHER SW1/SW2 AND |
| | | FACEPLATE RESET OPERATION |
| 9 | sw 1 sectionalizer | Sectionalizer tripped, Switch 1. This bit is set if any |
| | | automatic control function has opened the switch. The bit is |
| | | cleared when the switch is closed for any reason, and is also |
| | | cleared on reinitialization of the Switch Control using the |
| | | Setup software, or is cleared when you toggle the |
| | | REMOTE/LOCAL switch. |
| 10 | sw 2 sectionalizer | Sectionalizer tripped, Switch 2. As above, for Switch 2. |
| 11 | status input 12 | Reserved |
| 12 | sw 1 sectionalizer mode | Switch 1 not ready. This bit is set when switch operation is |
| | | disabled. This may occur when low pressure is detected, |
| | | external local is set, or bad battery voltage is present. See |
| | | status points 14, 15, and 22 to determine which condition is |
| | | causing the bit to be set. |
| 13 | sw 2 sectionalizer mode | Switch 2 not ready. As above, for Switch 2. |
| 14 | low press or low oil detected | Low Pressure/Low Oil detected (if applicable). |
| 15 | external scada | Operator is in external local operation (if applicable). |
| 16 | mtce | Maintenance required. This bit is set when some form of |
| | | maintenance (other than battery replacement) is required. It |
| | | is set when the battery charger has failed due to over |
| | | voltage, when the temperature sensor has failed, or when |
| | | the switch Open/Close contacts are not mutually exclusive. |
| | | This is a summary bit. The exact cause of the failure can be |
| | | determined from the inspection of other status points. |
| 17 | sw 1 position fail | Open/Close switch position indication is inconsistent, |
| | | Switch 1. This bit is set if either both contacts are closed, or |
| | | both contacts are open. |
| 18 | sw 2 position fail | Open/Close switch position indication is inconsistent, |
| | | Switch 2. This bit is set if either both contacts are closed, or |
| | | both contacts are open. |
| 19 | ac pwr fail | Control power failure. This bit is set if ac power is not |
| | | available to the battery charger. It indicates that the Switch |
| | | Control is operating on battery backup. |
| 20 | battery override mode | Operator failure override set. This bit is set after the |
| | | operator has executed the Failure Override Latch On control |
| | | command to let the switch be operated even if battery |
| | | power is low. The bit remains set until the override is |
| | | disabled using the Failure Override Latch Off command. |
| | | Also, the status point will go off, and Failure Override will |
| | | become disabled, after a 15 minute timeout, if it was not |
| | | already turned off by the Latch Off command. |
| 21 | battery low | Battery system low. The battery voltage is low, but the |
| | | switch will operate. |
| 22 | battery sys summary fail | Battery system bad. The battery voltage is too low to |
| | | operate the switch. This condition blocks the operation of |
| | | the switch unless the Failure Override bit is set. The “bad” |
| | | battery status is only set when the battery voltage is |
| | | definitely too low to operate the switch. |
| 23 | battery charger fail | Battery charger has failed. The charging voltage applied to |
| | | the battery system was too high when the charger was |
| | | connected, and the charger has been turned off. |
| 24 | battery test | Battery test in progress. The Switch Control automatically |
| | | performs a test procedure on the batteries at periodic |
| | | intervals. During the test, the battery voltage fluctuates. |
| 25 | cabinet door | Cabinet door open. This bit is set if the door to the Switch |
| | | Control enclosure is ajar. When the door is closed, this bit is |
| | | cleared and all power to the faceplate LEDs is turned off. |
| 26 | temp sensor fail | Temperature sensor bad. The temperature sensor in the |
| | | Switch Control is reading out of range. When the sensor is |
| | | reading incorrectly, various temperature-related correction |
| | | factors will not be accurate. |
| 27 | sw 1 a ph tgt | Phase A - overcurrent fault, Switch 1. This bit is set if the |
| | | peak current measured on Phase A has exceeded the |
| | | programmed fault threshold level continuously for at least |
| | | the programmed period of time. The bit is cleared |
| | | automatically once AC power has been restored to all |
| | | phases, the switch is closed, and 45 minutes have elapsed or |
| | | the faceplate REMOTE/LOCAL switch is toggled. |
| 28 | sw 1 b ph tgt | Phase B - overcurrent fault, Switch 1. As above, for Phase |
| | | B, Switch 1. |
| 29 | sw 1 c ph tgt | Phase C - overcurrent fault, Switch 1. As above, for Phase |
| | | C, Switch 1. |
| 30 | sw 1 grd tgt | Overcurrent ground fault, Switch 1. As above, for ground, |
| | | Switch 1. |
| 31 | sw 2 a ph tgt | Phase A - overcurrent fault, Switch 2. This bit is set if the |
| | | peak current measured on Phase A has exceeded the |
| | | programmed threshold level continuously for at least the |
| | | programmed period of time. For a normally closed switch, |
| | | the bit is cleared automatically once ac power has been |
| | | restored to all phases, the switch is closed, and 45 minutes |
| | | have elapsed or the faceplate REMOTE/LOCAL switch is |
| | | toggled. For the normally open switch, you can toggle the |
| | | REMOTE/ LOCAL switch to clear the condition while the |
| | | line switch is open or closed. |
| 32 | sw 2 b ph tgt | Phase B - overcurrent fault, Switch 2. As above, for Phase |
| | | B, Switch 2. |
| 33 | sw 2 c ph tgt | Phase C - overcurrent fault, Switch 2. As above, for Phase |
| | | C, Switch 2. |
| 34 | sw 2 grd tgt | Overcurrent ground fault, Switch 2. As above, for ground, |
| | | Switch 2. |
| 35 | line voltage loss | This point is set for any configured voltage channel where |
| | | the voltage sensor shows a loss of voltage. For example, |
| | | pad-mounted gear may be configured with three voltage |
| | | sensors or six voltage sensors. |
| 36 | sw 1 pwr flow a | Phase A - current direction, Switch 1. This bit is set if the |
| | | current on Phase A is flowing in the direction opposite to |
| | | the “normal” direction configured in the Switch Control. |
| | | The Switch Control identifies reverse current when the |
| | | voltage- current phase angle deviates more than 90 degrees |
| | | from the value set during installation for unity power factor. |
| 37 | sw 1 pwr flow b | Phase B - current direction, Switch 1. As above, for Phase |
| | | B, Switch 1. |
| 38 | sw 1 pwr flow c | Phase C - current direction, Switch 1. As above, for Phase |
| | | C, Switch 1. |
| 39 | sw 2 pwr flow a | Phase A - current direction, Switch 2. This bit is set if the |
| | | current on Phase A is flowing in the direction opposite to |
| | | the “normal” direction configured in the Switch Control. |
| | | The Switch Control identifies reverse current when the |
| | | voltage- current phase angle deviates more than 90 degrees |
| | | from the value set during installation for unity power factor. |
| 40 | sw 2 pwr flow b | Phase B - current direction, Switch 2. As above, for Phase |
| | | B, Switch 2. |
| 41 | sw 2 pwr flow c | Phase C - current direction, Switch 2. As above, for Phase |
| | | C, Switch 2. |

ANALOG INPUT TABLE

| Index | Status Input | Description - DNP |
|---|---|---|
| 1 | 0 ref | 0% voltage reference standard. This is provided for the |
| | | benefit of the protocol implementation to conform to the |
| | | RTU standard. It is loaded as a constant with the value zero. |
| 2 | sw 1 amps grd | Neutral current of Switch 1, taken as the vector sum of the |
| | | phase currents on Phases A, B, and C of Switch 1. Current |
| | | is measured using true RMS techniques and reported in |
| | | units of 1 count equals 1 ampere. |
| 3 | sw 1 amps a | Single-phase current measured on Phase A of Switch 1. |
| | | Current is measured |
| 4 | sw 1 amps b | Single-phase current measured on Phase B of Switch 1. |
| | | Current is measured using true RMS techniques and |
| | | reported in units of 1 count equals 1 ampere. |
| 5 | sw 1 amps c | Single-phase current measured on Phase C of Switch 1. |
| | | Current is measured using true RMS techniques and |
| | | reported in units of 1 count equals 1 ampere. |
| 6 | sw 2 amps grd | Neutral current of Switch 2, taken as the vector sum of the |
| | | phase currents on Phases A, B, and C of Switch 2. Current |
| | | is measured using true RMS techniques and reported in |
| | | units of 1 count equals 1 ampere. |
| 7 | sw 2 amps a | Single-phase current measured on Phase A of Switch 2. |
| | | Current is measured using true RMS techniques and |
| | | reported in units of 1 count equals 1 ampere. |
| 8 | sw 2 amps b | Single-phase current measured on Phase B of Switch 2. |
| | | Current is measured using true RMS techniques and |
| | | reported in units of 1 count equals 1 ampere. |
| 9 | sw 2 amps c | Single-phase current measured on Phase C of Switch 2. |
| | | Current is measured using true RMS techniques and |
| | | reported in units of 1 count equals 1 ampere. |
| 10 | sw 1 volts a | Single-phase voltage measured on Phase A of Switch 1. |
| | | Voltage is measured using true RMS techniques and scaled |
| | | to yield a nominal value of 120 Vac. Configuration of the |
| | | Switch Control at the time of installation provides the |
| | | scaling factors such as voltage transformer turn ratio, etc. In |
| | | cases where loads are connected in a delta (phase-to-phase) |
| | | configuration, the Switch Control's Sensor Conditioning |
| | | module is jumpered to yield phase-to-phase voltage |
| | | readings. Voltage is reported in units of 1 sensor count |
| | | equals 0.1 Vac RMS. |
| 11 | sw 1 volts b | Single-phase voltage measured on Phase B of Switch 1. As |
| | | above, for Phase B, Switch 1. |
| 12 | sw 1 volts c | Single-phase voltage measured on Phase C of Switch 1. As |
| | | above, for Phase C, Switch 1. |
| 13 | sw 2 volts a | Single-phase voltage measured on Phase A of Switch 2. |
| | | Voltage is measured using true RMS techniques and scaled |
| | | to yield a nominal value of 120 Vac. Configuration of the |
| | | Switch Control at the time of installation provides the |
| | | scaling factors such as voltage transformer turn ratio, etc. In |
| | | cases where loads are connected in a delta (phase-to-phase) |
| | | configuration, the Switch Control's Sensor Conditioning |
| | | module is jumpered to yield phase-to-phase voltage |
| | | readings. Voltage is reported in units of 1 sensor count |
| | | equals 0.1 Vac RMS. |
| 14 | sw 2 volts b | Single-phase voltage measured on Phase B of Switch 2. As |
| | | above, for Phase B, Switch 2. |
| 15 | sw 2 volts c | Single-phase voltage measured on Phase C of Switch 2. As |
| | | above, for Phase C, Switch 2. |
| 16 | sw 1 phase angle a | Phase angle on Phase A of Switch 1. Each count equals one |
| | | eighth of a degree. |
| 17 | sw 1 phase angle b | Phase angle on Phase B of Switch 1. As above, for Phase B, |
| | | Switch 1. |
| 18 | sw 1 phase angle c | Phase angle on Phase C of Switch 1. As above, for Phase C, |
| | | Switch 1. |
| 19 | sw 2 phase angle a | Phase angle on Phase A of Switch 2. Each count equals one |
| | | eighth of a degree. |
| 20 | sw 2 phase angle b | Phase angle on Phase B of Switch 2. As above, for Phase B, |
| | | Switch 2. |
| 21 | sw 2 phase angle c | Phase angle on Phase C of Switch 2. As above, for Phase C, |
| | | Switch 2. |
| 22 | sw 1 kvars a | Single-phase kVARs measured on Phase A of Switch 1. |
| | | kVARs (volt- amperes, reactive) are calculated from single- |
| | | phase true RMS voltage and current sensor values and the |
| | | respective voltage-current phase angle. Each count equals |
| | | one kVAR. |
| 23 | sw 1 kvars b | Single-phase kVARs measured on Phase B of Switch 1. As |
| | | above, for Phase B, Switch 1. |
| 24 | sw 1 kvars c | Single-phase kVARs measured on Phase C of Switch 1. As |
| | | above, for Phase C, Switch 1. |
| 25 | sw 2 kvars a | Single-phase kVARs measured on Phase A of Switch 2. |
| | | kVARs (volt- amperes, reactive) are calculated from single- |
| | | phase true RMS voltage and current sensor values and the |
| | | respective voltage-current phase angle. Each count equals |
| | | one kVAR. |
| 26 | sw 2 kvars b | Single-phase kVARs measured on Phase B of Switch 2. As |
| | | above, for Phase B, Switch 2. |
| 27 | sw 2 kvars c | Single-phase kVARs measured on Phase C of Switch 2. As |
| | | above, for Phase C, Switch 2. |
| 28 | cabinet temp | The most recent cabinet temperature reading. This value is |
| | | in units of ° F. |
| 29 | battery volts | Battery voltage, nominally 24 Vdc. If ac power is on, this |
| | | value is updated |

BINARY OUTPUT TABLE

| Index | Status Input | Description - DNP |
|---|---|---|
| 0 | SW 1 OPEN/CLOSE | Issue the Close/Open command to Switch 1. The |
| | | Close/Open command may be issued using either the |
| | | Select/Operate sequence, the Direct Operate function, or the |
| | | Direct Operate without Ack function. Both Trip and Close |
| | | are valid for this point. |
| 1 | SW2 OPEN/CLOSE | Issue the Close/Open command to Switch 2. As above, for |
| | | Switch 2. |
| 2 | SW1 SHOTS-TO-LOCKOUT | Issue the Shots-to-Lockout command to Switch 1. This |
| | | command may be issued using either the Select/Operate |
| | | sequence, the Direct Operate function, or the Direct Operate |
| | | without Ack function. Only a Close command is valid for |
| | | this point. This command is ignored and returns an error if |
| | | the switch is not open, or automatic operation is not |
| | | enabled. |
| 3 | SW2 SHOTS-TO-LOCKOUT | Issue the Shots-to-Lockout command to Switch 2. This |
| | | command may be issued using either the Select/Operate |
| | | sequence, the Direct Operate function, or the Direct Operate |
| | | without Ack function. Only a Close command is valid for |
| | | this point. This command is ignored and returns an error if |
| | | the switch is not open, or automatic operation is not enabled |
| 4 | RESET FAULT | Reset (clear) any outstanding overcurrent fault conditions |
| | | present. The fault condition otherwise remains active for 45 |
| | | minutes after the switch is closed and ac power is fully |
| | | restored, or until the REMOTE/LOCAL switch is toggled. |
| 5 | BAT TEST | Begin a battery test cycle. This command must be issued |
| | | using a Pulse On request. If ac power is on, the charger is |
| | | disconnected for several minutes while the test is in |
| | | progress. If ac power is off, a brief battery impedance test |
| | | evaluates the battery condition. |
| 6 | FAIL OVERRIDE | Enable or disable the Failure Override status. This |
| | ENABLED/DISABLED | command must be issued using the Latch On/Off request in |
| | | the control relay output block. This allows Open and Close |
| | | commands to be processed even if the switch “Not Ready” |
| | | condition is active. |
| 7 | AUTOMATIC | Enable or disable “Automatic” operation. This command |
| | ENABLED/DISABLED | must be issued using the Latch On/Off request in the control |
| | | relay output block. In “Automatic” mode, the Switch |
| | | Control automatically opens the switch if a preconfigured |
| | | recloser sequence is recognized after a detected fault. |

APPENDIX D
SAP Cycle Count Sample Data according to some embodiments.
Following is a partial sample of the SAP cycle count data export according to some embodiments:

| | | | | | COUNT | | | | Replen- | |
|---|---|---|---|---|---|---|---|---|---|---|
| | | | | | Unre- | Unre- | Blocked | | ishment | |
| Plant | SLoc | LabOff | Mail Description | Material | stricted | stricted | Stk Qty | Recorder | Qty | Comment |
| W090 | 0506 | CM2 | METER/MODULE INTEGRATED | M241063 | | 103.000 | 0.000 | 24.001 | 96.000 | |
| | | | ELECTRIC FORM 2S | | | | | | | |
| W090 | 0507 | CM2 | METER/MODULE INTEGRATED | M241063 | | 266.000 | 0.000 | 192.001 | 192.000 | |
| | | | ELECTRIC FORM 2S | | | | | | | |
| W090 | 0510 | CM2 | METER/MODULE INTEGRATED | M241063 | | 84.000 | 0.000 | 40.001 | 96.000 | |
| | | | ELECTRIC FORM 2S | | | | | | | |
| W090 | 0511 | CM2 | METER/MODULE INTEGRATED | M241063 | | 48.000 | 0.000 | 48.001 | 96.000 | |
| | | | ELECTRIC FORM 2S | | | | | | | |
| W090 | 0512 | CM2 | METER/MODULE INTEGRATED | M241063 | | 88.000 | 0.000 | 20.001 | 96.000 | |
| | | | ELECTRIC FORM 2S | | | | | | | |
| W090 | 0513 | CM2 | METER/MODULE INTEGRATED | M241063 | | 59.000 | 0.000 | 48.001 | 96.000 | |
| | | | ELECTRIC FORM 2S | | | | | | | |
| W090 | 0514 | CM2 | METER/MODULE INTEGRATED | M241063 | | 249.000 | 0.000 | 384.001 | 288.000 | |
| | | | ELECTRIC FORM 2S | | | | | | | |
| W090 | 0601 | CM2 | METER/MODULE INTEGRATED | M241063 | | 30.000 | 0.000 | 120.001 | 192.000 | |
| | | | ELECTRIC FORM 2S | | | | | | | |
| W090 | 0602 | CM2 | METER/MODULE INTEGRATED | M241063 | | 6.000 | 0.000 | 4.001 | 8.000 | |
| | | | ELECTRIC FORM 2S | | | | | | | |
| W090 | 0603 | CM2 | METER/MODULE INTEGRATED | M241063 | | 6.000 | 0.000 | 4.001 | 8.000 | |
| | | | ELECTRIC FORM 2S | | | | | | | |
| W090 | 0604 | CM2 | METER/MODULE INTEGRATED | M241063 | | 36.000 | 0.000 | 96.001 | 192.000 | |
| | | | ELECTRIC FORM 2S | | | | | | | |
| W090 | 0605 | CM2 | METER/MODULE INTEGRATED | M241063 | | 12.000 | 0.000 | 4.001 | 4.000 | |
| | | | ELECTRIC FORM 2S | | | | | | | |

APPENDIX E
CC&B Sample Data according to some embodiments.
Following is a partial sample of the CC&B data export:

| SHIP_DT | SHIP_MTH | SHIP_YR | MATL_CD | MATL_CD_DESC | BADGE_NBR | CUST_LOC | CUST_LOCATION | AGING |
|---|---|---|---|---|---|---|---|---|
| May 30, | 5 | 2014 | 231932 | METER GAS SMARTMETER | 61540446 | 2 | UNKN | 1489 |
| 2014 | | | | AC250 OR R275 | | | | |
| May 30, | 5 | 2014 | 231932 | METER GAS SMARTMETER | 61540444 | 2 | UNKN | 1489 |
| 2014 | | | | AC250 OR R275 | | | | |
| May 30, | 5 | 2014 | 231932 | METER GAS SMARTMETER | 61540443 | 2 | UNKN | 1489 |
| 2014 | | | | AC250 OR R275 | | | | |
| May 30, | 5 | 2018 | 231932 | METER GAS SMARTMETER | 62170805 | 9 | UNKN | 28 |
| 2018 | | | | AC250 OR R275 | | | | |
| May 30, | 5 | 2018 | 231932 | METER GAS SMARTMETER | 62171017 | 9 | UNKN | 28 |
| 2018 | | | | AC250 OR R275 | | | | |
| May 30, | 5 | 2018 | 231932 | METER GAS SMARTMETER | 62170808 | 9 | UNKN | 28 |
| 2018 | | | | AC250 OR R275 | | | | |
| May 30, | 5 | 2018 | 231932 | METER GAS SMARTMETER | 62170972 | 9 | UNKN | 28 |
| 2018 | | | | AC250 OR R275 | | | | |
| May 30, | 5 | 2018 | 231932 | METER GAS SMARTMETER | 62170975 | 9 | UNKN | 28 |
| 2018 | | | | AC250 OR R275 | | | | |
| May 30, | 5 | 2018 | 231932 | METER GAS SMARTMETER | 62170960 | 9 | UNKN | 28 |
| 2018 | | | | AC250 OR R275 | | | | |
| May 30, | 5 | 2018 | 231932 | METER GAS SMARTMETER | 62171004 | 9 | UNKN | 28 |
| 2018 | | | | AC250 OR R275 | | | | |
| May 30, | 5 | 2018 | 231932 | METER GAS SMARTMETER | 62170797 | 9 | UNKN | 28 |
| 2018 | | | | AC250 OR R275 | | | | |
| May 30, | 5 | 2018 | 231932 | METER GAS SMARTMETER | 62170833 | 9 | UNKN | 28 |
| 2018 | | | | AC250 OR R275 | | | | |
| May 30, | 5 | 2018 | 231932 | METER GAS SMARTMETER | 62170836 | 9 | UNKN | 28 |
| 2018 | | | | AC250 OR R275 | | | | |

APPENDIX F
Theoretical EPC Design according to some embodiments.
Following is a table of a theoretical RFID EPC design (for 12 meters from a single pallet) which would use
the 24 hexadecimal values of the EPC to convey the meter type, vendor, and badge # as well as whether
or not the RFID is attached to a single meter or pallet of meters according to some embodiments. Actual EPC
definition will need to be defined and agreed to with the meter vendor according to some embodiments.

| | Meter Type | | | | | | |
|---|---|---|---|---|---|---|---|
| Data Field | 1 | Vendor | | Pallet | Meter Badge # | | |
| Hex Length | {E = | 6 | Spacer | 6 | 10 | | |
| Sample | electric, | {000000- | 1 | {000000- | {0000000000- | Pallet EPC | Meter EPC |
| Values | A = gas} | FFFFFF} | {0} | FFFFFF} | 9999999999} | 24 | 24 |
| | E | AAAAAA | 0 | 001945 | 0000000001 | EAAAAAA00019450000000000 | EAAAAAA00019450000000001 |
| | E | AAAAAA | 0 | 001945 | 0000000002 | EAAAAAA00019450000000000 | EAAAAAA00019450000000002 |
| | E | AAAAAA | 0 | 001945 | 0000000003 | EAAAAAA00019450000000000 | EAAAAAA00019450000000003 |
| | E | AAAAAA | 0 | 001945 | 0000000004 | EAAAAAA00019450000000000 | EAAAAAA00019450000000004 |
| | E | AAAAAA | 0 | 001945 | 0000000005 | EAAAAAA00019450000000000 | EAAAAAA00019450000000005 |
| | E | AAAAAA | 0 | 001945 | 0000000006 | EAAAAAA00019450000000000 | EAAAAAA00019450000000006 |
| | E | AAAAAA | 0 | 001945 | 0000000007 | EAAAAAA00019450000000000 | EAAAAAA00019450000000007 |
| | E | AAAAAA | 0 | 001945 | 0000000008 | EAAAAAA00019450000000000 | EAAAAAA00019450000000008 |
| | E | AAAAAA | 0 | 001945 | 0000000009 | EAAAAAA00019450000000000 | EAAAAAA00019450000000009 |
| | E | AAAAAA | 0 | 001945 | 0000000010 | EAAAAAA00019450000000000 | EAAAAAA00019450000000010 |
| | E | AAAAAA | 0 | 001945 | 0000000011 | EAAAAAA00019450000000000 | EAAAAAA00019450000000011 |
| | E | AAAAAA | 0 | 001945 | 0000000012 | EAAAAAA00019450000000000 | EAAAAAA00019450000000012 |

1. A system for enabling communication between various remote electrical devices comprising:
a Server comprising one or more Server Processors and one or more Server Non-transitory Processor Readable Media, the one or more Server Non-transitory Processor Readable Media having instructions stored thereon that when executed by the one or more Server Processors implement:
a Graphical User Interface (GUI);
a Client comprising one or more Client Processors and one or more Client Non-transitory Computer Readable Media, the Client Non-transitory Computer Readable Media having instructions stored thereon that when executed by the one or more Client Processors implement:
a Polling Process that is configured to read, translate, and/or record data, and
Business Logic that identifies events and/or conditions and generates asynchronous alerts to the Server; and
an End Device comprising one or more End Device Processors and one or more End Device Non-transitory Computer Readable Media, the End Device Non-transitory Computer Readable Media having instructions stored thereon that when executed by the one or more End Device Processors implement:
a Send Operation configured to send End Device Data,
a Receive Operation configured to receive Server Data and/or Client Data, and
a Configuration Operation configured to change one or more End Device Parameters controlling one or more End Device Functions and/or End Device Settings;
wherein the GUI is configured to initiate a desired command to be sent to the End Device via the Server;
wherein the Client is configured to translate messages from the Server and transmit Translated Messages to the End Devices; and
wherein the Send Operation is configured to send the End Device Data to the Client; and
wherein the Configuration Operation is configured to change one or more End Device Parameters based on instructions received from the Server and/or Client.

2. The system of claim 1,
wherein the End Device is an Electric Meter Assembly comprising an Electric Meter configured to monitor and record electricity usage.

3. The system of claim 2,
the Electric Meter Assembly further comprising:
a Support Platform including at least one Transformer coupled to the Support Platform.

4. The system of claim 3,
the Electric Meter Assembly further comprising:
a Socket Housing coupled to the Support Platform, the Socket Housing comprising:
a Socket Interface extending from a top side of the Socket Housing;
a Secondary Housing at least partially enclosed within the Socket Housing, the Secondary Housing including at least one CT Shunt; and
at least one Switch Assembly including an Actuator Shaft extending through the top side of the Socket Housing.

5. The system of claim 4,
wherein the Electric Meter is coupled to the Socket Interface; and
wherein the Electric Meter is removable and/or portable.

6. The system of claim 5,
wherein the at least one Actuator Shaft is configured to be coupled to the at least one CT Shunt via at least one Roller Contact.

7. The system of claim 5,
wherein the at least one Actuator Shaft is supported within a spring in a plunger housing, the spring positioned in a cavity of the plunger housing and extending coupled to a contact of the at least one actuator shaft.

8. A system for enabling communication between various remote electrical devices comprising:
a Server comprising one or more Server Processors and one or more Server Non-transitory Processor Readable Media, the one or more Server Non-transitory Processor Readable Media having instructions stored thereon that when executed by the one or more Server Processors implement:
a Graphical User Interface (GUI);
a Client comprising one or more Client Processors and one or more Client Non-transitory Computer Readable Media, the Client Non-transitory Computer Readable Media having instructions stored thereon that when executed by the one or more Client Processors implement:
a Polling Process that is configured to read, translate, and/or record data, and
Business Logic that identifies events and/or conditions and generates asynchronous alerts to the Server; and
one or more End Devices comprising one or more End Device Processors and one or more End Device Non-transitory Computer Readable Media, the one or more End Device Non-transitory Computer Readable Media having instructions stored thereon that when executed by the one or more End Device Processors implement:
a Send Operation configured to send End Device Data,
a Receive Operation configured to receive Server Data and/or Client Data, and
a Configuration Operation configured to change one or more End Device Parameters controlling one or more End Device Functions and/or End Device Settings;
wherein the GUI is configured to initiate a desired command to be sent to the End Device via the Server;
wherein the Send Operation is configured to send the End Device Data to the Client;
wherein the Server comprises a Virtual Machine running at least one Operating System; and
wherein the Client comprises at least one Router.

9. The system of claim 8,
wherein the one or more End Devices comprise an Electric Meter Assembly.

10. The system of claim 8,
wherein the one or more End Devices comprise a Smart Inverter.

11. The system of claim 8,
wherein the one or more End Devices comprises an Environmental Sensor.

12. The system of claim 8,
wherein the one or more End Devices comprise a Smart Thermostat.

13. The system of claim 8,
wherein the one or more End Devices comprise a Supervisory Control and Data Acquisition (SCADA) system.

14. The system of claim 8,
wherein the one or more End Devices comprise a Radio Frequency Identification (RFID) Reader.

15. The system of claim 8,
wherein the one or more End Devices comprise a Distributed Generator (DG).

16. A system for enabling communication between various remote electrical devices comprising:
one or more Servers comprising one or more Server Processors and one or more Server Non-transitory Processor Readable Media, the one or more Server Non-transitory Processor Readable Media having instructions stored thereon that when executed by the one or more Server Processors implement:
a Graphical User Interface (GUI), and
an Application Programming Interface (API);
one or more Clients comprising one or more Client Processors and one or more Client Non-transitory Computer Readable Media, the Client Non-transitory Computer Readable Media having instructions stored thereon that when executed by the one or more Client Processors implement:
a Polling Process that is configured to read, translate, and/or record data; and
an End Device comprising one or more End Device Processors and one or more End Device Non-transitory Computer Readable Media, the End Device Non-transitory Computer Readable Media having instructions stored thereon that when executed by the one or more End Device Processors implement:
a Send Operation configured to send End Device Data,
a Receive Operation configured to receive Server Data and/or Client Data, and
a Configuration Operation configured to change one or more End Device Parameters controlling one or more End Device Functions and/or End Device Settings;
wherein the GUI is configured to initiate a desired command to be sent to the End Device via the Server;
wherein the one or more Clients are configured to translate messages from the Server and transmit Translated Messages to the End Devices;
wherein the Send Operation is configured to send the End Device Data to the one or more Servers and/or one or more Clients.
wherein the Configuration Operation is configured to change one or more End Device Parameters based on instructions received from the one or more Servers and/or one or more Clients; and
wherein the API is configured to receive a request from a Supervisory Control and Data Acquisition (SCADA) system that includes data for the End Device.

17. The system of claim 16,
wherein the one or more End Devices are connected to the Client; and
wherein the Client comprises a Background Process configured to perform scheduled actions against the connected one or more End Devices.

18. The system of claim 17,
wherein the Background Process is configurable via a Configuration Flat File.

19. The system of claim 17,
wherein the Background Process comprises deleting Client Subscriptions that have not renewed within a configurable time period.

20. The system of claim 16,
wherein the End Device is an Electric Meter Assembly comprising an Electric Meter configured to monitor and record electricity usage.
